(19) United States
(12) Patent Application Publication
(10) Pub. No.: US 2022/0402955 A1
(43) Pub. Date: Dec. 22, 2022

(54) METAL COMPLEX AND LIGHT EMITTING DEVICE

(71) Applicant: City University of Hong Kong, Kowloon (HK)

(72) Inventors: Yun CHI, Kowloon (HK); Lin GAN, Kowloon (HK); JiBiao JIN, Kowloon (HK)

(21) Appl. No.: 17/743,543

(22) Filed: May 13, 2022

Related U.S. Application Data
(60) Provisional application No. 63/189,942, filed on May 18, 2021.

(51) Int. Cl. C07F 15/00; H01L 51/00

(52) U.S. Cl. CPC C07F 15/0033; H01L 51/0085

(57) ABSTRACT

A metal complex having at least one N-heterocyclic carbene ligand. The metal complex provides a blue emission. This is useful for organic light emitting diode (OLED) components where blue emitters have trailed behind the advances of red and green emitters.

### TECHNICAL FIELD

The invention relates to a metal complex and a light emitting device, particularly a light emitting device including an emissive layer having a metal complex.

### BACKGROUND

Organic light-emitting diodes (OLED) have already become a very important technology of the 21st century, e.g. for the display panel and lighting industries. Full-color OLED displays demand utilization of efficient and stable OLED emitters with all three elementary colors, namely: red, green and blue (RGB). Their success is due to the fast development of efficient luminescent materials and associated device architectures, for achieving nearly unitary external quantum efficiency. Despite remarkable progression within the field there is still a high demand within both the academic and industrial sectors for OLED emitters showing improved performance in all three RGB colors. A key requirement for OLED emitters is their capability to harvest both the electrically generated singlet and triplet excitons for lower power consumption and better performance. Meanwhile, the OLED should achieve longer operation lifespans, which could be, in part, solved by using more robust and durable emitters, together with achievement of balanced carrier transports within the devices.

Currently, both red and green emitters have been well developed, passing all stringent industrial assessment and being employed for commercial processes. However, blue emitters within an OLED remain a challenge for industrialization. Due to the higher emission energy of blue emitters compared to that of red and green counterparts, the associated devices tend to possess an inferior emission efficiency and poor stability during operation as a result of the facile thermal population to the upper lying quenching states and longer radiative lifetime of emitters.

Currently within the field of OLEDs there are two classes of highly efficient emitters, namely: thermally activated delayed fluorescence (TADF) emitters (e.g.

pure organic TADF materials) and phosphorescent emitters (e.g. transition metal-based phosphors). These materials are competing for the future commercial applications. One reason is that both emitters can provide excellent luminescent properties, adequate thermal and chemical stabilities, and versatile color tunability, and especially very high internal quantum efficiency of 100% based on the theoretical prediction. Hence, those with better stability and reduced radiative lifetime upon excitation will be more suitable for future commercial applications.

As discussed above, there is a necessity for robust blue emitters, so that the thermally induced decomposition can be suppressed. This challenge may be solved by employment of both the phosphorescent sensitizer and TADF terminal emitters, to which the Forster resonance energy transfer (FRET) from the assistant phosphor to terminal emitter may eventually afford the efficient narrow bandwidth blue electroluminescence.

Iridium(III) metal complexes have been proposed as possible phosphors and integral components for OLED devices due to their remarkable stability and efficient green and red luminescence. Systematical design of the chromophoric chelates is essential to control and fine-tune their emission wavelengths. Some of the reported Ir(III) complexes involve functional cyclometalating bidentate chelates linked to a N-donor fragment (such as pyridine, pyrazole or imidazole) in the form of either the homoleptic or heteroleptic derivatives with formula Ir(C^N)₃ or IR(C^N)₂(L^X), where C^N is N-containing aromatics and L^X is anionic ancillary.

However, one problem that hampers the widespread adoption of OLED technology is the lack of efficient and stable blue phosphors. Due to the stronger ligand-centered nit* contribution of typical C^N chelates upon excitation and poor ligand field strength exerted by the N-donor group, the corresponding blue emitters exhibit structured emission profile and multiple peak maxima, and relatively longer radiative lifetime and poor emission efficiency.

FIG. 1 shows the potential energy surface diagram of a hypothetical Ir(C^N)₃ or Ir(C^N)₂(L^X) complex, as exemplified by sky-blue emissive bis[2-(4,6-difluorophenyl)pyridinato-C²,N](picolinato)iridium(III) (FIrpic). It has been reported that the emissive T₁ state constituted a mixed metal-to-ligand charge transfer (MLCT) and ligand-centered ππ* processes, while the metal-centered (MC) dd state is a T₁ state in geometry with metal-ligand distances lengthened, which is thermally activated from the T₁ state in geometry close to the ground state S₀. Thus, tuning emission from sky-blue FIrpic and analogues in giving a new blue emitter can be done by addition of electron-withdrawing (or donating) group at the HOMO (or LUMO) segment of the Ir(III) complexes, which gives a new T₁′ state. However, this manipulation is expected to reduce the T₁′-MC dd energy gap to the derivatized emitter, thus causing enhanced emission quenching. This means that the class of Ir(C^N)₃ or Ir(C^N)₂(L^X) complex is not the desired and durable blue OLED emitter.

### SUMMARY

It is an object of the invention to address the above needs, to overcome or substantially ameliorate the above disadvantages or, more generally, to provide blue phosphors with an improved emission efficiency as well as better stability against unwanted degradation of emitters during device operation.

It is also an object of the invention to provide phosphors which render increasing photoluminescence quantum yield, for example to a value higher than 60%, phosphorescence peak max. located in the region 450-490 nm, radiative lifetime lower than 2 microsecond, and a true blue color with Commission Internationale de l′Éclairage coordinates CIE (y)-corrected current efficiency maximum (cd·A−1/y)≥280, or CIE(y)=0.16 and below. Generally, these features will provide high-performance OLED devices.

In a first aspect, the present invention provides a metal complex comprising a structure of Formula (I):

ML¹ₐL²_{b}L³_{c}L⁴_{d}L⁵ₑ (I),

where:
M is a transition metal;
L¹ is a bidentate ligand and a is an integer of 1 to 3;
L², L³, L⁴, and L⁵ are independently a monodentate ligand, or two adjacent L², L³, L⁴, and L⁵ is a bidentate ligand, and b, c, d, and e are independently an integer of 0 to 4;
a+b+c+d+e is 2, 3, 4, or 5; and
L¹ has a structure of Formula (II):

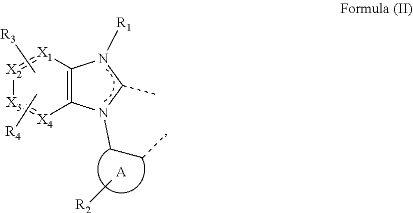

where:
A is a C₆₋₁₀ aryl ring or a 5 to 10 membered heteroaryl ring;
R₁ is selected from the group consisting of: C₁₋₆ alkyl, C₂₋₆ alkylether, C₁₋₆ alkoxy, C₁₋₆ fluoroalkyl, C₂₋₆ alkenyl, C₂₋₆ alkynyl, substituted or unsubstituted C₃₋₈ cycloalkyl, substituted or unsubstituted C₃₋₈ cycloalkenyl, substituted or unsubstituted 3 to 8 membered heterocycloalkyl, substituted or unsubstituted 3 to 8 membered heterocycloalkenyl, substituted or unsubstituted C₆₋₁₀ aryl, substituted or unsubstituted C₇₋₁₁ aralkyl, substituted or unsubstituted heteroaryl having 5 to 10 carbon atoms or heteroatoms, and substituted or unsubstituted heteroaralkyl having 6 to 11 carbon atoms or heteroatoms;
R₂, R₃, and R₄ are independently selected from the group consisting of: hydrogen, deuterium, fluorine, cyano, C₁₋₆ alkyl, C₁₋₆ alkoxy, C₁₋₆ fluoroalkyl, substituted or unsubstituted C₆₋₁₀ aryl, and substituted or unsubstituted heteroaryl having 5 to 10 carbon atoms or heteroatoms; and
two of X₁, X₂, X₃, and X₄ are C, and the other two of X₁, X₂, X₃, and X₄ are N.

M may be selected from the group consisting of: iridium, rhodium, platinum, palladium, gold, osmium, and ruthenium. Preferably, M is iridium.

Preferably, A is a phenyl ring.

Preferably, R₁ is selected from the group consisting of: C₁₋₆ alkyl, C₂₋₆ alkylether, C₄₋₆ alkoxy, C₄₋₆ fluoroalkyl, substituted or unsubstituted C₆₋₁₀ aryl, and substituted or unsubstituted C₇₋₁₁ aralkyl. More preferably, R₁ is methyl, ethyl, propyl, phenyl, p-tert-butylphenyl, m-tert-butylphenyl, 1, 1′-biphenyl, p-trifluoromethylphenyl, or the corresponding deuterated derivative thereof.

Preferably, R₂, R₃, and R₄ are independently selected from the group consisting of: hydrogen, deuterium, fluorine, cyano, C₁₋₆ alkyl, C₁₋₆ fluoroalkyl, and substituted, unsubstituted C₆₋₁₀ aryl, or the corresponding deuterated derivative thereof. More preferably, R₂ is hydrogen, tert-butyl, trifluoromethyl, or phenyl, and additionally or alternatively, R₃ and R₄ are independently hydrogen, tert-butyl, trifluoromethyl, phenyl.

Optionally, when X₁ and X₄ are N, X₁ and X₃ are N, or X₂ and X₄ are N, R₃ and R₄ are different from each other. When X₁ and X₄ are N, one of R₃ and R₄ may be tert-butyl, while the other one of R₃ and R₄ may be hydrogen, trifluoromethyl, phenyl, or aryl.

Optionally, the metal complex is a homoleptic metal complex, where all ligands are identical.

Optionally, the metal complex is a tris-bidentate metal complex with two pairs of two adjacent L², L³, L⁴, and L⁵ identical to L¹, or a tris-bidentate metal complex with only one pair of two adjacent L², L³, L⁴, and L⁵ identical to L¹.

Optionally, the metal complex comprises a facial isomer or a meridional isomer.

Most preferably, the metal complex is selected from one of the following:

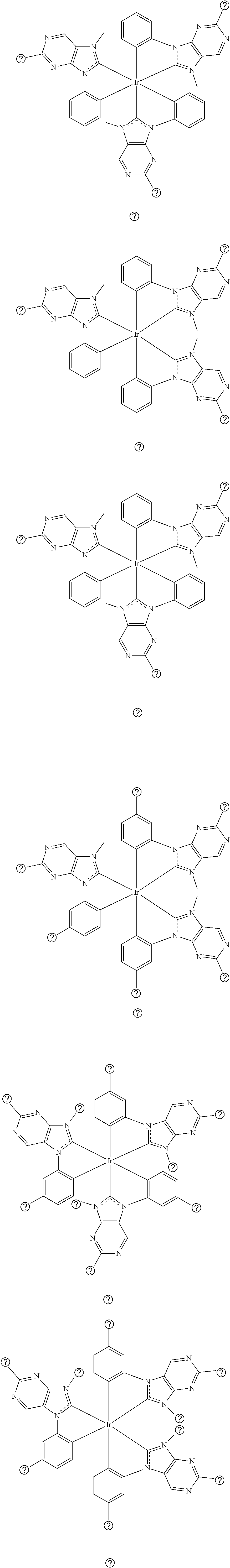

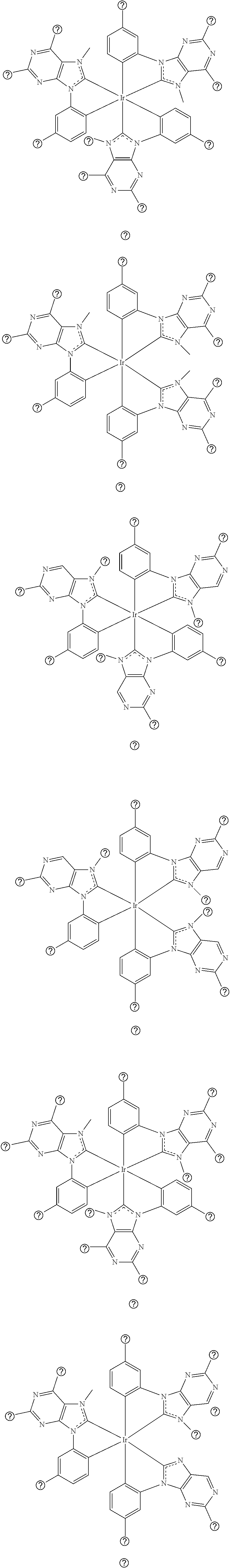

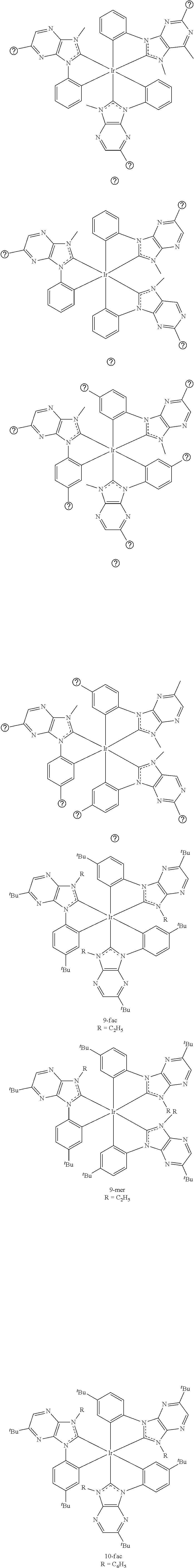

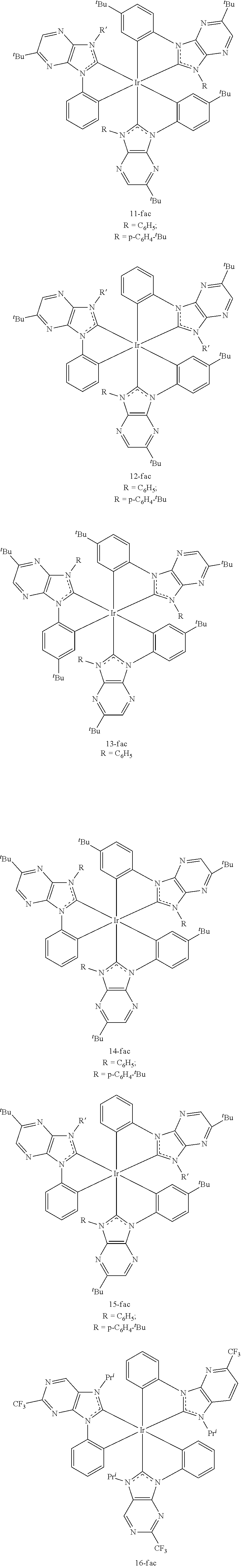

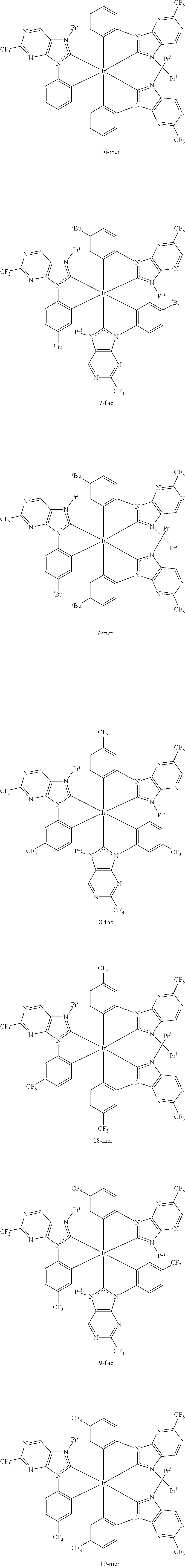

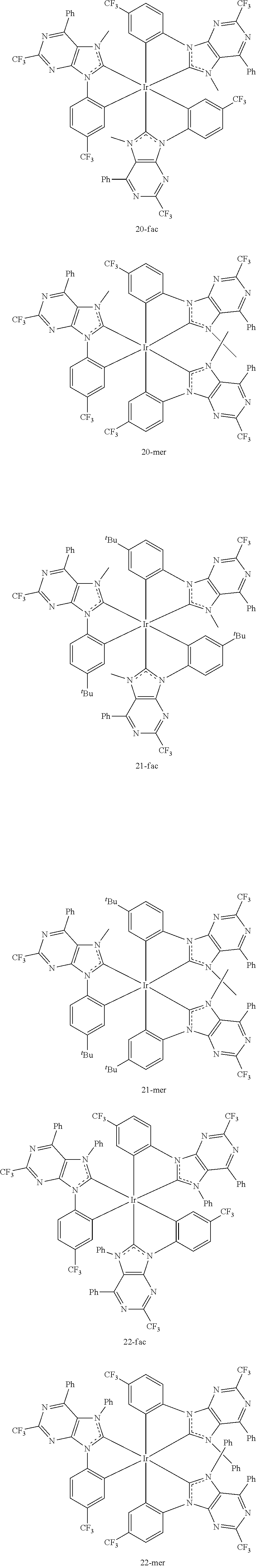

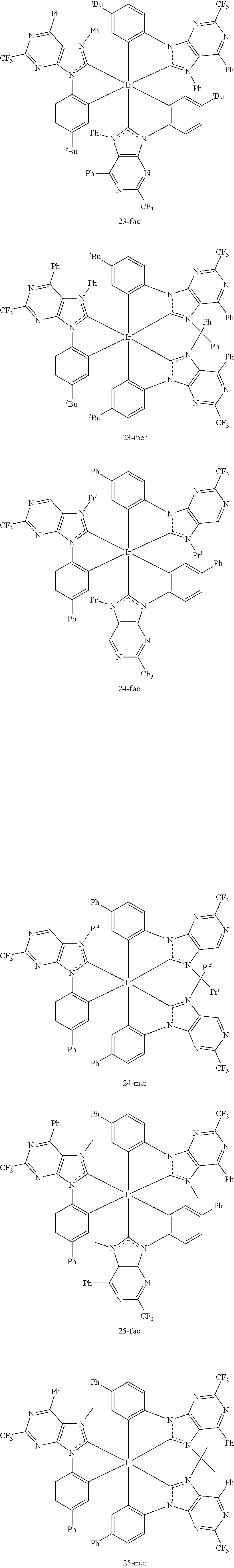

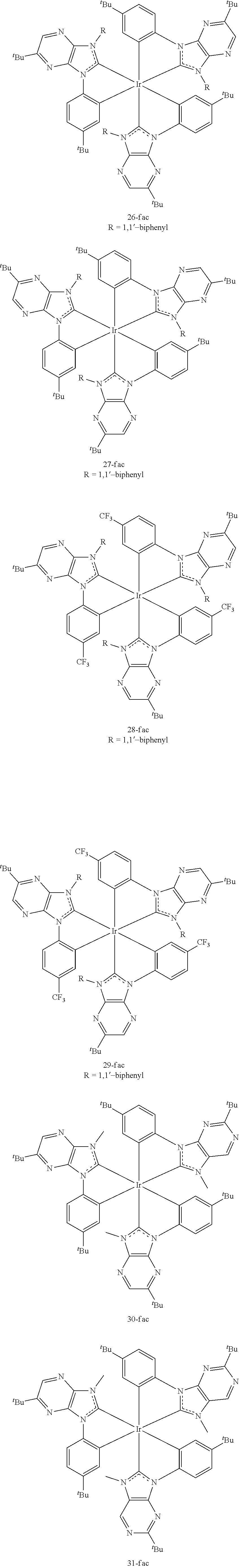

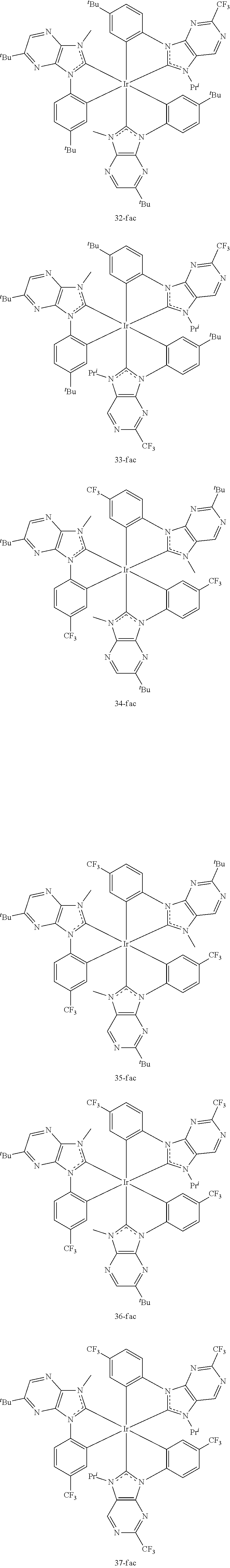

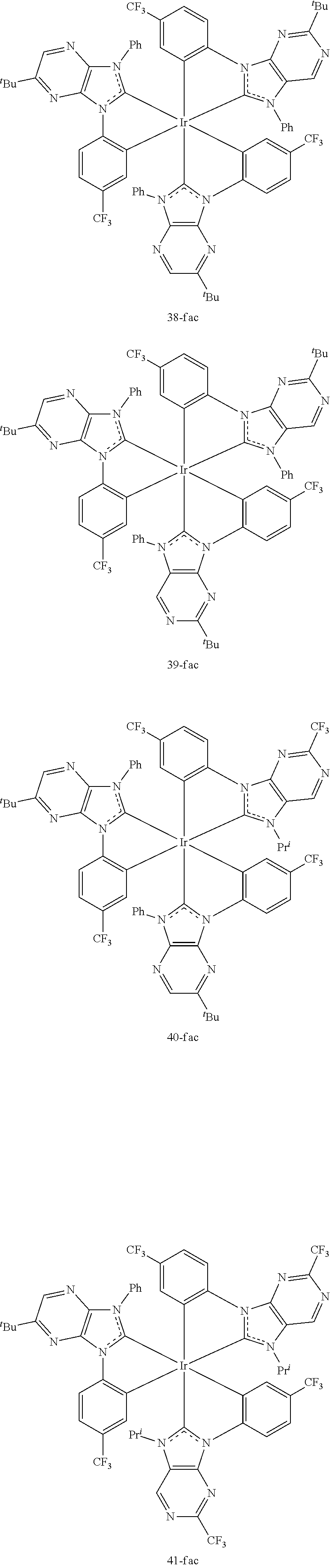

In a second aspect, the present invention provides a method of preparing a metal complex. The metal complex may be the metal complex in the first aspect.

The method comprises the steps of: forming a chelating agent from a reagent selected from the group consisting of: forming a chelating agent from a reagent selected from the group consisting of: a pyrimidone-based reagent, a pyrimidineamine-based reagent, a pyrimidinediol-based reagent, and a pyrazinecarbonitrile-based reagent, and mixing the chelating agent and a metal reagent to form the metal complex.

The chelating agent may be a functional 9H-purin-7-ium derivative, a CF₃-substituted 9H-purin-7-ium derivative, or an imidazo[4,5-b]pyraz-3-ium derivative. The metal reagent may be IrCl₃(tht)₃.

In a third aspect, the present invention provides a light emitting device (e.g. a phosphorescent organic light-emitting diode) comprising an emissive layer having a metal complex. The metal complex may be the metal complex in the first aspect or a metal complex prepared using the method in the second aspect. The emissive layer may be arranged to emit light with a wavelength in the range of 420-565 nm, preferably in the range of 420-490 nm.

### BRIEF DESCRIPTION OF THE DRAWINGS

Embodiments of the invention will now be described, by way of example, with reference to the accompanying drawings, in which:

FIG. 1 shows the potential energy surface diagram of a hypothetical Ir(C^N)₃ or Ir(C^N)₂(L^X) complex;

FIG. 2 shows the potential energy surface diagram of a hypothetical Ir(C^C)₃ complex;

FIG. 3 shows the crystal structural drawing of 1-mer;

FIG. 4 shows the UV-Vis absorption and photoluminescence spectra of different purin-8-ylidene-based Ir(III) metal complexes in toluene at room temperature;

FIG. 5 is a schematic diagram of energy level alignments of OLEDs containing a purin-8-ylidene-based Ir(III) metal complex;

FIG. 6 shows the normalized electroluminescence spectra of a 2-mer-based OLED and a 2-fac-based OLED;

FIG. 7 is a graph showing the current density-voltage-luminance (J-V-L) characteristics of the 2-mer-based OLED and the 2-fac-based OLED;

FIG. 8 is a graph showing the current density-luminance-external quantum efficiency (EQE) of the 2-mer-based OLED and the 2-fac-based OLED;

FIG. 9 is a schematic diagram of hyperphosphorescent OLED containing a purin-8-ylidene-based Ir(III) metal complex;

FIG. 10 shows the transient photoluminescence (PL) decay curves of the light emitting layer of an OLED with different doping contents of 2 -mer;

FIG. 11 shows the electroluminescent spectrum of a 2-mer-based OLED;

FIG. 12 is a graph showing the current density-voltage-luminance (inset) and current efficiency-luminance-EQE curves of the 2-mer-based OLED;

FIG. 13 shows the crystal structural drawing of 5S-fac;

FIG. 14 shows the UV-Vis absorption and photoluminescence spectra of different purin-8-ylidene-based Ir(III) metal complexes in toluene at room temperature;

FIG. 15 shows the crystal structural drawing of 8-fac;

FIG. 16 shows the UV-Vis absorption and photoluminescence spectra of different imidazo[4,5-b]pyrazin-2-ylidene-based Ir(III) metal complexes in toluene at room temperature;

FIG. 17 is a schematic diagram of energy level alignments of the solution-processed OLED containing an imidazo[4,5-b]pyrazin-2-ylidene-based Ir(III) metal complex;

FIG. 18 shows the normalized electroluminescent spectra of a 9-fac-based OLED at different doping levels;

FIG. 19A is a graph showing the current density against the applied voltage of the 9-fac-based OLED at different doping levels;

FIG. 19B is a graph showing the luminance against the applied voltage of the 9-fac-based OLED at different doping levels;

FIG. 20A is a graph showing the current efficiency against the applied current density of the 9-fac-based OLED at different doping levels;

FIG. 20B is a graph showing the power efficiency against the applied current density of the 9-fac-based OLED at different doping levels;

FIG. 20C is a graph showing the external quantum efficiency against the applied current density of the 9-fac-based OLED at different doping levels;

FIG. 21 shows the normalized electroluminescent spectra of the OLEDs based on the sensitizers 8-fac and 9-fac and the narrow bandwidth emitter BCzBN;

FIG. 22A is a graph showing the current density against the applied voltage of the OLEDs based on the sensitizers 8-fac and 9-fac and the narrow bandwidth emitter BCzBN;

FIG. 22B is a graph showing the luminance against the applied voltage of the OLEDs based on the sensitizers 8-fac and 9-fac and the narrow bandwidth emitter BCzBN;

FIG. 23A is a graph showing the current efficiency against the applied current density of the OLEDs based on the sensitizers 8-fac and 9-fac and the narrow bandwidth emitter BCzBN;

FIG. 23B is a graph showing the power efficiency against the applied current density of the OLEDs based on the sensitizers 8-fac and 9-fac and the narrow bandwidth emitter BCzBN; and

FIG. 23C is a graph showing the external quantum efficiency against the applied current density of the OLEDs based on the sensitizers 8-fac and 9-fac and the narrow bandwidth emitter BCzBN.

### DETAILED DESCRIPTION

Before any embodiments of the invention are explained in detail, it is to be understood that the invention is capable of other embodiments and of being practiced or of being carried out in various ways. Also, it is to be understood that the phraseology and terminology used herein is for the purpose of description and should not be regarded as limiting. Terms of degree, such as “about” or “approximately” are understood by those of ordinary skill to refer to reasonable ranges outside of the given value, for example, general tolerances associated with manufacturing, assembly, and use of the described embodiments.

The inventors have, through their own research, trials and experiments, devised that N-heterocyclic carbene-based (NHC-based) Ir(III) complexes constitute an optimal design for efficient blue phosphors for use in OLEDs.

The heavy atom effect of third-row transition-metal complexes (e.g. Ir(III) complexes) can often induce a fast spin-orbit coupling that, in turn, promotes facile and electro-generated singlet-to-triplet transition and efficient phosphorescence with shortened radiative lifetime, resulting in promising phosphors.

Emission color of Ir(III) complexes can be fine-tuned across all visible spectral region by: (i) introduction of greater (or reduced) π-conjugation on the chromophoric segment, which causes red (or blue) shifted emission, (ii) addition of electron-withdrawing (or donating) group on the segment that dominates the highest occupied molecular orbitals (HOMO) of molecule, which induces blue (or red) shifting, and (iii) functionalization of electron-withdrawing (or donating) group on the segment that dominates the lowest unoccupied molecular orbitals (LUMO), which offers red (or blue) shifting. Moreover, strong spin-orbital coupling facilitated by the iridium atom gives efficient intersystem crossing between the singlet and triplet excited states, facilitating nearly 100% internal conversion efficiency, which is beneficial for fabrication of efficient OLEDs.

NHCs are highly versatile ligands with unique features that are capable to engage into robust metal-ligand bonds, owing to their strong a-donating and relatively weak π-accepting abilities. NHCs such as functional imidazolylidene and benzoimidazolylidene cyclometalates, can be used for the synthesis of higher energy (i.e., purple and blue) emitters, due to the strongly destabilized π*-orbitals of carbene (C^C) chelates. These carbene complexes can involve either bidentate or tridentate pincer designs, to which their key function is to increase the crystal field strength of resulting metal complexes and to mitigate the thermal population to their upper lying MC dd excited states for achieving better luminescence.

Particularly, the class of homoleptic, tris-bidentate Ir(III) complexes Ir(C^C)3 possess the following practical advantages, namely: (i) possession of the third-row transition metal ion at 3+ oxidation state, (ii) possession of six iridium-carbon (e.g.; both Ir—C_{carbene} and Ir—C_{aryl}) bonds which could exert the strongest ligand field strength and notably destabilize the corresponding MC dd excited states, and (iii) adoption of higher lying LUMO orbital on the coordinative carbene fragments. Among these intrinsic properties, points (i) and (ii) are especially important for effective destabilization of MC dd excited states which reduces the relatively rate of nonradiative decay processes, thereby giving improved thermal and photo stabilities and thus emission efficiency. Point (iii) is essential for achieving the true blue and blue emission of the widened HOMO-LUMO energy gap. Hence, this coordination mode is expected to offer a sufficient large energy-gap between the emissive excited state (Ti state) and upper lying MC dd excited state, giving a suppressed quenching process, even for blue emitters.

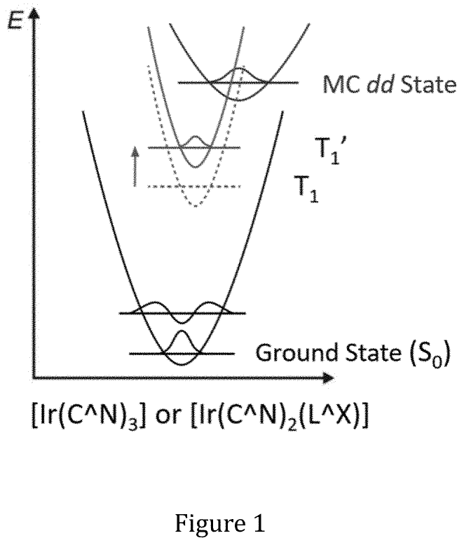

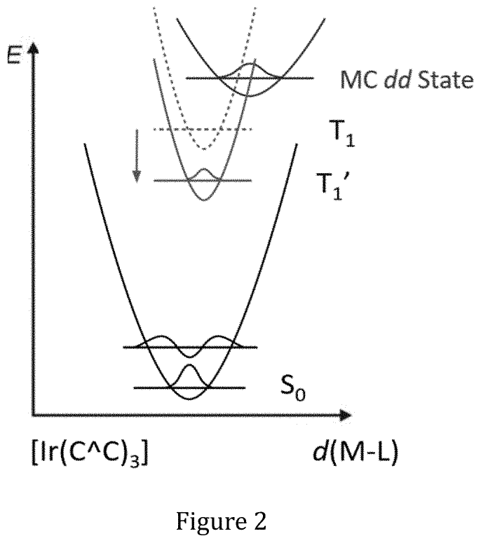

FIG. 2 shows the potential energy surface diagram of a hypothetical Ir(C^C)₃ complex, as exemplified by purple emitting tris(1-phenyl-3-methylbenzimidazolin-2 -ylidene-C,C²′)iridium(III), [Ir(pmb)₃]. Different from that of the hypothetical Ir(C^C)₃ or Ir(C^N)₂(L^X) complex (FIG. 1), tuning emission from purple [Ir(pmb)₃] and derivatives to a pure blue emitter required stabilization of the initial T₁ state in giving a new state of lowered energy. Hence, the enlarged T₁′-MC dd state separation would retard the thermally activated non-radiative decay. This offers an important advantage for blue emissive [Ir(C^C)₃] complexes, if all other factors, such as inherent stability of chelate and metal-chelate bond strength, remain substantially the same.

In one embodiment, the metal complex comprises a structure of Formula

ML¹ₐL²_{b}L³_{c}L⁴_{d}L⁵ₑ (I),

where:
M is a transition metal;
L¹ is a bidentate ligand and a is an integer of 1 to 3;
L², L³, L⁴, and L⁵ are independently a monodentate ligand, or two adjacent L², L³, L⁴, and L⁵ is a bidentate ligand, and b, c, d, and e are independently an integer of 0 to 4;
a+b+c+d+e is 2, 3, 4, or 5; and
L¹ has a structure of Formula (II):

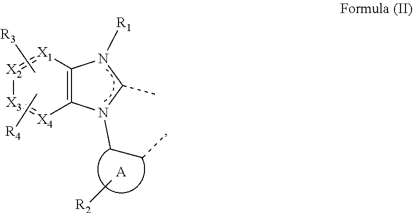

where:
A is a 5-membered or 6-membered carbocyclic or heterocyclic ring,
R₁ is selected from the group consisting of: C₁₋₆ alkyl, C₂₋₆ alkylether, C₁₋₆ alkoxy, C₁₋₆ fluoroalkyl, C₂₋₆ alkenyl, C₂₋₆ alkynyl, substituted or unsubstituted C₃₋₈ cycloalkyl, substituted or unsubstituted C₃₋₈ cycloalkenyl, substituted or unsubstituted 3 to 8 membered heterocycloalkyl, substituted or unsubstituted 3 to 8 membered heterocycloalkenyl, substituted or unsubstituted C₆₁₀ aryl, substituted or unsubstituted C₇₋₁₁ aralkyl, substituted or unsubstituted heteroaryl having 5 to 10 carbon atoms or heteroatoms, and substituted or unsubstituted heteroaralkyl having 6 to 11 carbon atoms or heteroatoms, preferably methyl, ethyl, propyl, phenyl, p-tert-butylphenyl, m-tert-butylphenyl, 1, 1′-biphenyl, p-trifluoromethylphenyl, or the corresponding deuterated derivative thereof;
R₂, R₃, and R₄ are independently selected from the group consisting of: hydrogen, deuterium, fluorine, cyano, C₁₋₆ alkyl, C₁₋₆ alkoxy, C₁₋₆ fluoroalkyl, substituted or unsubstituted C₆₋₁₀ aryl, and substituted or unsubstituted heteroaryl having 5 to 10 carbon atoms or heteroatoms, preferably hydrogen, deuterium, fluorine, cyano, C₁₋₆ alkyl, C₁₋₆ fluoroalkyl, and substituted, unsubstituted C₆₋₁₀ aryl, or the corresponding deuterated derivative thereof, and
two of X₁, X₂, X₃, and X₄ are C, and the other two of X₁, X₂, X₃, and X₄ are N.

As used herein, “the corresponding deuterated derivative thereof” refers to any of the aforementioned functional groups with at least one hydrogen atom substituted by deuterium.

The metal complex is preferably a tris-bidentate metal complex. M is selected from the group consisting of: iridium, rhodium, platinum, palladium, gold, osmium, and ruthenium. Preferably, M is iridium, platinum, or gold. A is preferably a phenyl ring. R₂ is hydrogen, trifluoromethyl, phenyl or tert-butyl. R₃ and R₄ are independently hydrogen, tert-butyl, trifluoromethyl, or phenyl. In a preferred embodiment, when X₁ and X₄ are N, X₁ and X₃ are N, or X₂ and X₄ are N, R₃ and R₄ are different.

As will be known by the skilled person based on the above disclosure, when the metal complex is an Ir(III) complex, the ligands occupy an octahedral arrangement around the Ir(III) metal center. The three ligands of the same type can occupy either the corners of one face of the octahedron (facial isomer (fac-isomer)) or a meridional positions, i.e. two of the three ligand bonding points are in trans positions relative to one another (meridional isomer (mer-isomer)). “f-” and “fac-” and “m” and “mer-” are used interchangeably herein to refer to “facial” and “meridional” respectively. The metal complex may be predominantly or exclusively a single isomer, or it may be a mixture of isomers. Where the metal complex is a mixture of isomers, it may be any mixture.

In some embodiment, when the metal complex is a homoleptic Ir(III) carbene complex, it may include N-phenyl, N-methyl-imidazol-2-ylidene (pmi) or N-phenyl, N-methyl-benzimidazol-2-ylene (pmb) chelate. To red-shift emission, N-phenyl cyclometalating fragment can be replaced with aromatic entities with greater π-conjugation. However, this modification would unavoidably increase both the ligand-centered ππ* contribution and radiative lifetime at the excited states and, hence, is less desirable.

In contrast, to blue-shift emission, functional 7,9-dihydro-8H-purin-8-ylidene, imidazo [4,5-b]pyridin-2 -ylidene (pmp) and imidazo [4,5-b]pyrazin-2 -ylidene (pmpz, cb and tpz) chelates can be used to synthesize true-blue Ir(III) carbene complexes, among which the introduced nitrogen atom can effectively lower the LUMO energy level and maintain a higher degree of metal-to-ligand charge transfer (MLCT) characters. Notably, these homoleptic Ir(III) complexes exist as both the facial (fac) and meridional (mer) isomers, with fac-isomers always exhibit more blue shifted emission wavelength compared to mer-isomers. Hence, isomerization can also be employed for further widening the photophysical landscape.

Therefore, in preferred embodiments, pyrimidineimidazolylidene and pyrazineimidazolylidene are preferred over 2,3-dihydro-1H-imidazolylidene, benzoimidazolylidene, imidazolylidene, and imidazo[4,5-b]pyridin-2-ylidene for reducing the respective LUMO energy level in achievement of the desired true blue emission and capability in fabrication of OLEDs. It is expected that, with proper adjustment of both the electronic and steric properties of the NHC chelates, the needed efficient true-blue emission, together with considerably shortened radiative lifetime to the microsecond and hundredth nanosecond region can be achieved. These photophysical characters are of particular importance as the shorter radiative lifetime, the less emission quenching would occur at the higher driving voltages during operation. Not to mentioned that, faster radiative decay would improve stability of emitters due to the reduced residence time at the highly energized excited states after excitation.

In the most preferred embodiment, the metal complex is selected from one of the following:

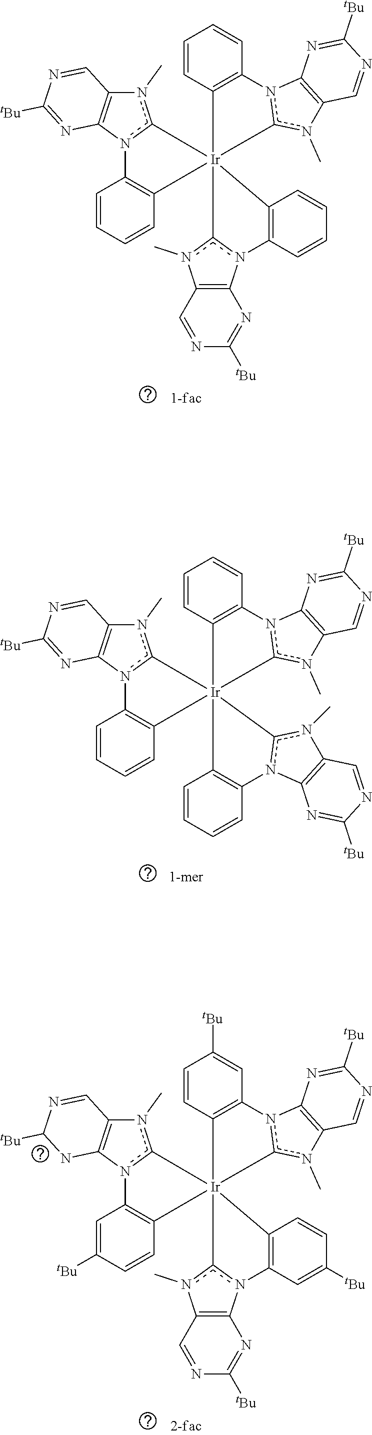

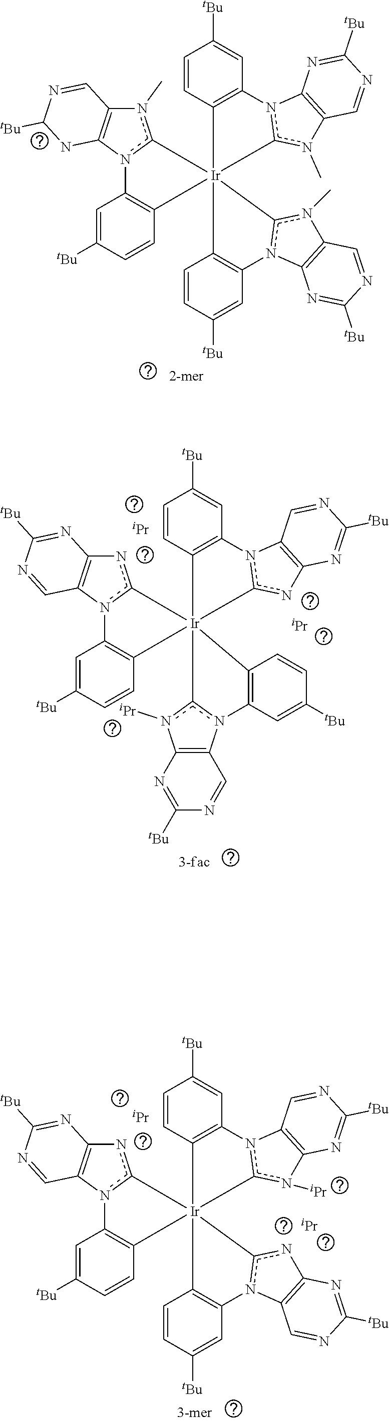

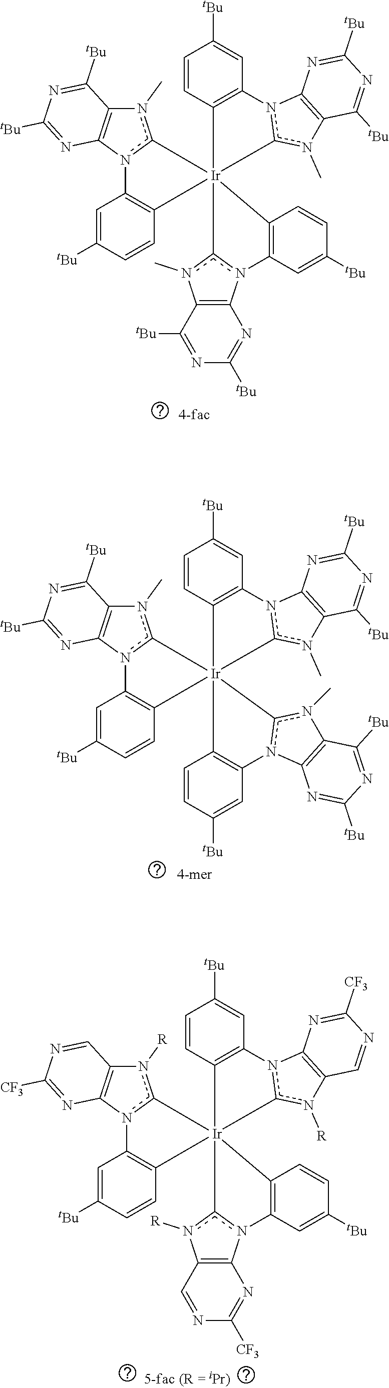

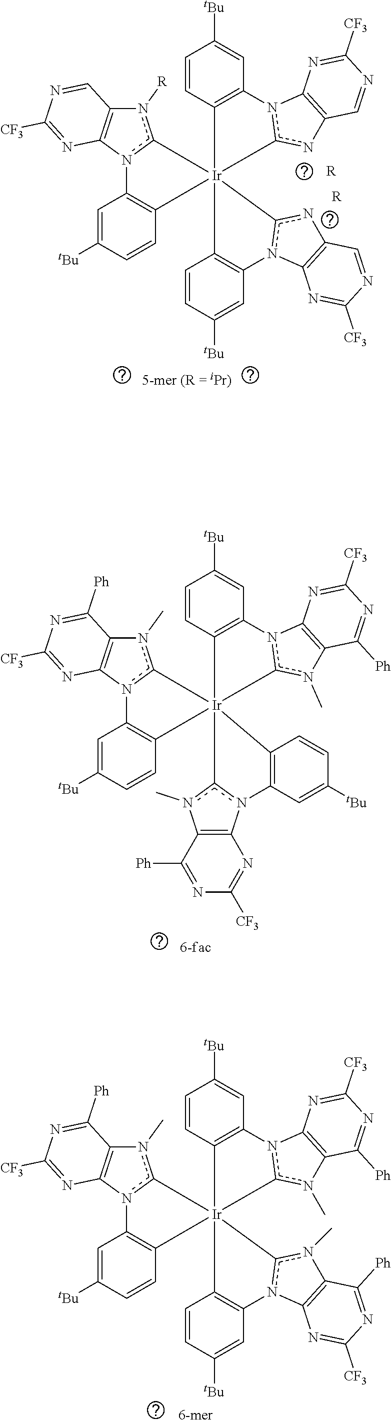

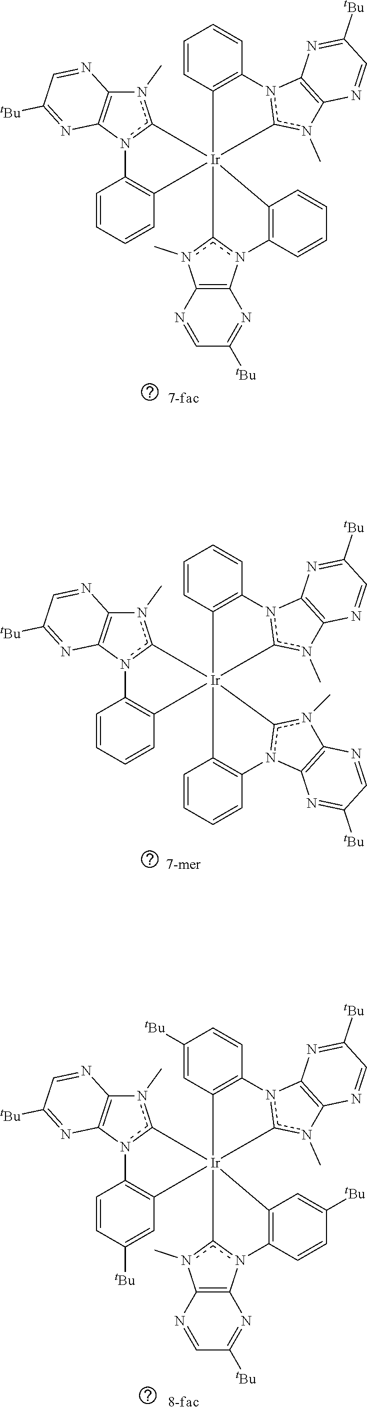

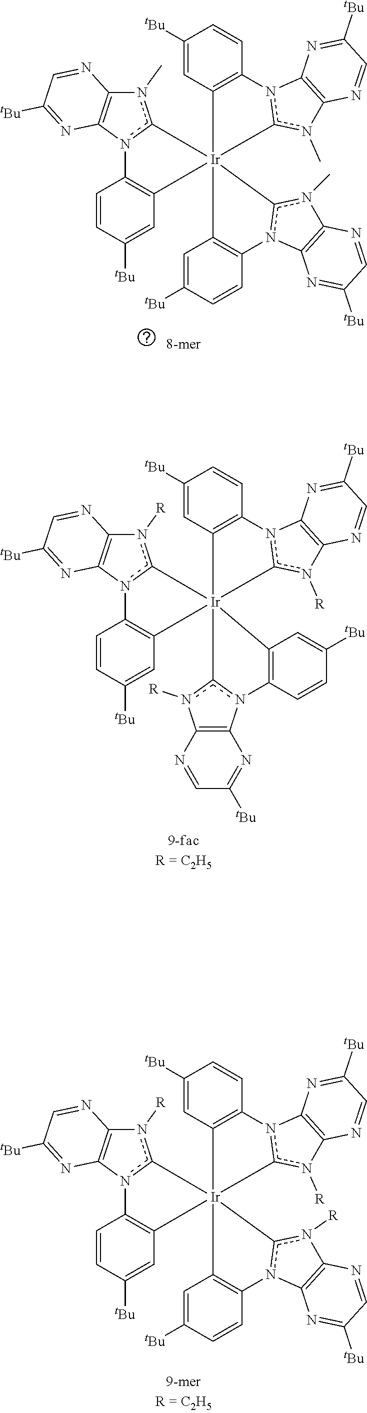

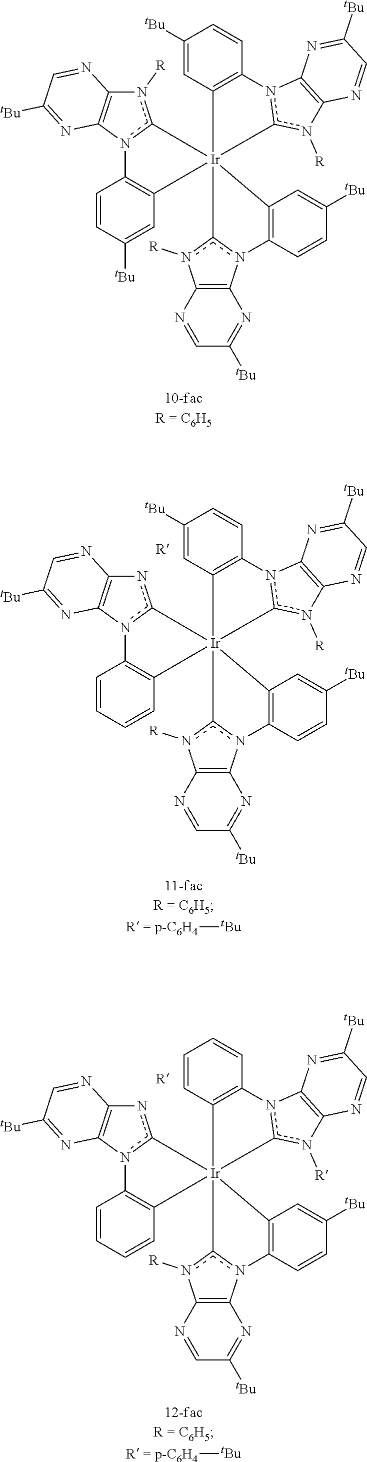

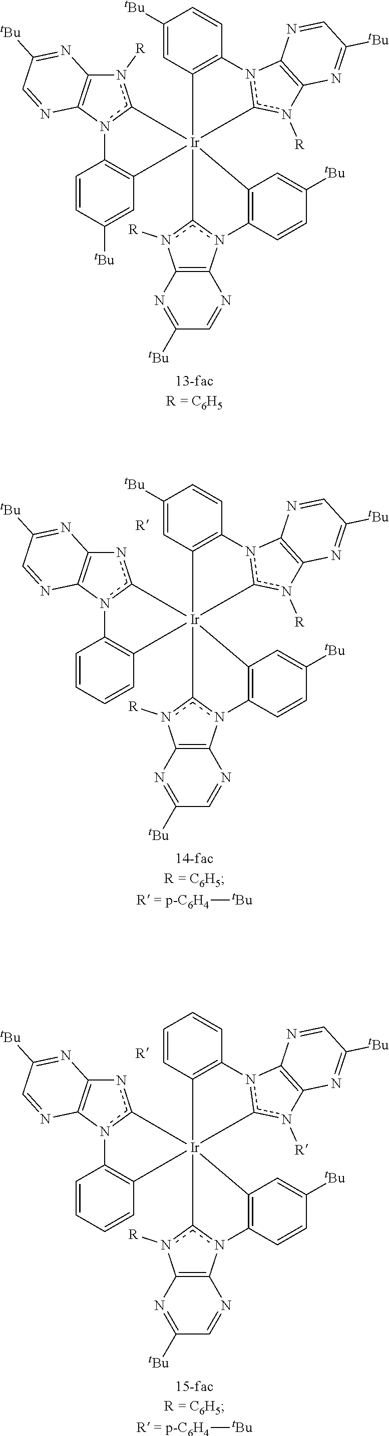

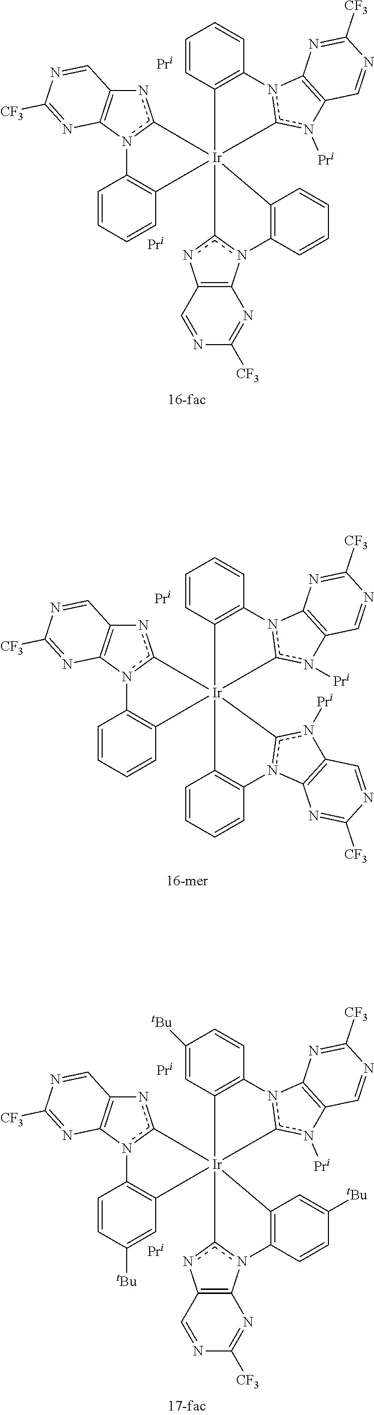

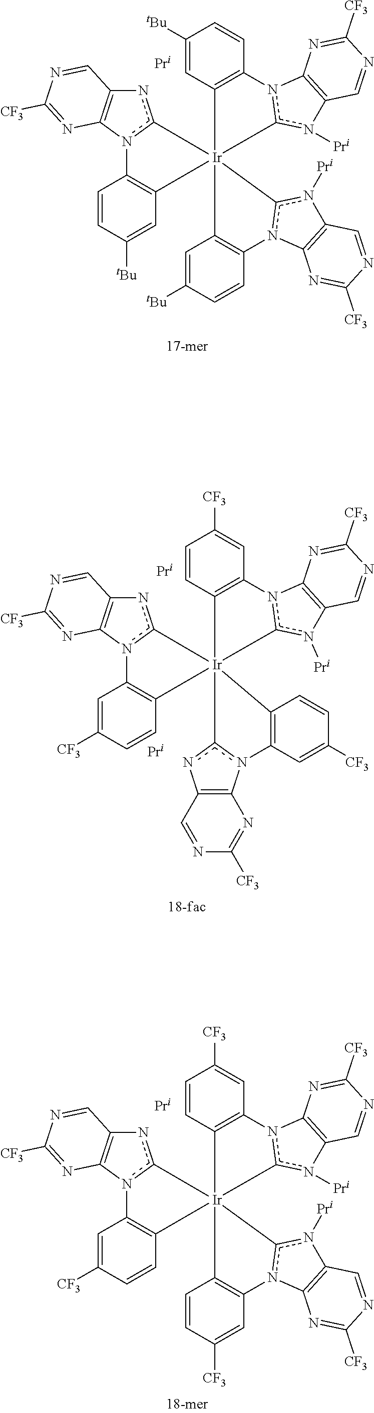

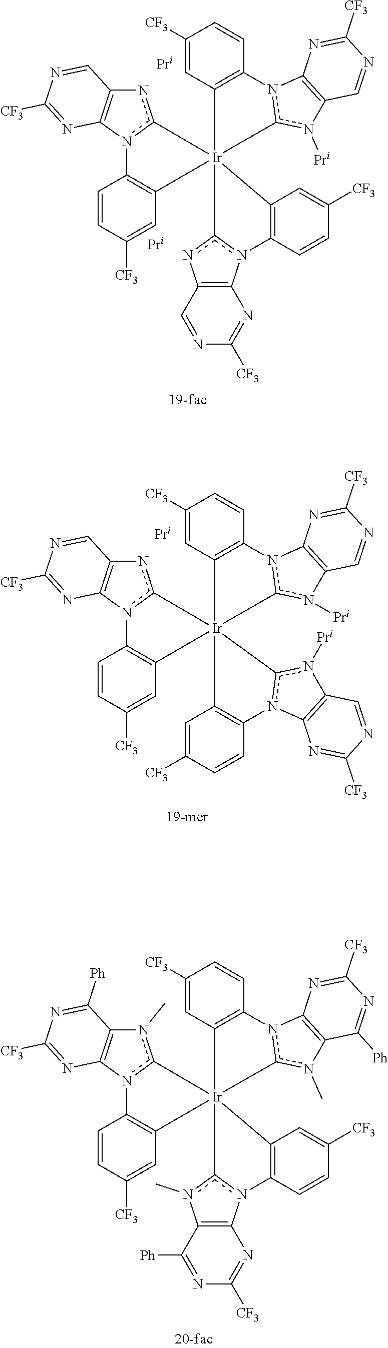

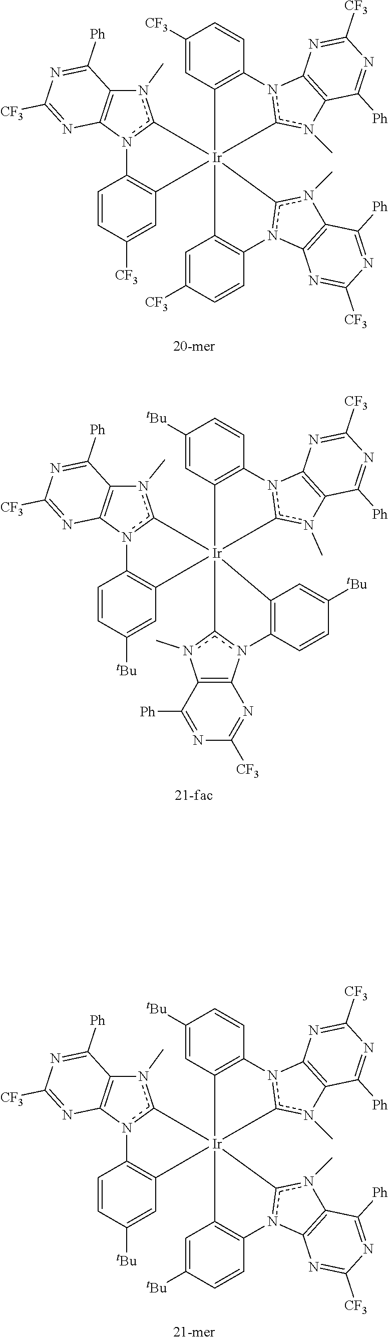

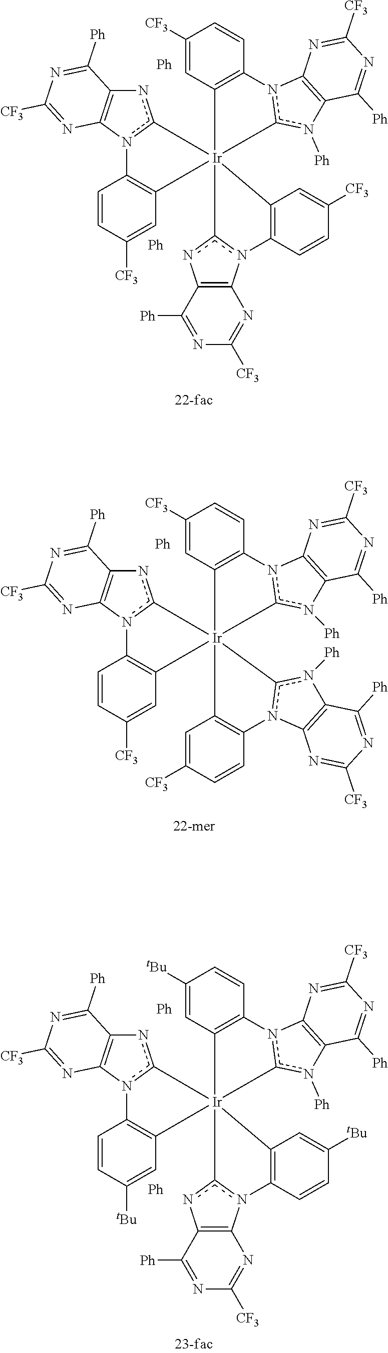

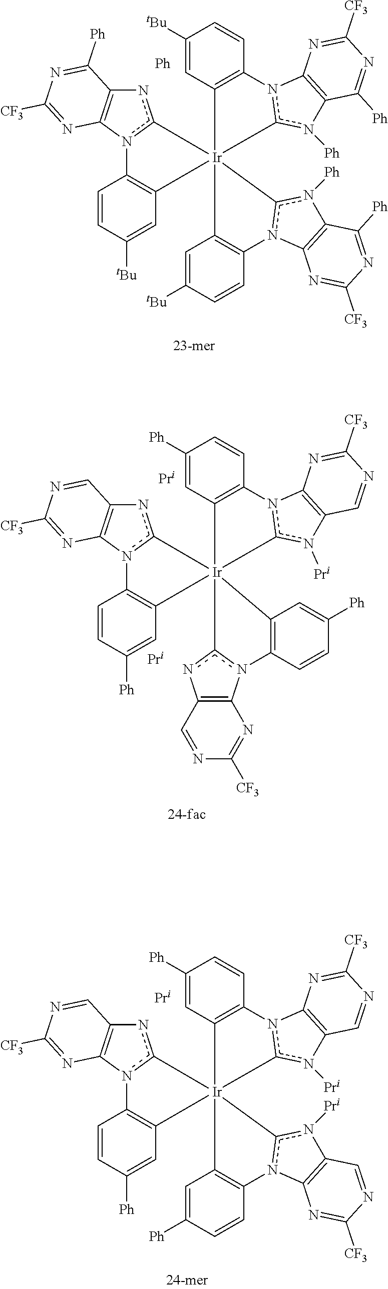

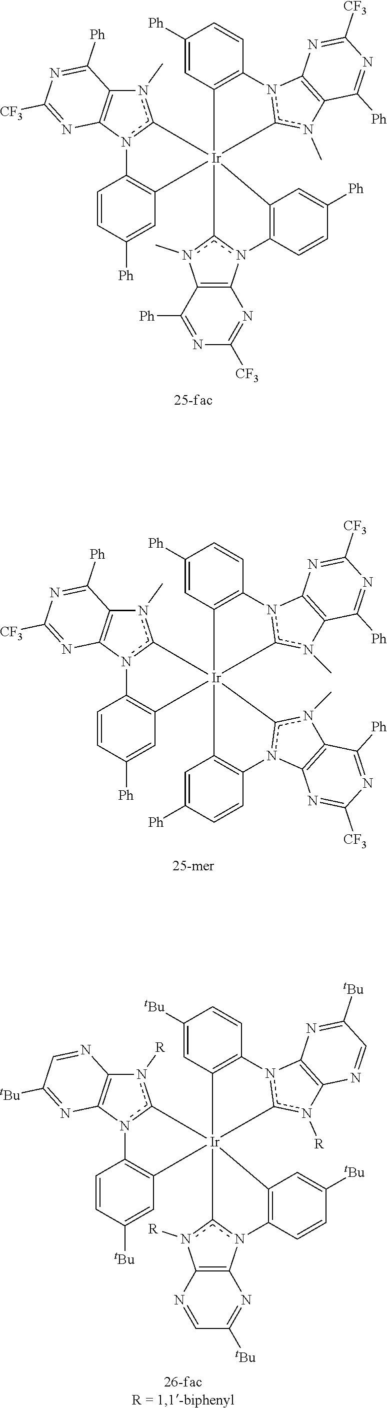

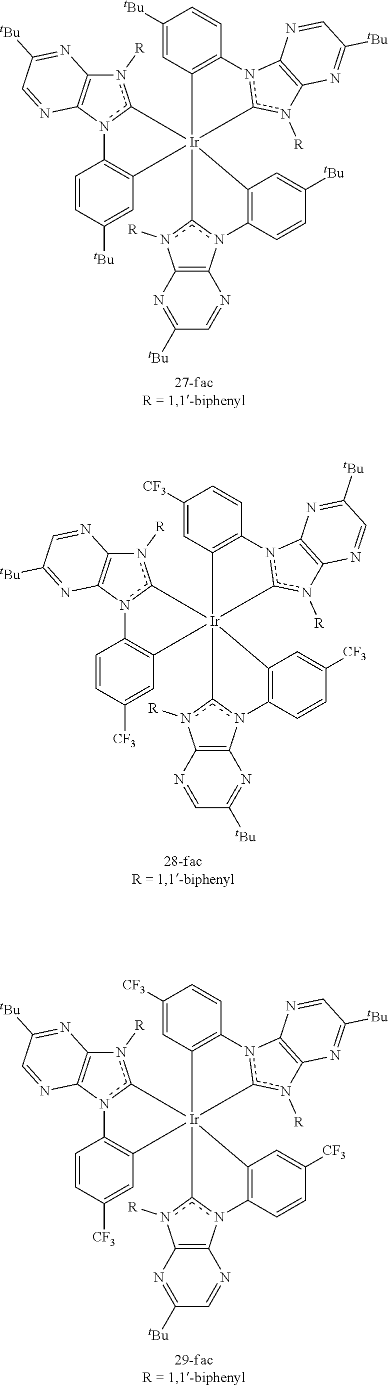

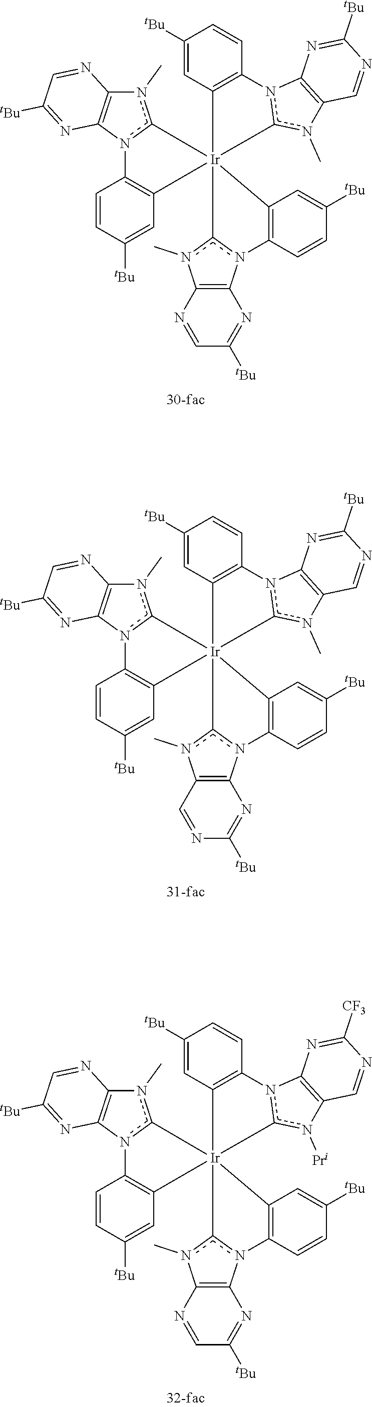

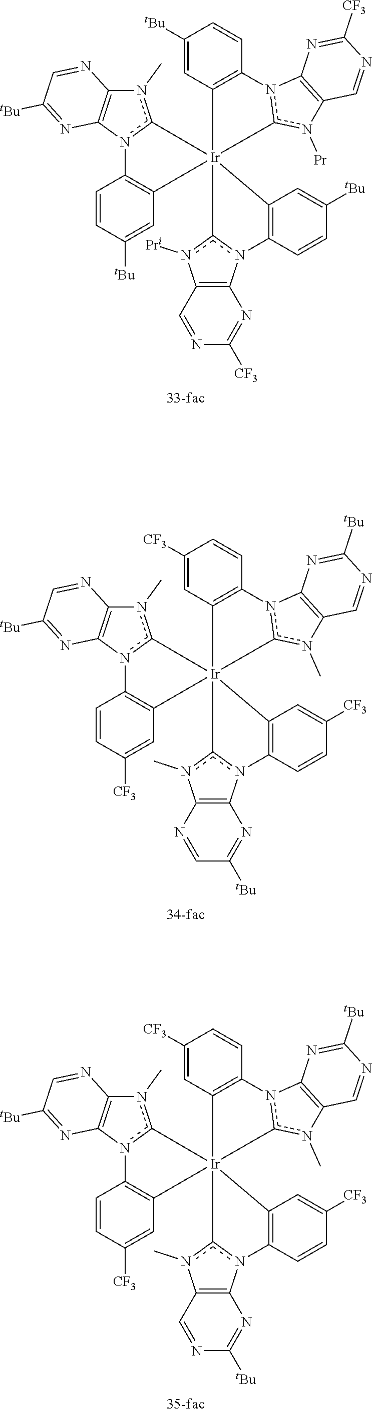

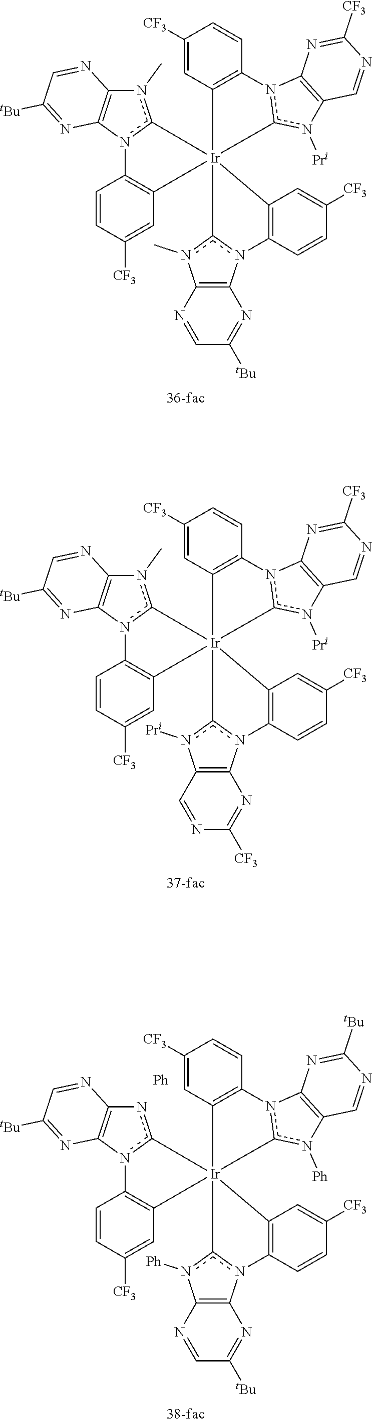

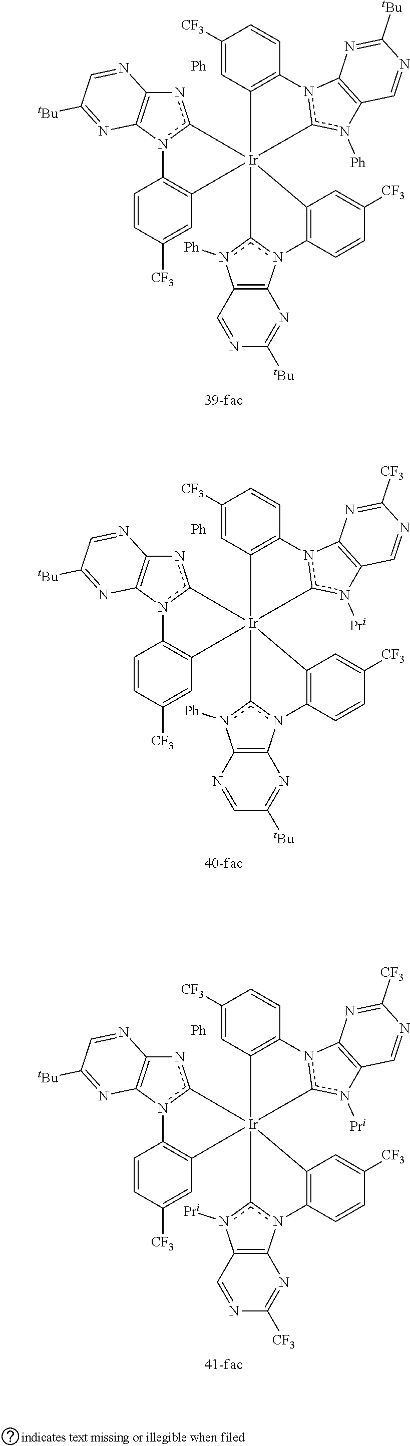

As shown above, the preferred chelates are based on (7,9-dihydro-8H-purin-8-ylidene) and (1,3 -dihydro-2 H-imidazo [4,5 -b]pyrazin-2 -ylidene), which differ in the relative position of nitrogen atoms, to which the electron negative nitrogen can lower the LUMO of the ligand-centered π-orbital, giving the required blue-emission and shortened radiative lifetimes.

Due to the difficulty in design of suitable chelates and Ir(III) phosphors, only the preparation 1,3-diaryl-(1,3 -dihydro-2H -imidazo [4,5-b]pyrazin-2-ylidene) chelates with symmetrically arranged N-substituted aryl groups on the imidazolylidene coordination unit has been reported. As a result, if substituents R₃ and R₄ in Formula (II) on the pyrazinyl fragment were different, i.e. R₃≠R₄, it will unavoidably produce a mixture of inseparable isomers upon formation of Ir(III) phosphors, giving unpredicted and inferior properties on material processing.

The method of preparing the metal complex in the present invention comprises the steps of: forming a chelating agent from a reagent selected from the group consisting of: a pyrimidone-based reagent, a pyrimidineamine-based reagent, a pyrimidinediol-based reagent, and a pyrazinecarbonitrile-based reagent, and mixing the chelating agent and a metal reagent to form the metal complex. “Chelating agent” and “pro-chelate” may be used interchangeably herein to refer to the compound that react with the metal ion to form a complex, preferably a charge neutral complex. “Metal reagent” as used herein refers to the material which provides the metal ion required for formation of the complex.

The metal reagent may be IrCl₃(tht)₃. The step of mixing the chelating agent and the metal reagent comprises heating the chelating agent, the iridium reagent, and a promoter (e.g. sodium acetate or potassium acetate) to reflux. As will be appreciated by those skilled in the art, “promoter” as used herein refers to a substance added to a catalyst to improve its performance in a reaction. The promoter may have little or no catalytic effect.

The chelating agent may be a 9H-purin-7-ium derivative, a CF₃-substituted 9H-purin-7-ium derivative, or an imidazo[4,5-b]pyraz-3-ium derivative.

In the embodiment where the chelating agent is a 9H-purin-7-ium derivative, the pyrimidone-based reagent is 2-pyrimidone or 2-(tert-butyl)pyrimidin-4(3H)-one. Also, the step of forming the chelating agent comprises the step of: forming an N⁴-phenylpyrimidine-4,5-diamine derivative from the pyrimidone-based reagent. The step of forming the N⁴-phenylpyrimidine-4,5-diamine derivative includes the steps of: conducting nitrosation and subsequent chlorination of the pyrimidone-based reagent to form a chloro-nitro-primidone derivative, substituting the chloro group of the chloro-nitro-primidone derivative with aniline and performing reduction of the nitro group to form the N⁴-phenylpyrimidine-4,5-diamine derivative. The step of forming the chelating agent may further includes the steps of performing cyclization of the N⁴-phenylpyrimidine-4,5-diamine derivative and treating with a triflating agent or an iodonium reagent to form the 9H-purin-7-ium derivative. The triflating agent may be methyl triflate or ethyl triflate, while the iodonium reagent may be diphenyliodonium and relevant functional derivatives.

In contrast to the typical synthetic protocol that involved the in-situ generation of silver-carbene intermediate, the reaction condition in the this embodiment required no such expensive silver salt and, hence, is very cost effective, together with another advantage of having improved product yields.

In the embodiment where the chelating agent is a CF₃-substituted 9H-purin-7-ium derivative, the pyrimidineamine-based reagent is a 2-(trifluoromethyl)pyrimidin-5-amine derivative. Also, the step of forming the chelating agent comprises: conducting bromination of the pyrimidineamine-based reagent to form a bromo-2-(trifluoromethyl)pyrimidin-5-amine derivative, treating the bromo-2-(trifluoromethyl)pyrimidin-5-amine derivative with aniline to form a N⁴-phenyl-2-(trifluoromethyl)pyrimidine-4,5-diamine derivative, and performing cyclization of the N⁴-phenyl-2-(trifluoromethyl)pyrimidine-4,5-diamine derivative to form the CF₃-substituted 9H-purin-7-ium derivative.

In another embodiment where the chelating agent is a CF₃-substituted 9H-purin-7-ium derivative, the pyrimidinediol reagent is a 2-(trifluoromethyl)pyrimidin-4, 6-diol derivative. The step of forming the chelating agent comprises: conducting nitration and subsequent chlorination of the pyrimidinediol-based reagent to form a chloro-nitro-2-(trifluoromethyl)pyrimidine derivative, substituting the chloro group of the chloro-nitro-2-(trifluoromethyl)pyrimidine derivative with aniline and conducting reduction of the nitro group of the chloro-nitro-2-(trifluoromethyl)pyrimidine derivative, to form a phenyl-2-(trifluoromethyl)pyrimidine-4,5-diamine derivative, and performing cyclization of the phenyl-2 itrifluoromethyl)pyrimidine-4,5 -diamine derivative and subsequent N-methylation to form the CF₃-substituted 9H-purin-7-ium derivative.

In the embodiment where the chelating agent is an imidazo[4,5-b]pyraz-3-ium derivative, the pyrazinecarbonitrile-based reagent is pyrazinecarbonitrile or tert-butylpyrazinecarbonitrile. Also, the step of forming the chelating agent comprises: performing Hofmann rearrangement of the pyrazinecarbonitrile-based reagent to form an amino-pyrazinecarbonitrile derivative, conducting bromination of the amino-pyrazinecarbonitrile derivative to form a bromo-amino-pyrazinecarbonitrile derivative, treating the bromo-amino-pyrazinecarbonitrile derivative with an orthoesther to form a formimidate derivative, performing condensation of the formimidate derivative with aniline to form a formamidine derivative, and conducting cyclization of the formamidine derivative and treatment with a triflating agent or iodonium reagent such as diphenyliodonium salt to form the respective imidazo[4,5-b]pyraz-3-ium derivative. Similar to the above embodiment, the triflating agent may be methyl triflate or ethyl triflate, while diphenyliodonium reagent can be either the symmetric or asymmetric derivatives.

This embodiment is different from the typical preparation method of the imidazo[4,5-b]pyraz-3-ium derivative, as shown in Scheme 1, which employs commercially available 3-chloropyrazin-2-amine as the starting material. After that, the sequential treatment with aniline at 110° C. for 24 hours (i), formic acid at 100° C. for 24 hours (ii), and methyl iodide and tetrahydrofuran at 65° C. (iii) afforded the demanded 1-methyl-3 -phenyl-1H -imidazo [4,5-b]pyrazin-1-ium iodide (5), which is contaminated with a by-product from possible methylation at the pyrazinyl N-atom.

An alternative typical preparation method is as follows. The symmetrically-arranged 1,3 -diphenyl-1H -imidazo [4,5-b]pyrazin-1-ium (6) or ethoxy-imidazopyrazine derivative (7) can be prepared from treatment of 2,3-dichloropyrazine with aniline at 110° C. for 24 hours (iv) in affording the N,N′-diphenylpyrazine-2,3-diamine, followed by reaction with triethyl orthoformate in the presence of ammonium iodide at room temperature for 12 hours (v) or with triethyl orthoformate in the presence of hydrogen chloride at 100° C. for 24 hours (vi), thereby forming an imidazolium fragment, to which the products are dependent to the catalyst and reaction temperature employed. However, unlike the method in the embodiment, these earlier approaches are only suitable in synthesizing symmetrically arranged pyrazine derivatives, but cannot afford the asymmetrically-arranged imidazo [4,5 -b]pyrazin-3 -ium derivatives discussed above. As the result, the synthesis using this asymmetric pro-chelate such as 6-(t-butyl)-1,3-diphenyl-1H-imidazo [4,5-b]pyrazin-3 -ium (8) with [Ir(COD) (μ-Cl)]₂ and xylene under reflux for 5 hours (i) can only afford a statistically distributed mixture of isomeric Ir(III) emitters [Ir(cb)₃], as shown in Scheme 2. The mixed products are expected to dexterously hamper the processability and reproducibility of the as-synthesized materials.

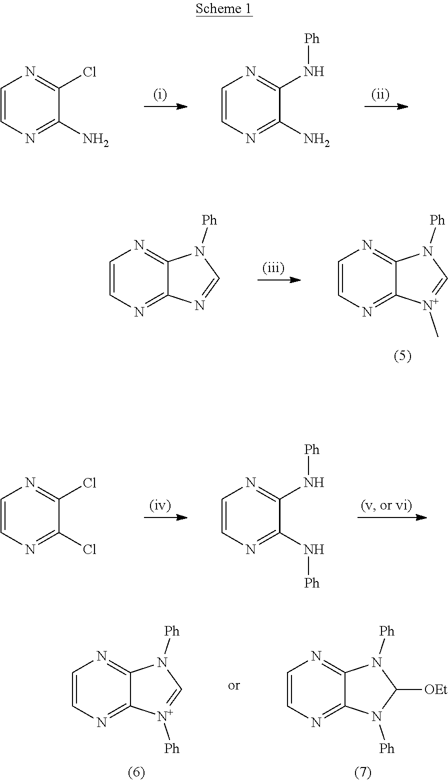

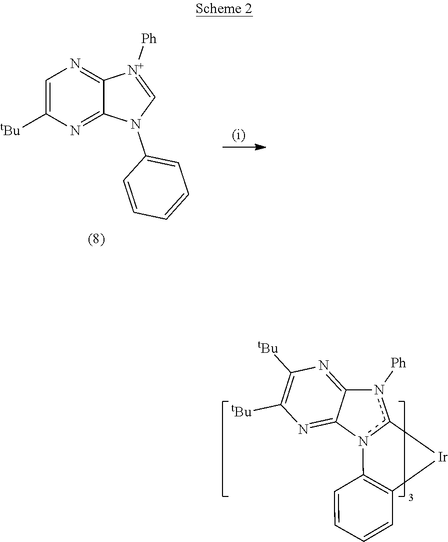

The metal complexes in the present invention may be used in a light emitting device, preferably an organic electronic device, for example, organic light-emitting diodes (OLED), light-emitting electrochemical cells (LEEC) and organic field-effect transistors (OFET). Preferably, the metal complex is used in an OLED, such as a phosphorescent OLED (PHOLED). Despite of the above-mentioned difficulty in producing the mixed Ir(III) phosphors with R₃ being tert-butyl and R₄ being H, from which the as-prepared OLED devices can still exhibit quite impressive photophysical performances. Therefore, the pure emitters (i.e. those without isomeric derivatives) in the present invention are expected to exhibit even better performance characteristics.

As known to those skilled in the art, OLEDs are considered as efficient and sustainable light sources and have already been used in both the display and lighting applications. It is usually a light-emitting diode (LED) in which the emissive electroluminescent layer is a film of organic compound which emits light in response to an electric current. This layer of organic semiconductor is usually situated between two electrodes. Generally, at least one of these electrodes is transparent. The metal complex may be present in any desired layer, preferably in the emissive electroluminescent layer (light-emitting layer), of the OLED as an emitter material. The emissive layer may emit light with a wavelength in the range of 420-565 nm, preferably in the range of 420-490 nm.

The metal complex may be used in the light-emitting layer without further additional components, or the metal complex may be comprised in the light-emitting layer with one or more further components. The light-emitting layer may further comprise one or more host (matrix) materials. This host material may be a polymer, for example poly(N-vinylcarbazole). The host material may, alternatively, be a small molecule with enlarged HOMO/LUMO energy gap and relatively greater triplet energy gap or tertiary aromatic amines, for example tris(4-carbazoyl-9-ylphenyl)amine (TCTA). The host material may also be a dibenzofuran-based material with relatively large triple energy gap, such as 2,8-bis(diphenylphosphino oxide) dibenzofuran (PPF). Suitable host materials are carbazole derivatives, for example 4,4′-bis(carbazol-9-yl)-2,2′-dimethylbiphenyl (CDBP), 4,4′-bis(carbazol-9-yl)biphenyl (CBP), 1,3-bis(N-carbazolyl)benzene (mCP), 3,3′-di(9H -carbazol-9-yl)-1,1′-biphenyl (mCBP), diphenyl[4-(triphenylsilyl)phenyl]phosphine oxide (TSPO1), and 1-(4-(dibenzo[b,d]thiophen-4-yl) -2,5 -dimethylphenyl)-1H-phenanthro[9,10-d]imidazole (txI).

In addition, the present invention may beneficially avoid the need to include a dye as it provides a blue emission. However, in alternative embodiments, a fluorescent dye may be present in the light-emitting layer of an OLED to alter the emission colour of the emitter material.

In the preferred embodiment, the OLED is constructed with the following layers which are arranged in the following order: an anode layer, a hole-injection layer (optional), a hole-transporting layer (optional), an electron-blocking layer (optional), an exciton-blocking layer (optional), a light-emitting layer (including the metal complex), a hole-blocking layer (optional), an electron-transporting layer (optional), an electron-injection layer (optional), and a cathode layer.

In general, the different layers in the OLED, if present, have the following thicknesses:
anode layer: 50 to 500 nm, preferably 100 to 200 nm;
hole-injection layer (optional): 1 to 50 nm, preferably 5 to 10 nm;
hole-transporting layer (optional): 5 to 100 nm, preferably 10 to 80 nm;
electron-blocking layer (optional): 1 to 50 nm, preferably 5 to 10 nm;
exciton-blocking layer (optional): 1 to 50 nm, preferably 5 to 10 nm;
light-emitting layer: 1 to 100 nm, preferably 5 to 60 nm;
hole-blocking layer (optional): 1 to 50 nm, preferably 5 to 10 nm;
electron-transporting layer (optional): 5 to 100 nm, preferably 20 to 60 nm;
electron-injection layer (optional): 1 to 20 nm, preferably 1 to 5 nm;
cathode layer: 20 to 1000 nm, preferably 30 to 500 nm.

The OLED may be comprised in a device, for example, stationary visual display units, such as visual display units of wearable or head-mounted devices, computers, televisions, visual display units in printers, kitchen appliances, advertising panels, information panels and illuminations; mobile visual display units such as visual display units in smartphones, cell-phones, tablet computers, laptops, digital cameras, MP3-players, vehicles, keyboards and destination displays on buses and trains; illumination units; units in items of clothing; units in handbags, units in accessories, units in furniture and units in wallpaper.

The photophysical properties of the preferred Ir(III)-based emitters are shown in Table 1, which reveals high photoluminescence quantum yields up to 97%, emission peak max. located in the region of 420-565 nm, and radiative lifetime lower than two microseconds. These photophysical parameters indicate the possible direction in achieving efficient and robust blue phosphors and respective PHOLEDs.

TABLE 1
Photophysical data of the tris-bidentate Ir(III) complexes in degassed
toluene solution.

| | λₘₐₓ^{[a]} | FWHM^{[b]} | Φ^{[c][d]} | τ_{obs}^{[d]} | τ_{rad}^{[d]} | kᵣ | kₙᵣ |
|---|---|---|---|---|---|---|---|
| Complex | (nm) | (cm-¹) | (%) | (μs) | (μs) | (10⁶s⁻¹) | (10⁶s⁻¹) |
| 1-fac | 423 | 3290 | 43 | 0.52 | 1.2 | 0.83 | 1.1 |
| 1-mer | 483 | 4110 | 75 | 0.77 | 1.0 | 1.0 | 0.3 |
| 2-fac | 436 | 3350 | 62 | 0.66 | 1.1 | 0.91 | 0.59 |
| 2-mer | 496 | 3990 | 92 | 0.89 | 0.97 | 1.0 | 0.1 |
| 3-fac | 447 | 3254 | 73 | 1.25 | 1.71 | 0.58 | 0.22 |
| 1-fac | 422 | 3850 | 39 | 0.49 | 1.26 | 0.79 | 1.25 |
| 5-fac | 468 | 3246 | 97 | 0.72 | 0.74 | 1.35 | 0.04 |
| 5-mer | 526 | 3253 | 81 | 0.92 | 1.14 | 0.88 | 0.21 |
| 6-fac | 508 | 3605 | 71 | 0.76 | 1.07 | 0.93 | 0.38 |
| 6-mer | 561 | 3493 | 66 | 0.81 | 1.23 | 0.81 | 0.42 |
| 7-fac | 466 | 3309 | 74 | 1.64 | 2.21 | 0.45 | 0.16 |
| 7-mer | 518 | 3736 | 46 | 0.42 | 0.92 | 1.08 | 1.27 |
| 8-fac | 485 | 3334 | 58 | 0.96 | 1.65 | 0.61 | 0.44 |
| 8-mer | 532 | 3613 | 45 | 0.19 | 0.42 | 2.4 | 2.9 |
| 9-fac | 483 | 3278 | 53 | 0.70 | 1.31 | 0.76 | 0.68 |
| 9-mer | 518 | 3870 | 48 | 0.25 | 0.53 | 1.89 | 2.05 |
| 10-fac | 468 | 2702 | 80 | 0.72 | 0.90 | 1.1 | 0.28 |
| 11-fac | 468 | 2752 | 75 | 0.68 | 0.91 | 1.1 | 0.37 |
| 12-fac | 464 | 2540 | 83 | 0.53 | 0.64 | 1.6 | 0.32 |

^{[a]}Recorded at a concentration of 10⁻⁵ M in toluene at room temperature.
^{[b]}Full width at half maximum.
^{[c]}Coumarin 102 (C102) in methanol (quantum yield (Q.Y.) = 87% and λₘₐₓ = 480 nm) were employed as standard.
^{[d]}Recorded in degassed toluene at a concentration of 10⁻⁵ M at room temperature.

As discussed above, Ir(C^C:)₃ complexes are promising materials for fabrication of robust and efficient blue PHOLEDs. The introduction of pyrimidine and pyrazine appendages at the chelating carbene fragments increase the strength of Ir—C_{carbene} dative bonding and shifts the emission from purple to true blue. In addition, the lone pair electron on the N atoms in the as-synthesized Ir(III) emitters may cause severe instability. Therefore, in the preferred embodiments, one or more tert-butyl substituents at the nearby or adjacent position were introduced to protect these N atoms from detrimental exposure to environment which would otherwise cause the unwanted decomposition. The tert-butyl substituent as R₃ or R_{4,} together with other structural features, are found to be capable to improve their chemical stability and to allow fine-tuning of their photophysical properties of the as-prepared Ir(III) metal phosphors. Further, substitution of the tert-butyl substituent with an electron-withdrawing CF₃ appendage offers a more stabilized π*-orbital, thus offering the futher red shifting of emission wavelength and improved photophysical properties of the Ir(III) complex.

Hereinafter, the present invention is described more specifically by way of examples, but the present invention is not limited thereto.

In the following examples, unless stated otherwise, commercially available reagents were used without further purification. All solvents were dried and degassed before used, and all reactions were conducted under N₂ and monitored using pre-coated TLC plates (0.20 nm with fluorescent indicator F254). ¹H and ¹⁹F NMR spectra were measured with Bruker Avance III HD 300 MHz NMR or Bruker Avance III 400 MHz NMR instrument. Elemental analysis was carried out on an Elemental Micro Carbon-Hydrogen-Nitrogen Analyzer (Elementar VARIO Micro Cube). Mass spectra were recorded on Applied Biosystems 4800 Plus MALDI TOF/TOF Analyzer (ABI) using 2,5-dihydroxybenzoic acid as the matrix substance. The single crystal X-ray structural analyses were conducted using phi and omega scans mode (APEX3) on a Bruker D8 Venture Photon II diffractometer with microfocus X-ray sources at 233 K. UV-Vis spectra were recorded on a HITACHI UH-4150 spectrophotometer. The steady-state emission spectra were measured with Edinburgh FS 920. Both wavelength-dependent excitation and emission responses of the fluorimeter were calibrated.

The lifetime studies were performed by a time-correlated single photon counting system (TCSPC) with a femtosecond, mode-locked Ti-Sapphire laser that was tuned to 720 nm, followed by the second-harmonic generation (360 nm) via a BBO crystal. The excitation source was then changed into vertical polarization using a half-wave plate. Lastly, a linear polarizer was set as 54.7 degree deviated from the vertical polarization plane in between the sample cell and PMT detector to avoid any emission anisotropy. Spectral grade solvents (Merck) were used as received.

To determine the photoluminescence quantum yield in solution, samples were degassed using at least three freeze-pump-thaw cycles. The solution quantum yields are calculated using the standard sample which has a known quantum yield, according to the following equation:

$$Φ = {Φ}_{R} \frac{I}{{I}_{R}} \frac{{A}_{R}}{A} \frac{{η}^{2}}{{η}_{R}^{2}} \qquad Equation 1$$

where Φ is the quantum yield, the subscript R refers to the reference compound of known quantum yield, I is the integrated fluorescence intensity and η is the refractive index of the solvent. A is the absorbance at the excitation wavelength with the value of absorbance around 0.1. The Φ value of studied complexes in PMMA thin film was measured by an integrated sphere.

The radiative lifetimes (τ_{rad}), radiative rate constant (kᵣ) and non-radiative rate constant (kₙᵣ) of the metal complexes were calculated using the following equations:

τ_{rad}=τ_{obs}/Φ (2)

kᵣΦ/τ_{obs} (3)

kₙᵣ=(1−Φ)/τ_{obs} (4)

### EXAMPLE 1

### Purin-8-Ylidene-Based Ir(III) Metal Complexes 1-mer,1-fac, 2-mer and 2-fac

Synthesis of Tert-Butyl-Substituted 9H-Purin-7-Ium Pro-Chelates (1tBuH2 and 2tBuH2)

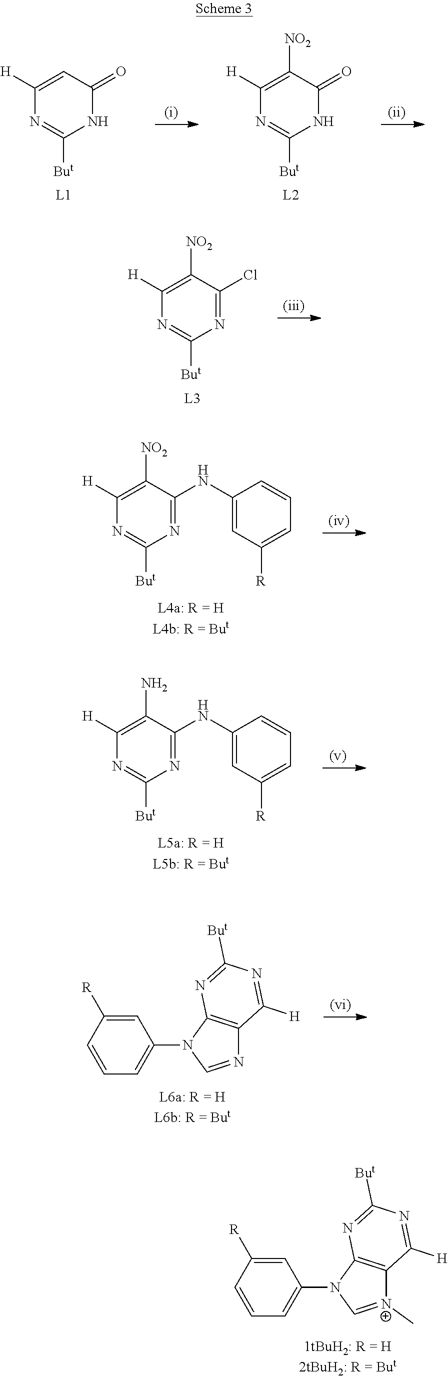

The functional 9H-purin-7-ium chelates were synthesized using a multi-step protocol, as shown in Scheme 3. Firstly, the key starting material, 2-(tert-butyl)pyrimidin-4(3H)-one (L1), was prepared from condensation of pivalamidine hydrochloride and the in-situ generated sodium salt of ethyl formylacetate.

Conversion of L1 to 2-(tert-butyl)-5-nitropyrimidin-4(3H)-one (L2) and next to 2-(tert-butyl)-4-chloro-5-nitropyrimidine (L3) were achieved by treatment KNO₃ in concentrated sulfuric acid (i), followed by chlorination using phosphorus oxychloride under reflux for 3 hours (ii).

Substitution of the chloro group with aniline and 3-(tert-butyl)aniline was conducted by refluxing ethylene glycol for 12 hours (iii), which gave formation of 2-(tert-butyl)-5-nitro-N-phenylpyrimidin-4-amine (L4a) and 2-(tert-butyl)-N-(3-(tert-butyl)phenyl)-5-nitropyrimidin-4-amine (L4b) in high yields.

Reduction of the nitro substituent was performed with treatment of excessive SnCl₂·2H₂O in methanol solution at room temperature for 3 hours (iv), giving isolation of 2-(tert-butyl)-N⁴-phenylpyrimidine-4,5-diamine (L5a) and 2-(tert-butyl)-N⁴-(3 itert-butyl)phenyl)pyrimidine-4,5 -diamine (L5b), after the routine work-up.

After that, cyclization with formic acid at 120° C. for 12 hours (v) afforded the respective 2 -(tert-butyl)-9-phenyl-9H-purine (L6a) and 2 -(tert-butyl)-9-(3-(tert-butyl)phenyl)-9H-purine (L6b) in high yields.

Finally, treatment with methyl trifluoromethanesulfonate with toluene at room temperature for 2 hours (vi) provided the pro-chelates 2-(tert-butyl)-9-phenyl-7-methyl-9H-purin-7-ium (1tBuH₂) and 2-(tert-butyl)-9-(3-(tert-butyl)phenyl)-7-methyl-9H-purin-7-ium (2tBuH₂), both of which can be employed for the subsequent coordination reaction with iridium metal reagent without further purification.

Synthesis of Purin-8-Ylidene-Based Ir(III) Metal Complexes (1-mer and 1-fac, 2-mer and 2 -fac)

A respective mixture of 1tButH₂ (1.0 g, 2.4 mmol) and 2tBuH₂ (1.0 g, 2.4 mmol), IrCl₃(tht)₃ (0.39 g, 0.7 mmol) and a promoter (sodium acetate (0.57 g, 6.9 mmol)) in degassed tert-butylbenzene (15 mL) was refluxed overnight under N₂. After that, the solvent was removed under vacuum. The residue was dissolved in 100 mL of CH₂Cl₂, washed with water, dried over anhydrous Na₂SO₄ and then evaporated to dryness. This gave a mixture of f- and m-stereoisomers. The reaction mixture was then purified by column chromatography using petroleum ether/ethyl acetate (4/1, v/v) as eluent to give respective isomeric products, namely: 1-mer (0.4 g, 59%) and 1-fac (0.16 g, 23%), 2-mer (0.4 g, 57%) and 2-fac (0.2 g, 29%). The Ir complexes are provided with 2-(tert-butyl)-7-methyl-9-phenyl-7,9-dihydro-8H-purin-8-ylidene and 2-(tert-butyl)-9-(3-(tert-butyl)phenyl)-7-methyl-7,9 -dihydro-8H -purin-8-ylidene coordination entities, respectively. All complexes were further purified by temperature gradient vacuum sublimation.

The combined yields of Ir(III) carbene complexes can go up to as high as about 80% and, after chromatographic separation, m-isomers are found to be approximately two-time in excess than that of corresponding f-counterparts.

Isomerization

Additional f-isomers can be obtained using acid-catalyzed isomerization process. mer-to-fac isomerization was effectively conducted in a mixture of ethyl acetate and trifluoroacetic acid, to which formation of excessive f-substituted derivatives, i.e., both 1-fac and 2-fac, were isolated as main products.

The detail of the isomerization is provided as follows. To a 100 mL sealed tube was added trifluoroacetic acid (4.9 mL, 1M in H₂O), ethyl acetate (53 mL), and 1-mer (0.5 g, 0.51 mmol) and 2-mer (0.5 g, 0.43 mmol), respectively. The tube was then filled with N₂ and heated at 70° C. for 15 hours. The reaction mixture was cooled to room temperature and was quenched with 100 mL of water and extracted several times with ethyl acetate. The solvent was removed and the residue was purified by silica gel column chromatography using petroleum ether/ethyl acetate (4/1, v/v) as eluent to give respective isomeric products: 1-mer (0.15 g, 30%) and 1-fac (0.35 g, 70%), 2-mer (0.20 g, 40%) and 2-fac (0.30 g, 60%).

Spectroscopic and Structural Analysis

The structures of each of 1-mer, 1-fac, 2-mer and 2-fac were verified by ¹H NMR spectroscopy and MALDI-TOF mass spectrometry, optionally by ¹³C NMR as well. It was expected that the m- and f-isomers possess three distinctive and identical chelates around the Ir(III) metal atom. Hence, the overall pattern and total number of ¹H NMR signals would be particularly useful in providing the initial structural information.

Selected spectroscopic data for 1-mer is provided as follows: MS (MALDI-TOF, ¹⁹³Ir): m/z 989.5334 [M+H]⁺; ¹H NMR (400 MHz, acetone-d₆) δ 8.94-8.67 (m, 6H), 7.17-6.97 (m, 4H), 6.93-6.84 (m, 1H), 6.76-6.56 (m, 4H), 3.51 (s, 3H), 3.50 (s, 3H), 3.34 (s, 3H), 1.53 (s, 9H), 1.52 (s, 9H), 1.51 (s, 9H).

Selected spectroscopic data for 1-fac is provided as follows: MS (MALDI-TOF, ¹⁹³Ir): m/z 989.5133 [M+H]⁺; ¹H NMR (400 MHz, acetone-d₆) δ 8.82 (d, J=7.4 Hz, 6H), 7.06 (t, J=7.6 Hz, 3H), 6.68 (t, J=7.3 Hz, 3H), 6.68 (t, J=7.3 Hz, 3H), 3.58 (s, 9H), 1.51 (s, 27H). ¹³C NMR (101 MHz, CDCl₃) δ 193.68, 172.24, 150.80, 146.63, 145.24, 136.35, 135.52, 125.98, 125.32, 122.13, 115.24, 39.72, 34.26, 30.08.

Selected spectroscopic data for 2-mer is provided as follows: MS (MALDI-TOF, ¹⁹³Ir): m/z 1157.7310 [M+H]⁺; ¹H NMR (400 MHz, acetone-d₆) δ 9.15-8.95 (m, 3H), 8.85 (d, J=5.8 Hz, 2H), 8.79 (s, 1H), 6.91 (d, J=7.6 Hz, 1H), 6.85-6.81 (m, 2H), 6.76 (d, J=7.6 Hz, 2H), 6.58 (d, J=7.7 Hz, 1H), 3.53 (s, 3H), 3.50 (s, 3H), 3.33 (s, 3H), 1.54 (s, 27H), 1.35 (s, 9H), 1.34 (s, 9H), 1.33 (s, 9H).

Selected spectroscopic data for 2-fac is provided as follows: MS (MALDI-TOF, ¹⁹³Ir): m/z 1157.7418 [M+H]⁺; ¹-H NMR (400 MHz, acetone-d₆) δ 9.03 (s, 3H), 8.80 (s, 3H), 6.75 (d, J=7.8 Hz, 3H), 6.46 (d, J=7.7 Hz, 3H), 3.59 (s, 9H), 1.54 (s, 27H), 1.36 (s, 27H). ¹³C NMR (101 MHz, CDCl₃) δ 194.00, 171.89, 150.70, 146.61, 144.96, 140.95, 135.24, 125.41, 122.97, 112.69, 39.65, 34.43, 34.30, 31.68, 30.07.

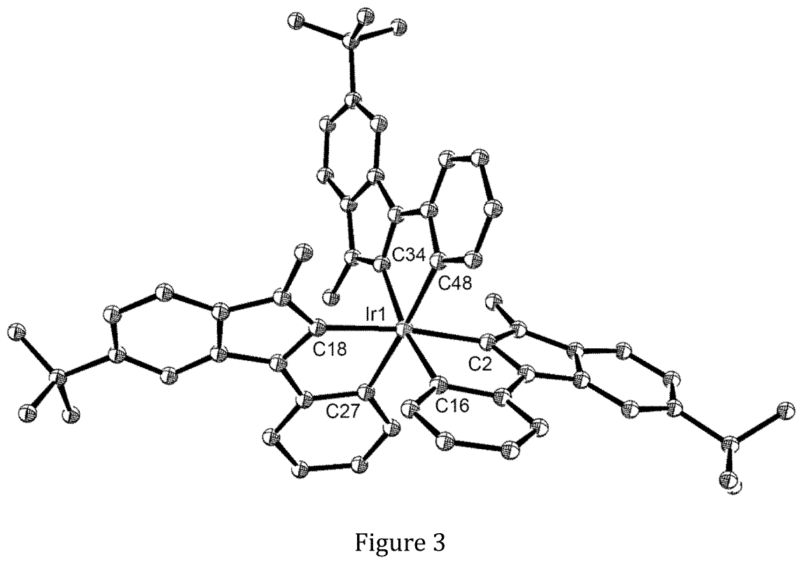

Single-crystal X-ray structural analysis was carried out for 1-mer to provide confirmation of the identity of chelates and gross coordination arrangement of these Ir(III) complexes. Ir(III) complex 1-mer existed as two crystallographically distinctive, but structurally identical molecules in the unit cells. FIG. 3 depicts only one of these molecules, to which the Ir(III) atom resides at the center of a slightly distorted octahedral arrangement. FIG. 3 is shown with thermal ellipsoids shown at 30% probability level, with selected bond lengths (A) of Ir1-C32=2.020(3), Ir1-C48=2.021(3), Ir1-C34=2.092(3), Ir1-C2=2.112(3), Ir1-C16=2.125(3) and Ir1-C18=2.128(3), and selected trans-C—Ir—C bond angles) (°) of C32-Ir1-C48=176.45(12), C34-Ir1-C16=168.42(13) and C2-Ir1-C18=172.12(12). Hydrogen atoms are omitted for clarity. The single crystal of 1-mer suitable for X-ray diffraction study was obtained via the slow diffusion of methanol into a saturated CH₂Cl₂ solution at room temperature.

Selected crystal data of 1-mer is provided as follows: CCDC deposition number: 2122409. C₄₈H₅₁IrN₁₂; M=988.20; monoclinic; space group=P 2₁/c; a=27.660(5) Å, b=14.723(2) Å, c=29.679(6) Å; β=106.049(8°); V=11615(4) Å³; Z=8; ρ_{calcd}=1.130 mgm-³; F(000)=4000, crystal size=0.37×0.11×0.03 mm³; λ(Mo-K_{α})=0.71073 Å; T=243 K; μ=4.740 mm⁻¹; 223695 reflections collected, 23507 independent reflections (Rᵢₙₜ=0.0987), max. and min. transmission=0.501 and 0.745, data/restraints/parameters=23507/834/1318, GOF=1.088, final R₁[I>2/σ(I)]=0.0388 and wR₂(all data)=0.1076.

As shown, all six Ir—C distances are different, but the unique trans-Ir—C distance (Ir1—C34=2.092(3) Å) is found to be notably shorter than the corresponding trans-Ir—C distance of phenyl cyclometalates (Ir1—C16=2.125(3) Å), which are in accordance with the metric features of many known homoleptic Ir(III) carbene cyclometalates. They can be also understood in terms of the enhanced bonding interaction between the metal d_{π}-orbital and empty π*-orbital of 9H-purin-7-ium fragments.

Photophysical Analysis

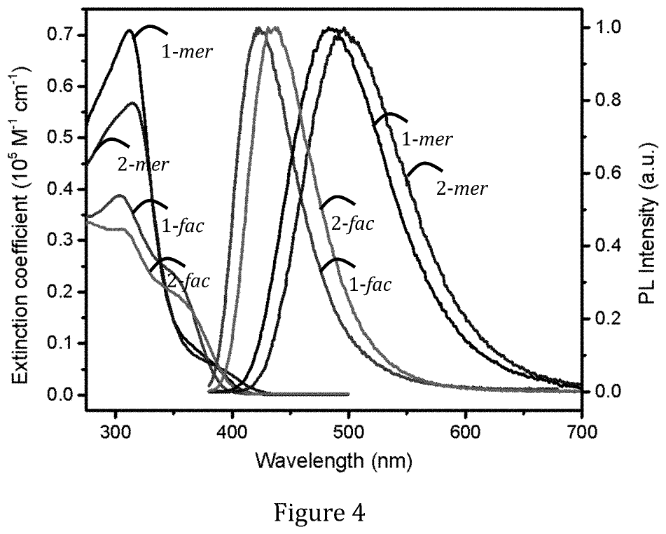

FIG. 4 depicts the UV-Vis absorption of the above tris-bidentate Ir(III) complexes in degassed toluene at room temperature. As shown, the absorption bands with wavelengths below 340 nm are attributed to the ligand centered as well as inter-ligand ππ* transitions, among which the mer-isomers showed a much larger extinction coefficient in comparison to their fac-counterparts. Further, at the longer wavelength region, the mer-isomers exhibited the relatively less intense and more red-shifted metal-to-ligand charge transfer (MLCT) absorption peaks vs. the respective fac-isomers. Without wishing to be bound by theories, this spectral pattern is believed to be related to the asymmetric arrangement of all coordinated carbene chelates and, to be universal to the relevant existing Ir(III) carbene complexes.

Also shown in FIG. 4 is their emission spectra which were measured in degassed toluene solution at room temperature. As shown in FIG. 4 and Table 2, both mer-isomers exhibited structureless emission profile with onset at about 410-420 nm and relatively more red-shifted peak max. at 483 nm and 496 nm, respectively. Further, the corresponding fac-isomers showed a much blue-shifted emission onset at about 380-390 nm, peak max. at 423 nm and 436 nm, and a significantly reduced full width at half maximum (FWHM) of 62 nm and 77 nm in comparison to the mer-isomers with identical carbene chelates (of about 100 nm). Moreover, those with 3-(tert-butyl)phenyl cyclometalate entities (i.e. both 2tBu derivatives) have showed more red-shifted peak wavelength in comparison with the parent 1tBu complexes with a phenyl substituent, which is a result of greater electron density at the Ir(III) metal center and more notably MLCT transition character.

The photoluminescence quantum yields (PLQYs; Φ) were measured. Particularly, the m-isomers were more efficient than their f-counterparts. Their radiative lifetimes (τ_{rad}), radiative rate constant (kᵣ) and non-radiative rate constant (kₙᵣ) were calculated and the data were listed in Table 2. The PLQYs span the region 43-92%, to which the smallest and the highest PLQY seems to coincide to those with the greatest and smallest emission energy, i.e. PL λₘₐₓ at 423 nm and 496 nm, respectively. Those with more red-shifted emission peak also exhibited shortened radiative lifetime, which is in accordance with the greater MLCT contribution at the excited state manifold. It is believed that the abnormal large FWHM and red shifting in wavelengths of mer-isomers were due to the solvation effect imposed to the greater asymmetric molecules, i.e. mer-isomers, to which the degree of MLCT contribution is expected to be greater than that of the corresponding fac-isomers. This hypothesis can be confirmed using the photophysical data in rigid PMMA matrix (Table 3), to which the mer-isomers reveals a large blue shift in emission peak max. of 23 nm and 26 nm versus the respective fac-isomers, which exhibited the red shifted peak max. of 2 nm and 4 nm, i.e., in the opposite direction.

TABLE 2
Photophysical data of the purin-8-ylidene-based Ir(III) metal complexes
at room temperature.

| | abs λₘₐₓ^{[a]} | PL λₘₐₓ^{[a]} | FWHM^{[b]} | Φ^{[c][d]} | τ_{obs}^{[d]} | τ_{rad}^{[d]} | kᵣ | kₙᵣ |
|---|---|---|---|---|---|---|---|---|
| Complex | (nm) | (nm) | (cm⁻¹/nm) | (%) | (μs) | (μs) | (10⁶ s⁻¹) | (10⁶ s⁻¹) |
| 1-mer | 312 (9.92), | 483 | 4110/100 | 75 | 0.77 | 1.0 | 1.0 | 0.3 |
| | 380 (1.00) | | | | | | | |
| 1-fac | 304 (5.46), | 423 | 3290/62 | 43 | 0.52 | 1.2 | 0.83 | 1.1 |
| | 350 (3.31) | | | | | | | |
| 2-mer | 315 (7.95), | 496 | 3990/101 | 92 | 0.89 | 0.97 | 1.0 | 0.1 |
| | 382 (0.92) | | | | | | | |
| 2-fac | 305 (4.55), | 436 | 3350/77 | 62 | 0.66 | 1.1 | 0.91 | 0.59 |
| | 350 (2.78) | | | | | | | |

^{[a]}Recorded at a concentration of 10⁻⁵ M in toluene at room temperature; extinction coefficient (ε) is given in parentheses with a unit of 10⁴ M⁻¹-cm⁻¹
^{[b]}Full width at half maximum.
^{[c]}Quinine sulfate (QS) in 0.1 M, sulfuric acid aqueous solution (Q.Y. = 54% and λₘₐₓ = 455 nm) were employed as standard.
^{[d]}Recorded in degassed toluene at a concentration of 10⁻⁵ M at room temperature.

TABLE 3
Photophysical data of the purin-8-ylidene-based Ir(III) metal com-
plexes in spin-casted PMMA thin film at room temperature (2 wt.%).

| Com- | PL λₘₐₓ^{[a]} | FWHM^{[b]} | Φ^{[c][d]} | τ_{obs}^{[d]} | τ_{rad}^{[d]} | kᵣ | kₙᵣ |
|---|---|---|---|---|---|---|---|
| plex | (nm) | (cm⁻¹) | (%) | (μs) | (μs) | (10⁶ s⁻¹) | (10⁶ s⁻¹) |
| 1-mer | 460 | 4734 | 64 | 0.61 | 0.96 | 1.04 | 0.60 |
| 1-fac | 425 | 3958 | 60 | 0.68 | 1.13 | 0.88 | 0.59 |
| 2-mer | 470 | 4049 | 46 | 0.68 | 1.47 | 0.68 | 0.79 |
| 2-fac | 440 | 4753 | 59 | 0.66 | 1.12 | 0.89 | 0.63 |

^{[a]}Recorded at a concentration of 10⁻⁵ M in toluene at room temperature.
^{[b]}Full width at half maximum.
^{[c]}Quinine sulfate (QS) in 0.1 M, sulfuric acid aqueous solution (Q.Y. = 54% and λₘₐₓ = 455 nm) were employed as standard.
^{[d]}Recorded in degassed toluene at a concentration of 10⁻⁵ M at room temperature.

Electroluminescence Analysis

To investigate the electroluminescent (EL) properties of NHC-based Ir(III) metal phosphors, due to their relatively promising luminescent properties as discussed above, fabrication of blue OLEDs was conducted using two better emitters 2-mer and 2-fac, as the solely dopant phosphor in the emissive layer and, as triplet sensitizer to convey the excitation energy through FRET to the boron-nitrogen-based TADF emitter ν-DABNA in achieving the true blue emission with narrowed emission bandwidth.

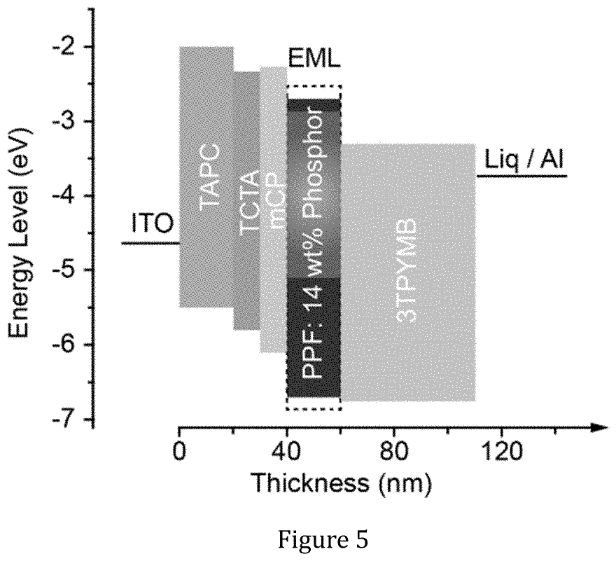

As shown in FIG. 5, the device structure consists of and is constructed with the following in sequential order: an indium tin oxide (ITO) electrode, 1,1-bis((di-4-tolylamino)phenyl)cyclohexane (TAP C; 20 nm), 4,4′,4″-tris(40 ommercia-9-yl)-triphenylamine (TCTA; 10 nm), 1,3-di(9H-carbazol-9-yl)benzene (mCP; 10 nm), 2,8-bis(diphenylphosphino oxide) dibenzofuran (PPF): 14 wt% Ir(III) complexes (20 nm), tris(2,4,6-trimethyl-3-(40 ommerci-3-yl)phenyl)borane (3TPYMB; 40 nm), lithium fluoride (LiF; 1 nm), and an aluminum electrode. In this device, TAPC and 3TPYMB were used as hole- and electron-transporting materials, respectively. TCTA and mCP functioned as electron- and exciton-blocking materials, respectively. LiF was the electron-injection layer, and PPF served as host material for the devices.

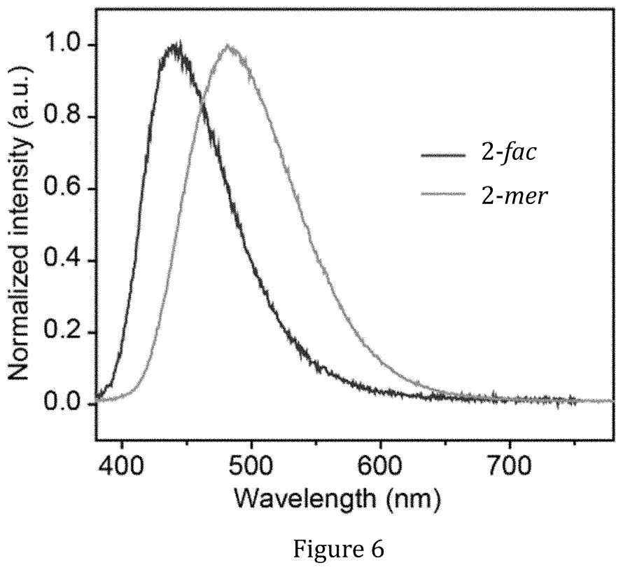

The electroluminescent characteristics and related data are shown in FIGS. 6 to 8 and Table 4.

TABLE 4
Electroluminescence data of the OLED devices.

| Sample | Vₒₙ [V] | EL λₘₐₓ [nm] | CE^{[a]} [cd A⁻¹] | EQE^{[a]} [%] | CIE_{xy} ^{[b]} |
|---|---|---|---|---|---|
| 2-fac | 3.6 | 440 | 7.7, 6.4, 3.1 | 7.5, 6.1, 2.8 | 0.157, |
| | | | | | 0.120 |
| 2-mer | 3.5 | 482 | 35.2, 35.3, 30.2 | 17.0, 16.9, | 0.189, |
| | | | | 14.2 | 0.316 |
| 14 wt % 2-mer: 2 | 3.5 | 472 | 22.4, 21.7, 15.9 | 19.6, 19.0, | 0.122, |
| wt % ν-DABNA | | | | 15.6 | 0.161 |
| 25 wt % 2-mer: 2 | 3.5 | 472 | 23.49, 19.7, 16.2 | 22.0, 18.9, | 0.120, |
| wt % ν-DABNA | | | | 14.9 | 0.155 |
| 40 wt % 2-mer: 2 | 3.5 | 472 | 22.89, 18.1, 7.8 | 21.7, 17.8, | 0.122, |
| wt % ν-DABNA | | | | 6.9 | 0.162 |

^{[a]}Maximum; Recorded at 100 and 1000 cd m⁻², respectively.
^{[b]} Recorded at 100 cd m⁻²

As shown in FIG. 6, the 2-fac-based device delivered true-blue emission with peaks at 440 nm and CIE coordinates of (0.157, 0.120). A fast efficiency roll-off is observed in this device (EQE from 7.5 to 2.8% at the maximum and 1000 cd m⁻²), which is believed to relate to exciton leakage from 2-fac (triplet energy, ET=3.1 eV) to mCP (ET=2.91 eV) and 3TPYMB (ET=2.95 eV). EL emission of 2-mer gave a peak max. at 482 nm, which has a hypsochromic shift of 14 nm compared to its PL spectrum in toluene solution (Table 2). This is believed to be related to the greater solvation effect that induced by the MLCT character in solution and the rigid environment that restricted CT reorganization in PPF host matrix.

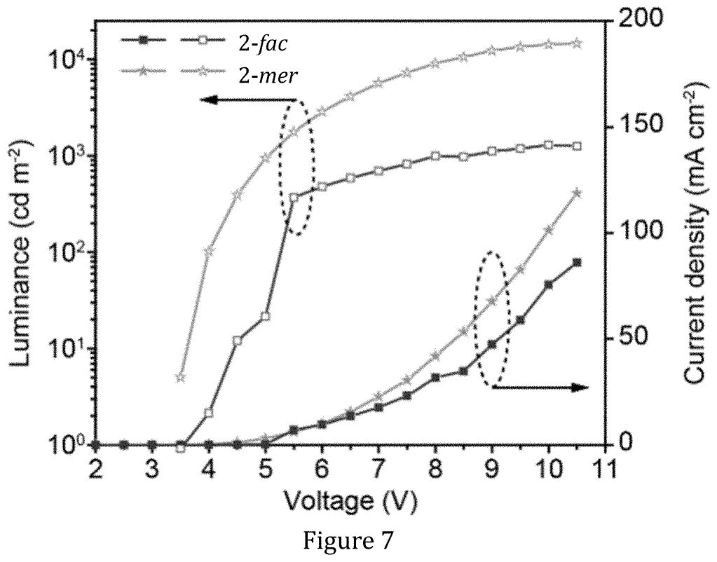

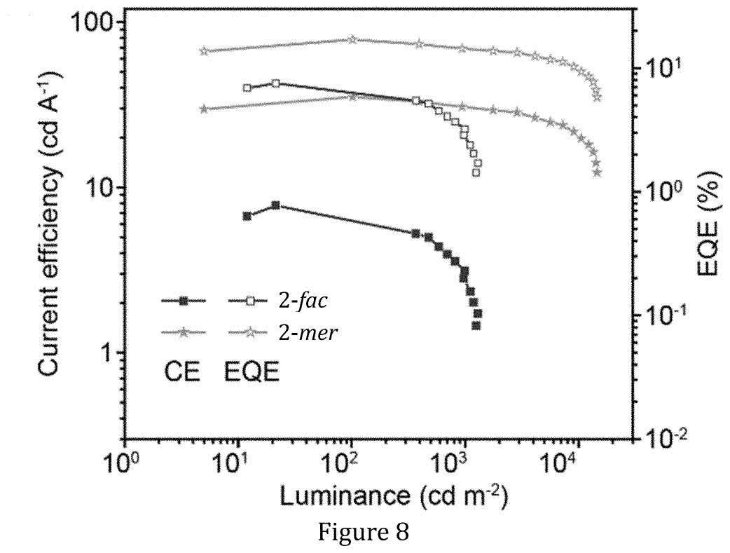

Moreover, only the characteristic emission bands of phosphors were observed in these OLED devices, indicating efficient energy transfer from the host material to phosphor. The current density-voltage-luminance (J-V-L) characteristics and the current density-luminance-EQE characteristics of these devices are depicted in FIGS. 7 and 8, respectively. Decent performance can be observed in 2-mer-based device with turn-on voltages of 3.5 V, maximum current efficiencies of 35.2 cd/m², and maximum EQE reached as high as 17.0%.

Hyperphosphorescent system can promote efficient energy transfer from the triplet excited states of the sensitizer to the singlet excited states of the fluorophore, giving significantly improved efficiency and operational lifetime of the fabricated device. Its working principle has been successfully applied in fabrication of a few phosphor-sensitized fluorescent and TADF-based OLED devices.

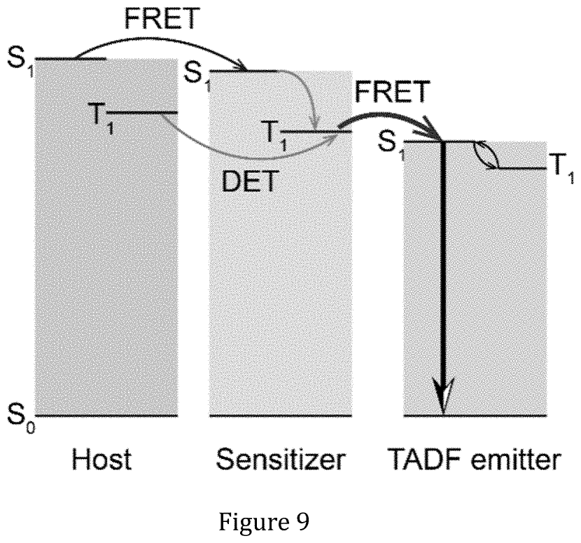

The energy transfer mechanism of the hyperphosphorescent OLEDs is schematically depicted in FIG. 9. In this example, ν-DAB NA was selected as the terminal emitter for its high EQE, narrowed emission band, and shortened fluorescence lifetime. It is expected that Förster resonant energy transfer (FRET) from 2 -mer to ν-DABNA could give efficient harvest of triplet excitons for emission because of the large overlap between the emission spectrum of 2-mer and the absorption spectrum of ν-DABNA and faster radiative transition rate of 2-mer.

Moreover, the Dexter energy transfer (DET) is believed to be suppressed owing to the introduction of bulky tert-butyl groups of 2-mer in keeping the larger intermolecular separation, and lowered doping concentration of ≤2 wt % for the terminal emitter ν-DABNA.

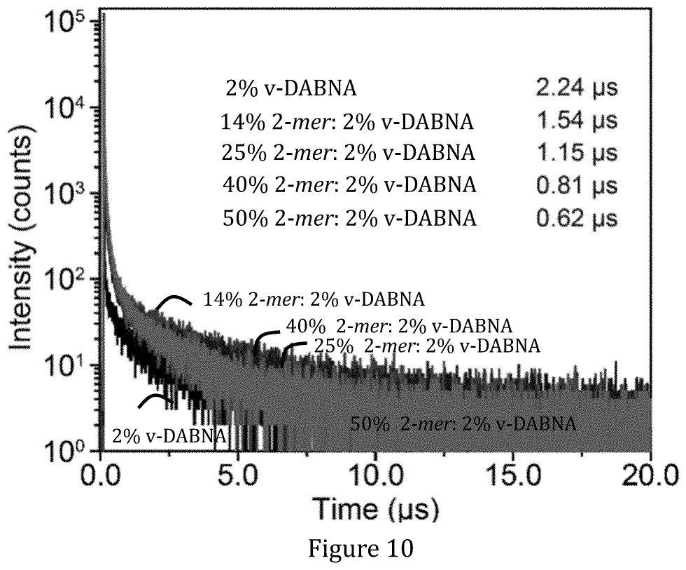

As shown in FIG. 10, the transient decay lifetimes of ν-DABNA-based emission were notably reduced from 2.24 μs to 0.62 μs without showing any broadened emission bandwidth of the ν-DABNA-based emission, upon increasing the doping concentration of 2-mer from 14 wt % up to 50 wt %. Meanwhile, the contribution percentage of the fast (prompt) decay component with a nearly constant lifetime of about 72 ns for a range of concentration from 32% to 58%, indicating the efficient FRET from Ir(III) sensitizer 2-mer to the terminal emitter ν-DABNA.

It is expected that the decreases in the long emission lifetimes from transient decay measurement would implicate a further improvement in efficiency of doped OLED devices. Therefore, the phosphor 2-mer was employed as assistant sensitizer in fabrication of hyperphosphorescent OLED devices. The modified device architecture is similar to the above OLED architecture, consisting of: ITO/TAPC (20 nm)/TCTA (10 nm)/mCP (10 nm)/PPF: 14˜40 wt % 2-mer: ν-DABNA 2 wt % (20 nm)/3TPYMB (40 nm)/LiF (1 nm)/Al.

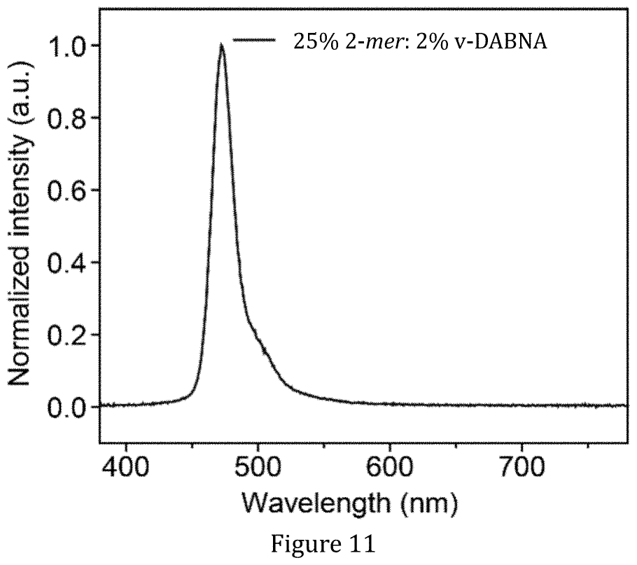

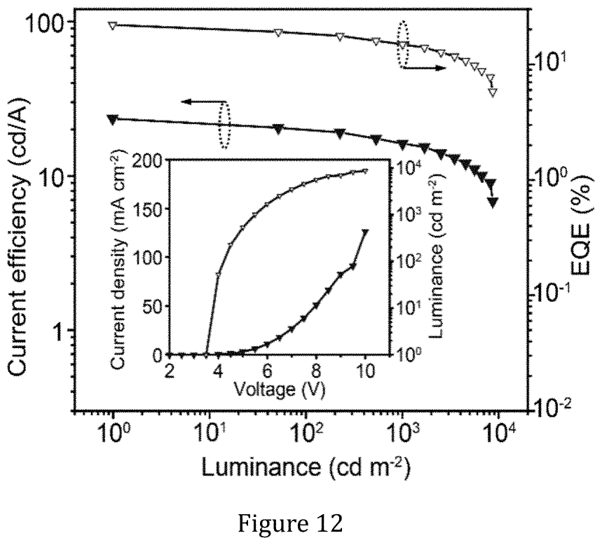

As can be seen from FIGS. 11 and 12, efficient energy transfer from assistant dopant 2-mer to terminal emitter ν-DABNA was confirmed by the EL spectrum, whereas only the emission of ν-DABNA was observed with a narrowed full width at half maximum (FWHM) of 21 nm for all devices. At the assistant dopant concentration of 25 wt %, both the efficient energy transfer process and excellent PL properties of ν-DABNA further push up the OLED performance to a max. EQE of 22.0%, CIE (x- and y-) coordinates of (0.122, 0.155), and a reduced efficiency roll-off, with EQE=14.9% at 1000 cd m⁻², highlighting the validity of hyperphosphorescence. Moreover, lowered device efficiencies were next obtained upon further increasing the concentration of assistant sensitizer to 40 wt %, which could be due to the triplet-triplet annihilation and triplet-polaron quenching that typically occurred at the higher doping concentration of phosphors.

### EXAMPLE 2

### Purin-8-Ylidene-Based Ir(III) Metal Complexes 5-mer, 5-fac, 6-mer and 6-fac

Synthesis of CF₃-Substituted 9H-Purin-7-Ium Pro-Chelate (A4)

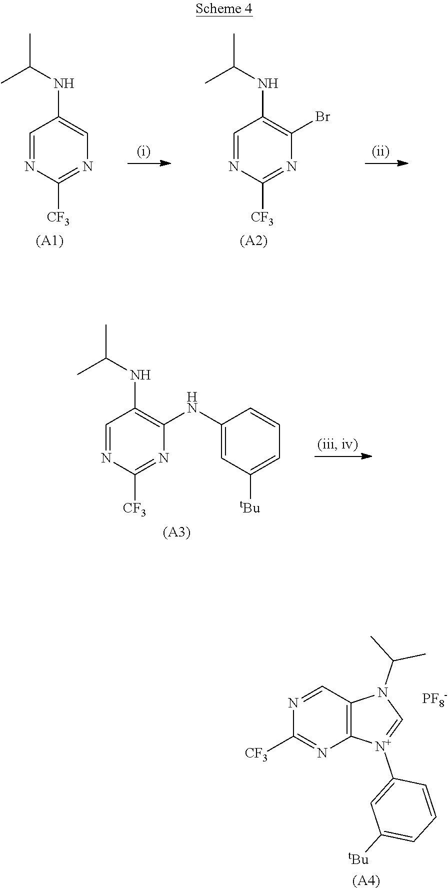

The CF₃-functionalized 9H-purin-7-ium pro-chelate was synthesized using a simple synthetic protocol as depicted in Scheme 4. Firstly, N-isopropyl-2-(trifluoromethyl)pyrimidin-5-amine (A1) was prepared from treatment of 44 commercially available 5-bromo-2-(trifluoromethyl)pyrimidine with isopropylamine upon heating.

Subsequent bromination of Al with N-bromosuccinimide (NBS) at room temperature for 12 hours (i) afforded 4-bromo-N-isopropyl-2-(trifluoromethyl)pyrimidin-5-amine (A2), which was then converted to N⁴-(3-(tert-butyl)phenyl)-N⁵-isopropyl-2-(trifluoromethyl)pyrimidine-4,5-diamine (A3) upon treatment with 3-tert-butylaniline at room temperature for 12 hours (ii).

After that, condensation of A3 with formic acid at 150° C. for 12 hours (iii), followed by metathesis with an aliquot of KPF₆ solution and MeOH at room temperature (iv) yielded the CF₃-substituted 9H-purin-7-ium hexafluorophosphate (A4), which can be employed for subsequent reaction without further purification.

Synthesis of Purin-8-Ylidene-Based Ir(III) Metal Complexes (S-mer)

A mixture of A4 (1.0 g, 1.97 mmol), IrCl₃(tht)₃ (0.32 g, 0.56 mmol) and a promoter, i.e. NaOAc (1.6 g, 5.6 mmol), in tert-butylbenzene (10 mL) was refluxed overnight under N₂. After that, the solvent was removed under vacuum. The residue was dissolved in 30 mL of CH₂Cl₂, washed with water, dried over anhydrous Na₂SO₄ and then evaporated to dryness. The residue was purified by column chromatography using a mixture of petroleum ether and ethyl acetate (4/1, v/v) as eluent to give tris(9-(3-(tert-butyl)phenyl)-7-isopropyl-2-(trifluoromethyl)-9H-purin-7-ium)iridium(III), S-mer (0.43 g, 60%) as the major product. It can be further purified by recrystallization from a mixed solution of CH₂Cl₂ and methanol, followed by vacuum sublimation.

Synthesis of Purin-8-Ylidene-Based Ir(III) Metal Complexes (5-fac)

To a 100 mL sealed tube was added 5-mer (0.5 g, 0.39 mmol), 4.9 mL of trifluoroacetic acid (1M in H₂O) and 50 mL ethyl acetate. The tube was then sealed under N₂ and heated at 70° C. for 48 h. After cooled to room temperature, the mixture was taken into excess of ethyl acetate, and washed with deionized water three times. The solvent was removed and the residue was purified by silica gel column chromatography using a mixture of petroleum ether and ethyl acetate (4/1, v/v) as eluent to give 5-fac (0.35 g, 70%). It can be further purified by recrystallization from a mixed solution of CH₂Cl₂ and methanol, followed by vacuum sublimation.

Synthesis of CF₃-Substituted 9H-Purin-7-Ium Pro-Chelate (B7)

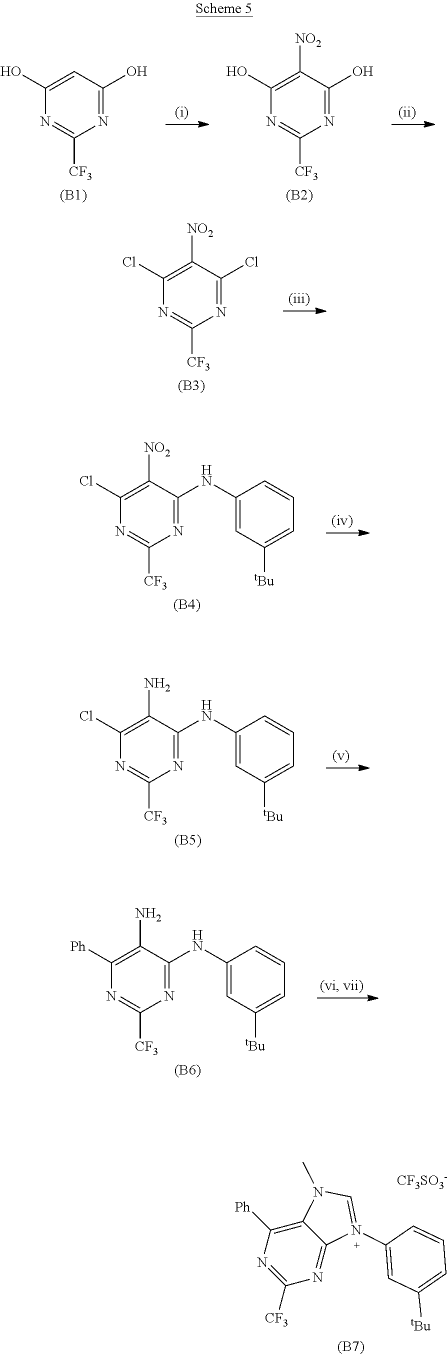

Compared with Scheme 4, synthesis of 9H-purin-7-ium pro-chelate (B7) was relatively more complicated and required a different starting material, 2-(trifluoromethyl)pyrimidine-4,6-diol (B1), as shown in Scheme 5. After that, nitration with HNO₃ and CF₃CO₂H at room temperature (i) and chlorination with PPCl₃ and dimethylaniline at 80° C. (ii) gave sequential formation of 5-nitro-2-(trifluoromethyl)pyrimidine-4,6-diol (B2) and 4,6-dichloro-5-nitro-2-(trifluoromethyl)pyrimidine (B3) in adequate yields.

Substitution of one chloro substituent of B3 with 3-(tert-butyl)aniline was conducted at −80° C. (with THF) (iii) , giving N-(3-(tert-butyl)phenyl)-6-chloro-5-nitro-2-(trifluoromethyl)pyrimidin-4-amine (B4), while reduction of the nitro group with Fe, in the presence of NH₄Cl, H₂O, THF, and MeOH at 80° C. (iv) afforded corresponding 6-chloro-2-(trifluoromethyl)pyrimidine-4,5-diamine (B5) in good yields. Then, the remaining chloro substituent of B5 was replaced with phenyl boronic acid (PhB(OH)₂) in the presence of Pd(PPh₃)₄, Na₂CO₃, H₂O and toluene at 90° C. (v) in giving 6-phenyl-2-(trifluoromethyl)pyrimidine-4,5-diamine (B6).

Finally, cyclization of B6 with formic acid at 120° C. (vi), followed by N-methylation with CF₃SO₃Me in the presence of toluene at room temperature (vii) afforded the CF₃-substituted 9H-purin-7-ium pro-chelate (B7), which is different from the pro-chelate A4 in Example 2 with a phenyl group located at the peripheral of 9H-purin-7-ium entity.

Synthesis of Purin-8-Ylidene-Based Ir(III) Metal Complexes (6-mer and 6-fac)

A mixture of B7 (1.0 g, 1.79 mmol), IrCl₃(tht)₃ (0.29 g, 0.51 mmol) and a promoter, i.e. NaOAc (0.42 g, 5.1 mmol), in tert-butylbenzene (30 mL) was refluxed overnight under N₂. After that, the solvent was removed under vacuum. The residue was dissolved in 30 mL of CH₂Cl₂, washed with water, dried over anhydrous Na₂SO₄ and then evaporated to dryness. The residue was purified by column chromatography using a mixture of petroleum ether and ethyl acetate (4/1, v/v) as eluent, giving two light yellow Ir(III) complexes: 6-mer (0.36 g, 50%) and 6-fac (0.14 g, 20%), in an approximate ratio of 5:2. Additional 6-fac can be obtained using acid-catalyzed isomerization process. They can be further purified by recrystallization from a mixed solution of CH₂Cl₂ and methanol, followed by vacuum sublimation.

Spectroscopic and Structural Analysis

The structures of each of 5-mer, 5-fac, 6-mer and 6-fac were verified by ¹H NMR spectroscopy and MALDI-TOF mass spectrometry. It was expected that the m- and f-isomers possess three distinctive and identical chelates around the Ir(III) metal atom. Hence, the overall pattern and total number of ¹H NMR signals would be particularly useful in providing the initial structural information.

Selected spectroscopic data for 5-mer is provided as follows: ¹H NMR (400 MHz, acetone-d₆) δ 9.38 (s, 1H), 9.36 (s, 1H), 9.34 (s, 1H), 9.01 (d, J=1.8 Hz, 1H), 8.99 (d, J=1.9 Hz, 1H), 8.93 (d, J=2.0 Hz, 1H), 7.12 (d, J=7.7 Hz, 1H), 6.88 (d, J=1.9 Hz, 1H), 6.86 (d, J=1.9 Hz, 1H), 6.82 (d, J=7.7 Hz, 1H), 6.72 (d, J=7.8 Hz, 1H), 6.63 (d, J=7.8 Hz, 1H), 4.93-4.86 (m, 1H), 4.81-4.74 (m, 1H), 4.71-4.64 (m, 1H), 1.90 (d, J=7.0 Hz, 3H), 1.54 (d, J=7.0 Hz, 3H), 1.45 (d, J=7.0 Hz, 3H), 1.35 (s, 9H), 1.34 (s, 18H), 0.99 (d, J=7.0 Hz, 3H), 0.87 (d, J=6.9 Hz, 3H), 0.81 (d, J=7.0 Hz, 3H).¹⁹F NMR (376 MHz, acetone-d₆) δ −69.47 (s, 3F), −69.54 (s, 3F), -69.61 (s, 3F). MALDI-TOF-MS [M+H]⁺: calculated: (C₅₄H₅₃F₉IrN₁₁) 1219.40; found: 1219.30.

Selected spectroscopic data for 5-fac is provided as follows: ¹H NMR (400 MHz, acetone-d₆) δ 9.35 (s, 3H), 8.94 (d, J=1.8 Hz, 3H), 6.77 (dd, J=1.8 Hz, J=7.8 Hz, 3H), 6.36 (d, J=7.8 Hz, 3H), 4.85-4.78 (m, 3H), 1.83 (d, J=7.1 Hz, 9H), 1.33 (s, 27H), 0.98 (d, J=6.9 Hz, 9H).¹⁹F NMR (376 MHz, acetone -d₆) 6 -69.50 (s, 9F).

MALDI-TOF-MS [M+H]⁺: calculated: (C₅₄H₅₃F₉IrN₁₁) 1219.40; found: 1218.52.

Selected spectroscopic data for 6-mer is provided as follows: ¹H NMR (400 MHz, acetone-d₆) δ 8.98 (d, J=1.9 Hz, 1H), 8.95 (d, J=1.9 Hz, 1H), 8.93 (d, J=1.9 Hz, 1H), 7.73-7.71 (m, 2H), 7.63-7.61 (m, 2H), 7.59-7.46 (m, 11H), 6.91 (d, J=7.6 Hz, 1H), 6.84-6.80 (m, 2H), 6.75-6.72 (m, 2H), 6.69 (d, J=7.7 Hz, 1H), 3.36 (s, 3H), 3.24 (s, 3H), 3.06 (s, 3H), 1.33 (s, 9H), 1.29 (s, 9H), 1.25 (s, 9H).¹⁹F NMR (376 MHz, acetone-d₆) δ −69.38 (s, 3F), −69.45 (s, 3F), −69.50 (s, 3F). MALDI-TOF-MS [M+H]⁺: calculated: (C₆₉H₆₀F₉IrN₁₂) 1420.45; found: 1419.44.

Selected spectroscopic data for 6-fac is provided as follows: ¹H NMR (400 MHz, acetone-d₆) δ 8.97 (s, 3H), 7.58-7.45 (m, 15H), 6.84-6.82 (d, J=8.0 Hz, 3H), 6.39-6.37 (d, J=8.0 Hz, 3H), 3.36 (s, 9H), 1.36 (s, 27H). ¹⁹F NMR (376 MHz, acetone-d₆) δ −69.43 (s, 9F). MALDI-TOF-MS [M+H]⁺: calculated: (C₆₉H₆₀F₉IrN₁₂) 1420.45; found: 1419.49.

The above structural characterization reveals a single and three distinctive set of the t-butyl and CF₃ resonance signals for the f- and m-isomers, respectively. Despite of the lowered synthetic yield, the f-derivative can be obtained in high yields using the acid-dependent isomerization well known in the art, while the unreacted m-isomers can be recovered for a second attempt. Due to their optimal emission wavelength in the blue spectral region and narrow bandwidth, their f-isomers are believed to be more advantageous for OLED fabrication in comparison to its m-isomer, 5-mer and 6-mer, to which the peak max. has already moved to 526 nm and 561 nm in solution state, as will be discussed below.

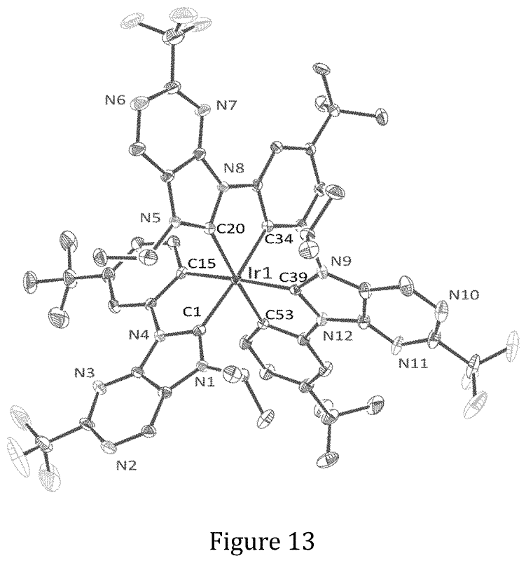

Single-crystal X-ray structural analysis was carried out for 5-fac to provide confirmation of the identity of chelates and gross coordination arrangement of these Ir(III) complexes. FIG. 13 is shown with thermal ellipsoids shown at 30% probability level, with selected bond lengths (Å) of Ir1—C1=2.019(5), Ir1—C20=2.031(4), Ir1—C39=2.027(4), Ir1—C15=2.088(4), Ir1—C34=2.093(4), Ir1—C53=2.090(4), and selected bond angles (°) of C1—Ir1—C15=78.33(17), C20—Ir1—C34=77.83(16) and C39—Ir1—C53=78.45(16). Hydrogen atoms are omitted for clarity. The single crystals of 5 -fac suitable for X-ray diffraction study were obtained from via the slow diffusion of methanol into a saturated CH₂Cl₂ solution at room temperature.

As shown, the molecular structure of 5 -fac reveals a slightly distorted octahedral arrangement. Due to the lack of C3 symmetry in crystal lattices, all six Ir—C distances are slightly different, among which the facially arranged carbenic Ir-C distances (Ir1—C1=2.019(5), Ir1—C20=2.031(4) and Ir1-C39=2.027(4) Å) are found to be notably shorter than the corresponding trans-Ir—C distance of phenyl cyclometalates (Ir1—C15=2.088(4), Ir1—C34=2.093(4) and Ir1—C53=2.090(4) Å). This metric data suggests that the Ir—C(carbene) bond strength is notably greater than that of Ir—C_{(phenyl)} groups, which is in accordance with other structurally characterized homoleptic Ir(III) complexes with electron deficient carbene entities.

Photophysical Analysis

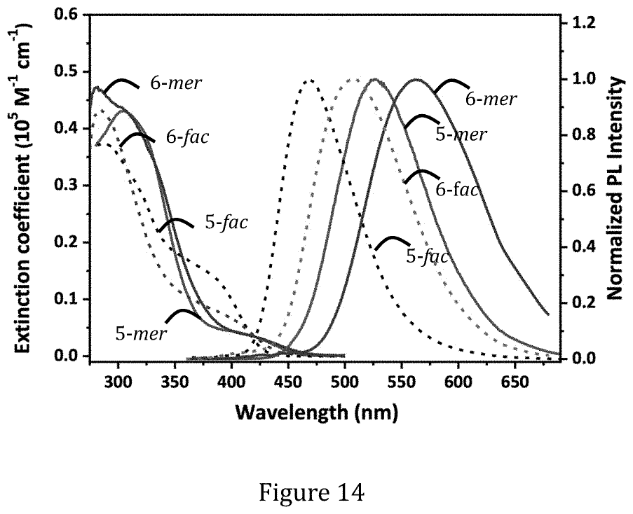

FIG. 14 depicts the UV-Vis absorption spectra of the above purin-8-ylidene Ir(III) complexes in toluene at room temperature, while Table 5 summarizes the corresponding metric parameters. As can be seen, 5-mer and 6-mer exhibited relatively intense ππ* absorption band in the high energy region between 280 nm-340 nm, and the absorption extinction coefficient (c) turned much smaller while moved into the lowered energy region. The corresponding lower energy absorption band at 408 nm and 428 nm can be assigned to the metal-to-ligand charge transfer (MLCT) absorption. Alternatively, the respective f-isomer showed a slightly less intensive absorption band at higher energy region of 310 nm-350 nm and, upon further moving to lower energy region, the corresponding MLCT absorption band occurred at 383 nm and 397 nm and retained a relatively higher extinction coefficient (c) in comparison to the m-counterparts. This spectral pattern may be related to the asymmetric arrangement off-isomers and is universal to all relevant existing homoleptic Ir(III) carbene complexes.

TABLE 5
Photophysical data of the purin-8-ylidene-based Ir(III) metal complexes
at room temperature.

| | abs λₘₐₓ^{[a]} | PL λₘₐₓ^{[a]} | FWHM^{[b]} | Φ^{[c][d]} | τ_{obs}^{[d]} | τ_{rad}^{[d]} | kᵣ | kₙᵣ |
|---|---|---|---|---|---|---|---|---|
| Complex | (nm) | (nm) | (cm⁻¹) | (%) | (μs) | (μs) | (10⁶ s⁻¹) | (10⁶ s⁻¹) |
| 5-mer | 304 (4.3), | 526 | 3253 | 81 | 0.92 | 1.14 | 0.88 | 0.21 |
| | 408 (0.4) | | | | | | | |
| 5-fac | 287 (3.7), | 468 | 3246 | 97 | 0.72 | 0.74 | 1.35 | 0.04 |
| | 383 (1.4) | | | | | | | |
| 6-mer | 280 (4.7), | 561 | 3493 | 66 | 0.81 | 1.23 | 0.81 | 0.42 |
| | 428 (0.3) | | | | | | | |
| 6-fac | 284 (4.3), | 508 | 3605 | 71 | 0.76 | 1.07 | 0.93 | 0.38 |
| | 397 (0.7) | | | | | | | |

^{[a]}Recorded at a concentration of 10⁻⁵ M in degassed toluene at room temperature; extinction coefficient (ε) is given in parentheses with a unit of 10⁴ M⁻¹ · cm⁻¹
^{[b]}Full width at half maximum.
^{[c]}Coumarin 102 (C102) in methanol (Q.Y. = 87% and λₘₐₓ = 480 nm) were employed as standard.
^{[d]}Observed lifetime as calculated from transient PL spectra.

Furthermore, as depicted in FIG. 14, both f-isomers showed the relatively blue-shifted emission peak max. at 468 nm and 508 nm. The corresponding m-isomers exhibited more red-shifted emission with peak max. at 526 nm and 561 nm, respectively. Moreover, the introduction of phenyl substituent, with slightly greater electron withdrawing character and greater π-conjugation, are responsible to the red shifting as observed in both 6-mer and 6-fac vs. the 5-mer and 5-fac derivatives. Also, both the f-isomers possess a slightly higher emission quantum yield and faster radiative rate constant (kᵣ) in comparison to their m-counterparts. Concomitantly, both the 6-mer and 6-fac derivatives, possess a systematically lowered quantum yield, reduced radiative rate constant, and increased non-radiative constant vs. those of 5-mer and 5-fac, highlighting the influence of the phenyl appendage.

Their emission spectra were recorded in PMMA thin film at a doping concentration of 2 wt % for making comparison to those observed in degassed toluene solution. As indicated in Table 6, except for 5-fac, which exhibited a slight red shifting from 468 nm to 474 nm, all other samples showed a notable blue shifting, giving structureless emission with peak max. at 509 nm, 530 nm and 490 nm for 5-mer, 6-mer and 6-fac, respectively. Hence, the associated f- and m-isomers can be considered to possess the genuine blue and sky-blue emission, respectively.

TABLE 6
Summarized photophysical data of the Ir(III) complexes in PMMA
thin films.

| | PL λₘₐₓ^{(a)} | FWHM^{(b)} | τ_{obs}^{(a)} |
|---|---|---|---|
| Complex | (nm) | (cm⁻¹/nm) | [μs] |
| 5-mer | 509 | 3868/102 | 0.72 |
| 5-fac | 474 | 3452/80 | 0.69 |
| 6-mer | 530 | 3811/111 | 0.65 |
| 6-fac | 490 | 3907/96 | 0.42 |

^{(a)}Measured in PMMA thin films at 2 wt. % at room temperature.
^{(b)}FWHM: full width at half maxima of PL emission peak max. in both cm⁻¹ and nm.

### Example 3

### Imidazo[4,5-b]Pyrazin-2-Ylidene-Based Ir(III) Metal Complexes

Synthesis of Imidazo[4,5-b]Pyraz-3-Ium Pro-Chelates (timpzH₂·OTf, t2impzH₂·OTf, t2empzH₂·OTf, and t2phmpzH₂·OTf)

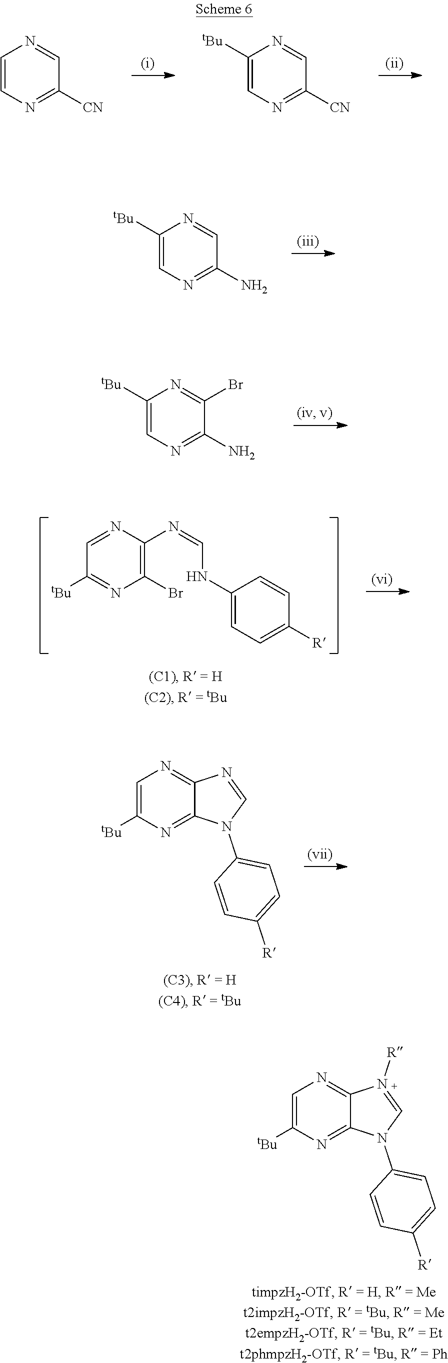

In Scheme 6, the reaction starts from commercially available pyrazinecarbonitrile, to which the tert-butyl group was introduced utilizing

Minisci alkylation, in presence of both silver triflate and pivalic acid, as well as (NH₄)25208 at 80° C. (i). After that, the cyano group was converted to an amino group using a mixture of sodium hypochlorite and sodium hydroxide solution by way of Hofman rearrangement at 80° C. (ii).

Bromination was next performed using N-bromosuccinimide at 0° C. (iii) in giving 3-bromo-5-(tert-butyl)pyrazin-2-amine. After that, the formamidine derivatives (C1) and (C2) were obtained by treatment of 3-bromo-5-(tert-butyl)pyrazin-2-amine with triethyl orthoformate at 140° C. in presence of catalytic amount of concentrated HCl (iv), followed by condensation of respective formimidate intermediate with aniline or 4-tert-butyl aniline at 140° C. (v).

The formamidine was next cyclized in presence of 1,8-diazabicyclo[5.4.0]undec-7-ene and CuI catalyst at 120° C. (vi) to afford the 1-aryl-imidazo[4,5-b]pyrazine (C3) and (C4) in adequate yields.

In the final step, the N-alkylation was performed using alkyl trifluoromethanesulfonate and methyl triflate or ethyl triflate at room temperature (vii) to give imidazo[4,5-b]pyraz-3-ium derivatives, timpzH₂·OTf, t2impzH₂·OTf, and t2empzH₂·OTf. This N-alkylation reaction is expected to occur at either the imidazolyl or pyrazinyl nitrogen sites and to afford a mixture of inseparable products. This isomeric mixture was directly employed for the subsequent coordination reaction with iridium metal reagent without further purification.

Alternatively, the N-arylation of 6-(tert-butyl)-1-aryl-1H-imidazo [4,5-b]pyrazine was performed using diphenyliodonium triflate in DMF solution of (4) at 100° C. in the presence of Cu(AcO)₂ to give the imidazo[4,5-b]pyraz-3-ium derivative, t2phmpzH₂·OTf.

Synthesis of Imidazo[4,5-b]Pyrazin-2-Ylidene-Based Ir(III) Metal Complexes (7-mer, 7-fac, 8-mer, 8-fac, 9-mer, and 9-fac)

A respective degassed tert-butylbenzene (20 mL) solution of timpzH₂·OTf (0.416 g, 1 mmol), t2impzH₂·OTf (0.416 g, 1 mmol), and t2empzH₂·OTf (0.416 g, 1 mmol), NaOAc (0.33 g, 4 mmol) and m-trichloridotris(tetrahydrothiophene-κ^{S})iridium(III) (m-IrCl₃(tht)₃, 0.113 g, 0.2 mmol) was refluxed for 12 hours. After removal of solvent, the residue was taken into CH₂Cl₂ solution. The organic phase was washed with deionized water and separated and concentrated to dryness. This gave a mixture off- and m-stereoisomers. The residue was further purified by column chromatography eluting with n-hexane/EA (6/1, v/v), followed by recrystallization to obtain a yellow solid 7-mer (25 mg, 13%) and a light-yellow solid of 7-fac (83 mg, 42%), a yellow solid 8-mer (70 mg, 35%) and a light-yellow solid of 8-fac (20 mg, 10%), a yellow solid 9-mer (172 mg, 66%) and a light-yellow solid of 9-fac (13 mg, 5%), respectively.

Synthesis of Imidazo[4,5-b]Pyrazin-2-Ylidene-Based Ir(III) Metal Complexes (10-fac,11-fac, and 12-fac)

A degassed tert-butylbenzene (10 mL) solution of t2phmpzH₂·OTf (0.29 g, mmol), NaOAc (1.64 g, 2 mmol) and m-trichloridotris(tetrahydrothiophene-κ^{S})iridium(III) (m-IrCl₃(tht)₃, 0.112 g, 0.2 mmol) was refluxed for 12 hours. After removal of solvent, the residue was taken into CH₂Cl₂ solution. The organic phase was washed with deionized water and separated and concentrated to dryness. This gave a mixture of three f-stereoisomers. The residue was further purified by column chromatography eluting with n-hexane/EA (3/1, v/v), followed by recrystallization to obtain a yellow solid 10-fac (30 mg, 11%), a yellow solid 11-fac (54 mg, 20%) and a light-yellow solid 12-fac (81 mg, 30%), respectively. Sequential conversion from 10-fac to 11-fac and, finally to 12-fac can be achieved by heating an o-dichlorobenzene solution of either 10-fac or 11-fac in presence of trifluoroacetic acid, or NaOAc (or potassium acetate) as catalyst.

Notably, their synthetic yields were affected by the employed imidazo[4,5-b]pyraz-3-ium pro-chelates, among which t2empzH₂·OTf gave the highest overall yields of 71% (i.e., as a mixture of m- and f-isomers) in reference to other chelates. Moreover, the relative yield off-isomers was found to decrease upon introduction of tert-butylphenyl and N-ethyl substituent to the imidazo[4,5-b]pyrazin-2-ylidene fragments. Despite of this difficulty, the acid-sensitive isomerization can be applied for effective conversion of m-isomers to their f-counterparts.

In these carbene complexes, both m- and f-isomers depicted decomposition and isomerization reactions above 330° C. during sublimation, making thermal deposition an infeasible method for OLED fabrication. This behavior is akin to the known poor stability for the homoleptic carbene emitter with dimethylfluorenyl cyclometalate, which is a common issue of blue phosphors for OLEDs.

In sharp contrast, three imidazo[4,5-b]pyrazin-2-ylidene-based Ir(III) metal complexes (10-fac, 11-fac, and 12-fac) are much more durable under all experimental conditions. Particularly, 12-fac can be heated to over 200° C. for over 2 days and showed no sign of decomposition. This class of derivatives should be highly suitable to serve as the desired OLED emitters with elongated operational lifetime.

Spectroscopic and Structural Analysis

The structures of each of 7-mer, 7-fac, 8-mer, 8-fac, 9-mer, 9-fac were verified by ¹H NMR spectroscopy and MALDI-TOF mass spectrometry.

Spectral data of 7-mer is provided as follows: MS (MALDI-TOF, ¹⁹³Ir): m/z 988.50586 [M⁺]; ¹H NMR (400 MHz, CDCl₃, 296 K): δ 8.77 (d, J=7.8 Hz, 1H), 8.74 (d, J=7.8 Hz, 1H), 8.70 (d, J=7.8 Hz, 1H), 8.36 (s, 1H), 8.35 (s, 1H), 8.29 (s, 1H), 7.14-7.03 (m, 3H), 6.99-6.94 (m, 2H), 6.83 (t, J=7.2 Hz, 1H), 6.79 (t, J=7.2 Hz, 1H), 6.76 (t, J=7.2 Hz, 1H), 6.66 (d, J=7.2 Hz, 1H), 3.39 (s, 3H), 3.39 (s, 3H), 3.28 (s, 3H), 1.54 (s, 9H), 1.54 (s, 9H), 1.53 (s, 9H). Anal. Calcd. for C₄₈H₅₁IrN₁₂: C, 58.34; H, 5.20; N, 17.01. Found: C, 58.30; H, 5.21; N, 17.03.

Spectral data of 7-fac is provided as follows: MS (MALDI-TOF, ¹⁹³Ir): m/z 989.46875 [M+H⁺]; ¹H NMR (400 MHz, CDCl₃, 296 K): δ 8.75 (d, J=7.6 Hz, 3H), 8.30 (s, 3H), 7.16 (td, J=7.6, 1.2 Hz, 3H), 6.84 (td, J=7.6, 1.2 Hz, 3H), 6.62 (d, J=7.6 Hz, 3H), 3.43 (s, 9H), 1.54 (s, 27H). Anal. Calcd. for C₄₈H₅₁IrN₁₂: C, 58.34; H, 5.20; N, 17.01. Found: C, 58.36; H, 5.18; N, 16.98.

Spectral data of 8-mer is provided as follows: MS (MALDI-TOF, ¹⁹³Ir): m/z 1157.62402 [M+H⁺]; ¹H NMR (400 MHz, CDCl₃, 296 K): δ 8.64 (d, J=8.0 Hz, 1H), 8.63 (d, J=8.0 Hz, 1H), 8.53 (d,J=8.0 Hz, 1H), 8.33 (s, 1H), 8.32 (s, 1H), 8.28 (s, 1H), 7.15-7.08 (m, 4H), 6.93 (d, J=2.0 Hz, 1H), 6.72 (d, J=2.0 Hz, 1H), 3.50 (s, 3H), 3.33 (s, 3H), 3.28 (s, 3H), 1.53 (s, 9H), 1.52 (s, 9H), 1.51 (s, 9H), 1.12 (s, 9H), 1.12 (s, 9H), 1.11 (s, 9H). Anal. Calcd. for C₆₀H₇₅IrN₁₂: C, 62.31; H, 6.54; N, 14.53. Found: C, 62.25; H, 6.60; N, 14.54.

Spectral data of 8-fac is provided as follows: MS (MALDI-TOF, ¹⁹³Ir): m/z 1157.70337 [M+H⁺]; ¹H NMR (400 MHz, CDCl₃, 296 K): δ 8.59 (d, J=8.2 Hz, 3H), 8.27 (s, 3H), 7.16 (dd, J=8.2, 2.2 Hz, 3H), 6.61 (d, J=2.2 Hz, 3H), 3.47 (s, 9H), 1.52 (s, 27H), 1.08 (s, 27H). Anal. Calcd. for C₆₀H₇₅IrN₁₂: C, 62.31; H, 6.54; N, 14.53. Found: C, 62.28; H, 6.58; N, 14.50.

Spectral data of 9-mer is provided as follows: MS (MALDI-TOF, ¹⁹³Ir): m/z 1198.62219 [M⁺]; ¹H NMR (400 MHz, CDCl₃, 296 K): δ 8.61 (d,J=8.2 Hz, 2H), 8.53 (d, J=8.2 Hz, 1H), 8.34 (s, 1H), 8.32 (s, 1H), 8.26 (s, 1H), 7.11 (dd, J=8.2, 2.0 Hz, 1H), 7.07 (dd, J=8.2, 2.0 Hz, 1H), 7.05 (dd, J=8.2, 2.0 Hz, 1H), 7.02 (d,J=2.0 Hz, 1H), 6.91 (d, J=2.0 Hz, 1H), 6.65 (d, J=2.0 Hz, 1H), 4.09-3.84 (m, 5H), 3.61 (dq, J=13.2, 7.2 Hz, 1H), 1.53 (s, 18H), 1.51 (s, 9H), 1.09 (s, 9H), 1.08 (s, 9H), 1.07 (s, 9H), 0.97 (t, J=7.2 Hz, 6H), 0.85 (t, J=7.2 Hz, 3H). Anal. Calcd. for C₆₃H₈₁IrN₁₂: C, 63.13; H, 6.81; N, 14.02. Found: C, 63.08; H, 6.83; N, 13.99.

Spectral data of 9-fac is provided as follows: MS (MALDI-TOF, ¹⁹³Ir): m/z 1198.68213 [M⁺]; ¹H NMR (400 MHz, CDCl₃, 296 K): δ 8.57 (d, J=8.2 Hz, 3H), 8.26 (s, 3H), 7.11 (dd, J=8.2, 2.0 Hz, 3H), 6.57 (d, J=2.0 Hz, 3H), 4.14 (dq, J=14.0, 7.2 Hz, 3H), 3.93 (dq, J=14.0, 7.2 Hz, 3H), 1.52 (s, 27H), 1.06 (s, 27H), 0.86 (t, J=7.2 Hz, 9H). Anal. Calcd. for C₆₃H₈₁IrN₁₂: C, 63.13; H, 6.81; N, 14.02. Found: C, 63.11; H, 6.85; N, 13.97.

Spectral data of 10-fac is provided as follows: MS (MALDI-TOF, ¹⁹³Ir): m/z 1343.63631 [M+H⁺];¹H NMR (400 MHz, CDCl₃) δ 8.67 (d, J=8.2 Hz, 3H), 8.11 (s, 3H), 7.19 (dd, J=8.4, 2.0 Hz, 3H), 6.80 (t, J=7.2 Hz, 3H), 6.76 (d, J=2.0 Hz, 3H), 6.60 (br, 6H), 1.57 (s, 27H), 1.13 (s, 27H). Anal. Calcd. for C₇₅H₈₁IrN₁₂: C, 67.09; H, 6.08; N, 12.52. Found: C, 67.11; H, 6.05; N, 12.48.

Spectral data of 11-fac is provided as follows: MS (MALDI-TOF, ¹⁹³Ir): m/z 1343.63521 [M+H⁺]; ¹H NMR (400 MHz, CDCl₃, 296 K) δ 8.80 (d, J=8.4 Hz, 1H), 8.73 (d, J=7.6 Hz, 1H), 8.57 (d, J=8.4 Hz, 1H), 8.38 (s, 1H), 8.11 (s, 1H), 8.05 (s, 1H), 7.23 (dd, J=8.0, 2.4 Hz, 1H), 7.17 (td, J=8.0, 1.6 Hz, 1H), 7.11 (dd, J=8.0, 2.4 Hz, 1H), 6.84 (td, J=7.2, 0.8 Hz, 1H), 6.81-6.67 (m, 6H), 6.56 (d, J=2.0 Hz, 1H), 6.33 (s, 4H), 1.55 (s, 9H), 1.52 (s, 9H), 1.38 (s, 9H), 1.12 (s, 9H), 1.05 (s, 9H), 1.00 (s, 9H). Anal. Calcd. for C₇₅H₈₁IrN₁₂: C, 67.09; H, 6.08; N, 12.52. Found: C, 67.09; H, 6.10; N, 12.49.

Spectral data of 12-fac is provided as follows: MS (MALDI-TOF, ¹⁹³1r): m/z 1343.63331 [M+H⁺]; ¹H NMR (400 MHz, CDCl₃, 296 K) δ 8.90 (d, J=8.0 Hz, 1H), 8.69 (d, J=8.0 Hz, 1H), 8.67 (d, J=8.0 Hz, 1H), 8.42 (s, 1H), 8.34 (s, 1H), 8.07 (s, 1H), 7.23 (t, J=7.2 Hz, 1H), 7.19-7.11 (m, 2H), 6.88 (t, J=7.2 Hz, 1H), 6.82-6.77 (m, 2H), 6.70 (t, J=7.2 Hz, 1H), 6.65-6.61 (m, 2H), 6.44 (br, 2H), 6.17 (br, 4H), 1.52 (s, 9H), 1.38 (s, 9H), 1.26 (s, 9H), 1.06 (s, 9H), 1.01 (s, 9H), 1.00 (s, 9H). Anal. Calcd. for C₇₅H₈₁IrN₁₂: C, 67.09; H, 6.08; N, 12.52. Found: C, 67.10; H, 6.11; N, 12.55.

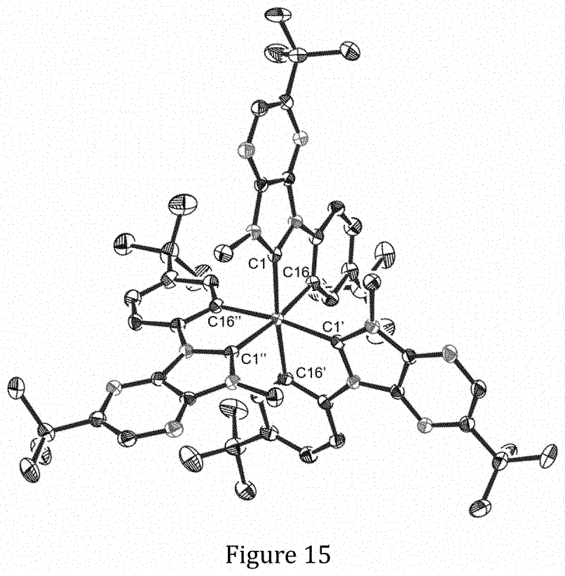

Single-crystal X-ray structural analysis was carried out for 8-fac to provide confirmation of the identity of chelates and gross coordination arrangement of these Ir(III) complexes. The structure of 8-fac is shown in FIG. 15, wherein thermal ellipsoids are shown at 30% probability level, with selected bond lengths (Å) being Ir—C(1)=2.0145(18) and Ir—C(16)=2.0892(19), selected bond angles (°) being C(1)—Ir—C(16)=78.23(7), and hydrogen atoms are omitted for clarity. The single crystal of 8-fac suitable for X-ray diffraction study was obtained via the slow diffusion of methanol into a saturated CH₂Cl₂ solution at room temperature. It crystallized in a trigonal crystal system with space group P-3c1 and, as expected, all three carbene cyclometalates have identical Ir—C(carbene) distance of 2.0145(18) Å and Ir—C(phenyl) distance of 2.0892(19) Å. Its Ir—C(carbene) distance is notably shorter, confirming the increased π-accepting character, particularly in comparison to that of electron deficient triazolylidene fragment.

Photophysical Analysis

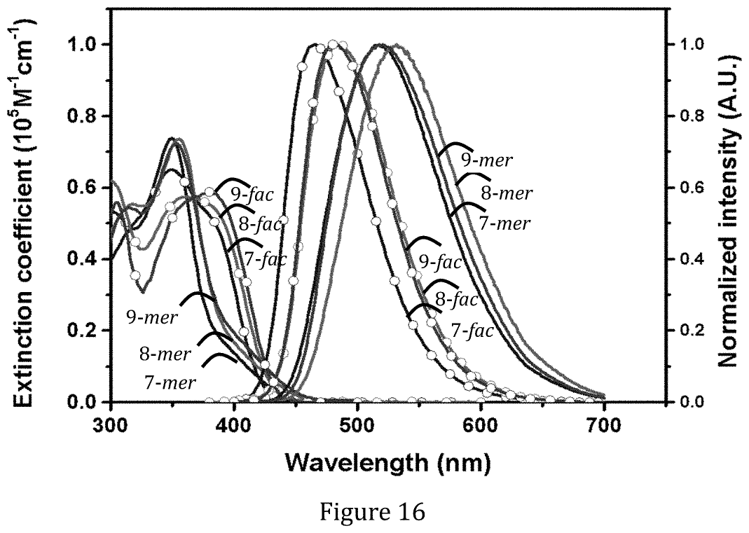

FIG. 16 depicts the UV-Vis absorption and emission spectra of the above Ir(III) imidazo[4,5-b]pyrazin-2-ylidene complexes in degassed toluene at room temperature. Table 7 shows the corresponding numerical data. As shown, all Ir(III) complexes exhibited intense absorption bands in 320-370 nm, which can be ascribed to ligand-centered (LC) ππ* and/or inter-ligand charge transfer transitions. For m-isomer, the weak absorption bands at 380 nm and onward, with lower absorption extinction coefficient, are attributed to a metal-to-ligand charge transfer (MLCT) transition. Notably, all f-isomers present relatively more intense absorption spanning the region 350-400 nm, to which the higher absorption extinction coefficient could be due to the co-existence of three symmetrically arranged carbene cyclometalates.

TABLE 7
Photophysical data of the tris-bidentate Ir(III) carbene complexes at room
temperature.

| | abs λₘₐₓ^{a} | em λₘₐₓ^{a} | FWHM^{b} | Φ^{c} | τ_{obs} | τ_{rad} | kᵣ | kₙᵣ |
|---|---|---|---|---|---|---|---|---|
| Complex | W | (nm) | (nm) | (%) | (μs) | (μs) | (10⁶ s⁻¹) | (10⁶ s⁻¹) |
| 7-mer | 350 (0.74) | 518 | 103 | 46 | 0.424 | 0.922 | 1.08 | 1.27 |
| 7-fac | 350 (0.65), | 466 | 75 | 74 | 1.635 | 2.21 | 0.453 | 0.159 |
| | 380 (0.52) | | | | | | | |
| 8-mer | 318 (0.55), | 532 | 104 | 45 | 0.187 | 0.415 | 2.4 | 2.9 |
| | 356 (0.74) | | | | | | | |
| 8-fac | 362 (0.58) | 485 | 81 | 58 | 0.958 | 1.65 | 0.605 | 0.438 |
| 9-mer | 314 (0.55), | 518 | 107 | 48 | 0.253 | 0.53 | 1.89 | 2.05 |
| | 354 (0.72) | | | | | | | |
| 9-fac | 306 (0.56), | 483 | 79 | 53 | 0.696 | 1.31 | 0.761 | 0.675 |
| | 380 (0.59) | | | | | | | |

^{a}Recorded at a concentration of 10⁻⁵ M in degassed toluene at room temperature; extinction coefficient (ε) is given in parentheses with a unit of 10⁵ M⁻¹ · cm⁻¹
^{b}Full width at half maximum.
^{c}Coumarin 153 (C153) in ethanol (Q.Y. = 58% and λₘₐₓ = 530 nm) and Coumarin 102 (C102) in methanol (Q.Y. = 87% and λₘₐₓ = 480 nm) were employed as standard.

For the photoluminescence, all Ir(III) complexes displayed structureless profiles with relatively broadened FWHM of 75-107 nm, showing the dominated MLCT contribution. However, m- and f-isomers possessed distinctive emission properties, particularly the emission wavelengths. This is evident by the occurrence of peak max. at 518 nm, 532 nm, and 518 nm for 7-mer, 8-mer, and 9-mer, respectively. In the meantime, their f-isomers displayed a hypochromic shifted peak max. at 466 nm, 485 nm, and 483 nm, respectively. The difference in emission peak max. between m- and f-isomers has been rationalized by the greater degree of MLCT contribution in m-isomers that is induced by possible ligand-to-ligand charge transfer processes.

Moreover, introduction of tert-butylphenyl cyclometalates induced a more red-shifted emission wavelength, comparing the spectral profiles of 7-mer and 8-mer. The variation in emission of the f-isomers, i.e., 7 -fac and 8-fac, was consistent with this trend, as the electron-donating ability of tert-butyl substituent would increase the electron density at the Ir(III) metal center and, hence, result in a much reduced MLCT transition energy gap.

Upon replacing N-methyl group of 8-mer with N-ethyl group in giving 9-mer, the emission is blue-shifted from 532 nm to 518 nm. Since both methyl and ethyl substituents possess similar electronic properties, this change in peak wavelength is believed to be related to the solvatochromism, exerted by the less polar N-ethyl substituents. This hypothesis is confirmed by a small variation in emission wavelength between the respective f-isomers, i.e., 8-fac (485 nm) and 9-fac (483 nm), as a result of inherently reduced MLCT contribution.

The photoluminescence quantum yields (PLQYs) were also measured. Particularly, the f-isomers were more efficient than their m-counterparts. Their radiative lifetimes, radiative and non-radiative rate constants were calculated and the data were listed in Table 7. Notably, the radiative lifetimes (and radiative rate constants) of all m-isomers were found to be shorter (and smaller) than their f-isomers, which may be attributed to the lowered emission energy and greater MLCT contribution at the excited states. Furthermore, the Ir(III) complexes bearing tert-butylphenyl cyclometalates, i.e., 8-mer and 8-fac and 9-mer and 9-fac, showed both the greater radiative and non-radiative rate constants, which can be due to the higher electron donating character and solution fluxionality of the additional tert-butyl appendages. Most importantly, the blue emission and higher PLQY of the f-isomers make them better candidates for fabrication of blue OLEDs.

Electroluminescence Analysis

To investigate the electroluminescent (EL) properties of NHC-based Ir(III) metal phosphors, solution-processed OLEDs were fabricated using the following architecture: an indium tin oxide (ITO) electrode, poly(3,4-ethylenedioxythiophene): polystyrenesulfonic acid (PEDOT:PSS; 50 nm), the combination of Ir(III) complexes and BCzBN doped in 1,3-di(9H-carbazol-9-yl)benzene (mCP) (30 nm)/bis[2-(diphenylphosphino)phenyl]ether oxide (DPEPO; 10 nm), 1,3,5-tri(3-pyridyl-3-phenyl)benzene (TmPyPB; 50 nm), 8-hydroxyquinolinolato-lithium (Liq; 1 nm), and an aluminum electrode (100 nm). In these devices, PEDOT:PSS and Liq were served as hole- and electron-injection layers, respectively. TmPyPB was employed as an electron-transporting material, and DPEPO was used as the hole-blocking layer. mCP served as the host material for the devices. The chemical structures of the materials are shown below.

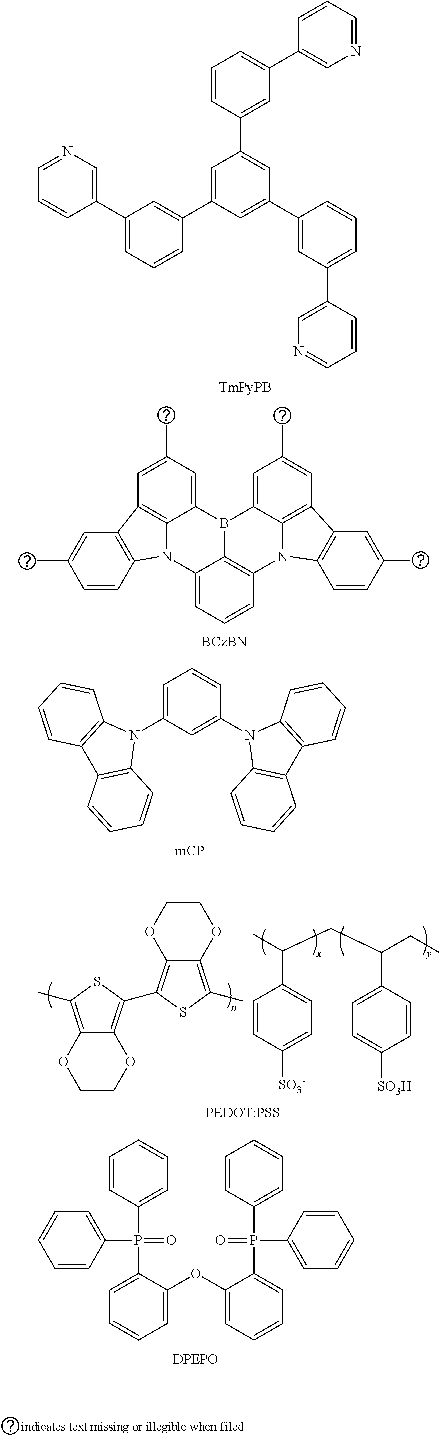

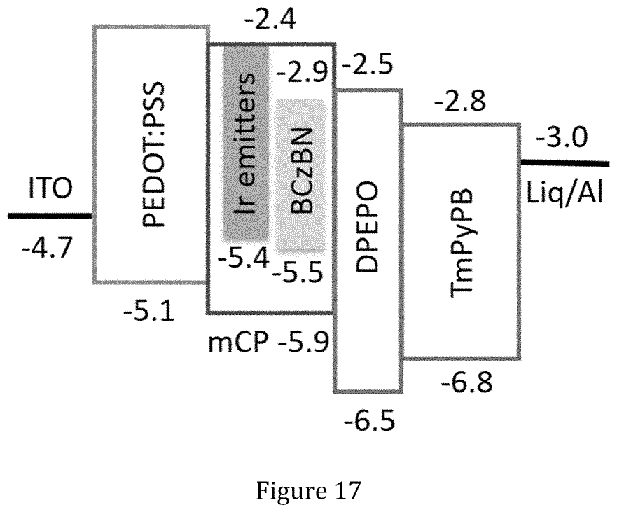

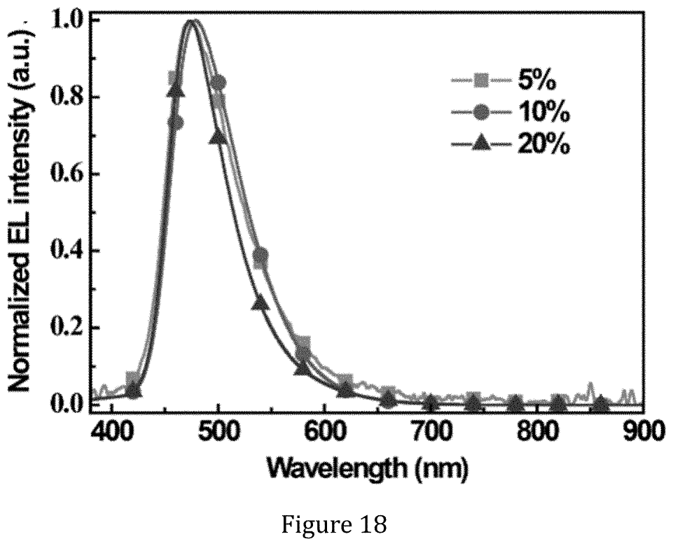

The energy levels of the employed materials were schematically depicted in FIG. 17. Among these Ir(III) emitters, 9-fac presented good solubility in majority of organic solvents and exhibited moderate emission properties. Hence, 9-fac was selected to evaluate the electroluminescent (EL) properties. As shown in FIG. 18, the 9-fac-based devices presented a sky-blue emission with the peak wavelength located between 474-480 nm at doping concentration of 5-20 wt %. The small fluctuation in the EL spectral profiles exemplified the suppressed intermolecular interaction due to the presence of bulky tert-butyl groups.

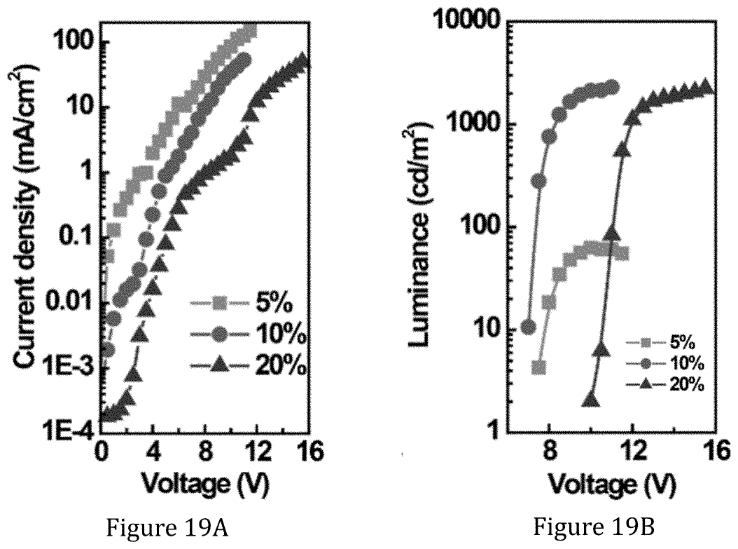

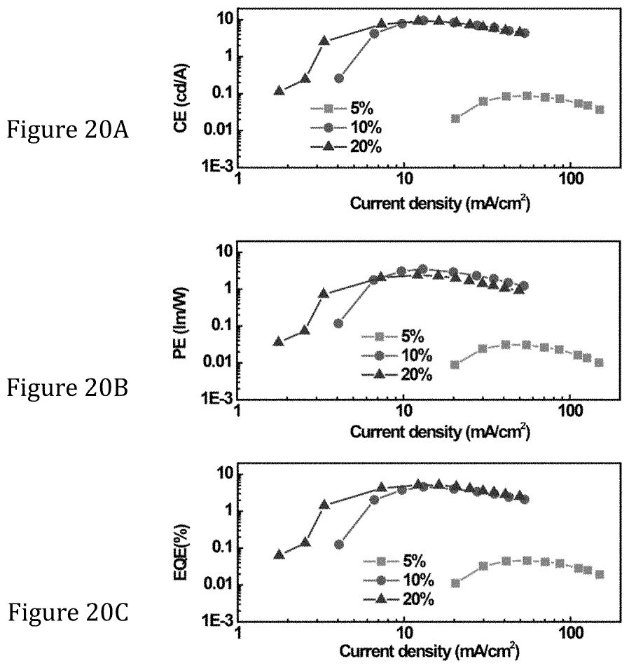

Relatively poor performances were observed at a low doping concentration of 5 wt %. The poor device performances can be ascribed to the carrier leakage or imbalanced carriers in the emissive layers. To improve the device performances, OLEDs with higher doping levels at 10 and 20 wt % were fabricated. The electroluminescent characteristics and corresponding data are shown in FIGS. 18 to 20C and Table 8. The performances were dramatically increased at a doping concentration of 20 wt %, giving a respectable maximum external quantum efficiency (EQE) of 5.1%, and high luminance (L) over 2000 cd m⁻².

TABLE E
Performances of the solution-processed phosphorescent OLED devices.

| | Concentration | EL λₘₐₓ | Maximum efficiency | | | |
|---|---|---|---|---|---|---|
| Guest | (%) | (nm) | CE (cd/A) | PE (lm/W) | EQE (%) | L (cd m⁻²) |
| 9-fac | 5 | 474 | 0.08 | 0.05 | 0.05 | 63 |
| 9-fac | 10 | 480 | 9.5 | 3.5 | 4.6 | 2294 |
| 9-fac | 20 | 474 | 9.1 | 2.4 | 5.1 | 2229 |

To maximize the application potential of these phosphors, the solution processed hyper-OLEDs (hyperphosphorescence) were designed. This is based on an understanding that the Ir(III) phosphors with the shortened radiative lifetime can sensitize the multi-resonance thermally activated delayed fluorescence (MR-TADF) emitter such as BCzBN with the unfavorably long delayed lifetime 50 μs. In view of the overall EL performances recorded in aforementioned binary devices, 10 wt % doping level was selected to achieve optimal carrier balance and Forster resonance energy transfer (FRET).

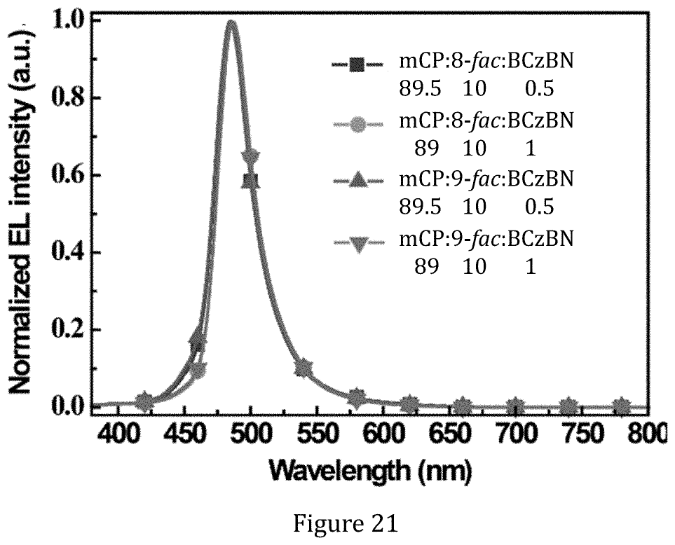

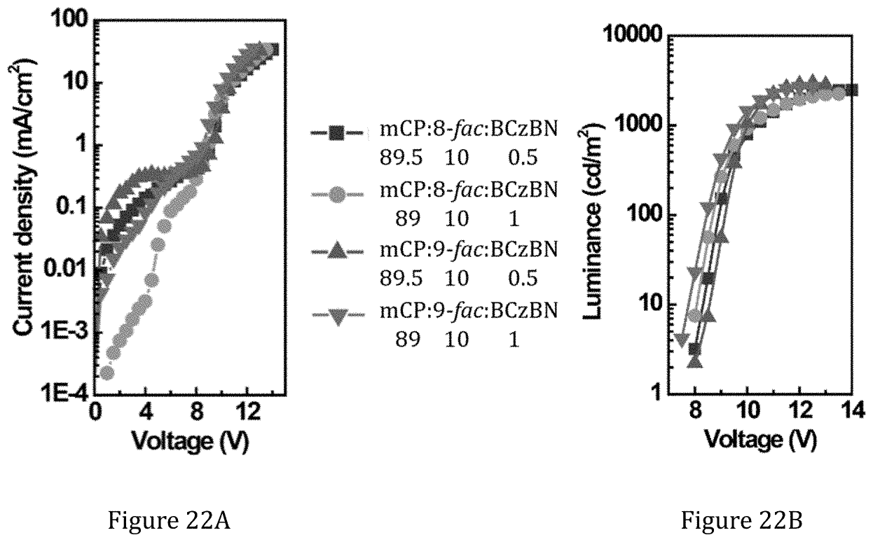

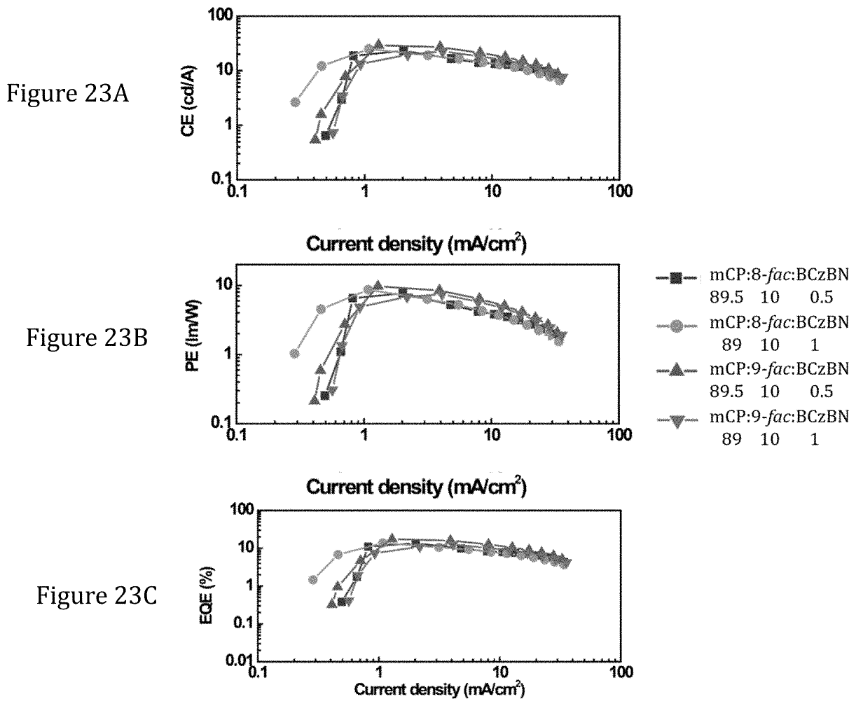

As depicted in FIGS. 21 to 23C and Table 9, narrowband emission with a full width at half maximum (FWHM) of 32 nm was successfully obtained. Meanwhile, regardless of the chosen sensitizer (8-fac or 9-fac), a sky-blue narrowband emission was observed, peaking at 485 nm, confirming the efficient energy transfer from the Ir(III) assistant sensitizer to the MR-TADF terminal emitter BCzBN. More impressively, the champion device was successfully achieved using 10 wt % of 9-fac and 0.5 wt % of BCzBN doped in the common host material mCP, giving a sky-blue emission with maximum EQE and luminance of 17.4% and 2978 cd m⁻², respectively, which are superior to the binary devices consisting of only the TADF host and BCzBN emitter with the red-shifted EL peak max. at around 490 nm. This result also provides a supplement to the reports on hyper-OLEDs using vacuum deposited phosphorescent sensitizer and blue emissive terminal emitter.

TABLE 9
Performances of solution-processed OLED devices with common host
material mCP.

| | | | | Maximum efficiency | | | |
|---|---|---|---|---|---|---|---|
| | Concentration | EL λₘₐₓ | FWHM | CE | PE | EQE | L |
| Guest | (%) | (nm) | (nm) | (cd/A) | (lm/W) | (%) | (cd m⁻²) |
| 8-fac: BCzBN | 10:0.5 | 485 | 32 | 23.2 | 7.7 | 13.7 | 2476 |
| 8-fac: BCzBN | 10:1 | 485 | 32 | 24.8 | 8.7 | 13.8 | 243 |
| 9-fac: BCzBN | 10:0.5 | 485 | 32 | 29.2 | 9.7 | 17.4 | 2978 |
| 9-fac: BCzBN | 10:1 | 485 | 32 | 22.6 | 7.5 | 12.6 | 2702 |

Accordingly, the present invention provides strategical approaches that afford the desired Ir(III) metal complexes bearing distinctive, functional 7,9-dihydro-8H -purin-8 -ylidene chelates, CF₃-substituted 8H -purin-8 -ylidene chelates, and 1,3 -dihydro-2 H -imidazo [4,5-b]pyrazin-2 -ylidene chelates with cyclometalating appendages, while its second N-aryl group is replaced by an alkyl functional group or even an non-cyclometalating aryl substituent. This new design would allow only one coordination possibility for carbene chelates and, hence, effectively inhibit formation of multiple isomers. Moreover, the added tert-butyl substituent, together with other essential structural features, can offer improvement to their chemical stability and the capability of fine-tuning photophysical properties of the as-prepared Ir(III)-based carbene phosphors.

It has been demonstrated that these carbene cyclometalate emitters possess both the m- and f-coordination modes, and efficient emission in the blue-to-purple spectral region, respectively. Both class of emitters can be utilized in fabrication of both the single dopant blue phosphorescent OLED devices, and efficient hyperphosphorescent OLED devices via efficient FRET. All homoleptic Ir(III) complexes with either m- and f-modes exhibited moderate to good photoluminescence in the fluid state with emission spanning from blue to green color at room temperature. The Ir(III) complexes in the present invention are true-blue emitters with very high emission efficiencies and short radiative lifetimes in solution, doped PMMA matrix and selected host materials of OLED devices. Short radiative lifetime may offer the elongated device stability urgently needed for blue emitters.

It will be appreciated by persons skilled in the art that numerous variations and/or modifications may be made to the invention as shown in the specific embodiments without departing from the spirit or scope of the invention as broadly described. The described embodiments of the invention should therefore be considered in all respects as illustrative, not restrictive.

1. A metal complex comprising a structure of Formula (I):
ML¹ₐL²_{b}L³_{c}L⁴_{d}L⁵ₑ (I),
where:
M is a transition metal;
L¹ is a bidentate ligand and a is an integer of 1 to 3;
L², L³, L⁴, and Ls are independently a monodentate ligand, or two adjacent L², L³, L⁴, and Ls is a bidentate ligand, and b, c, d, and e are independently an integer of 0 to 4;
a+b+c+d+e is 2, 3, 4, or 5; and
L¹ has a structure of Formula (II): 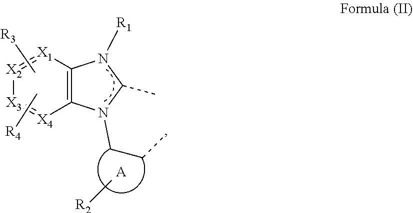
where:
A is a C₆₋₁₀ aryl ring or a 5 to 10 membered heteroaryl ring;
R₁ is selected from the group consisting of: C₁₋₆ alkyl, C₂₋₆ alkylether, C₁₋₆ alkoxy, C₁₋₆ fluoroalkyl, C₂₋₆ alkenyl, C₂₋₆ alkynyl, substituted or unsubstituted C₃₋₈ cycloalkyl, substituted or unsubstituted C₃₋₈ cycloalkenyl, substituted or unsubstituted 3 to 8 membered heterocycloalkyl, substituted or unsubstituted 3 to 8 membered heterocycloalkenyl, substituted or unsubstituted C₆₋₁₀ aryl, substituted or unsubstituted C₇₋₁₁ aralkyl, substituted or unsubstituted heteroaryl having 5 to 10 carbon atoms or heteroatoms, and substituted or unsubstituted heteroaralkyl having 6 to 11 carbon atoms or heteroatoms;
R₂, R₃, and R₄ are independently selected from the group consisting of:
hydrogen, deuterium, fluorine, cyano, C₁₋₆ alkyl, C₁₋₆ alkoxy, C₁₋₆ fluoroalkyl, substituted or unsubstituted C₆₋₁₀ aryl, and substituted or unsubstituted heteroaryl having 5 to 10 carbon atoms or heteroatoms; and
two of X₁, X₂, X₃, and X₄ are C, and the other two of X₁, X₂, X₃, and X₄ are N.

2. The metal complex according to claim 1, wherein M is selected from the group consisting of: iridium, rhodium, platinum, palladium, gold, osmium, and ruthenium.

3. The metal complex according to claim 1, wherein A is a phenyl ring.

4. The metal complex according to claim 1, wherein R₁ is selected from the group consisting of: C₁₋₆ alkyl, C₂₋₆ alkylether, C₁₋₆ alkoxy, C₁₋₆ fluoroalkyl, phenyl, substituted or unsubstituted C₆₋₁₀ aryl, and substituted or unsubstituted C₇₋₁₁ aralkyl.

5. The metal complex according to claim 4, wherein R₁ is methyl, ethyl, propyl, phenyl, p-tert-butylphenyl, m-tert-butylphenyl, 1,1′-biphenyl, p-trifluoromethylphenyl, or the corresponding deuterated derivative thereof.

6. The metal complex according to claim 1, wherein R_{2,} R_{3,} and R₄ are independently selected from the group consisting of: hydrogen, deuterium, fluorine, cyano, C₁₋₆ alkyl, C₁₋₆ fluoroalkyl, and substituted, unsubstituted C₆₋₁₀ aryl, or the corresponding deuterated derivative thereof

7. The metal complex according to claim 6, wherein R₂ is hydrogen, trifluoromethyl, tert-butyl, or phenyl.

8. The metal complex according to claim 6, wherein R₃ and R₄ are independently hydrogen, tert-butyl, trifluoromethyl, phenyl, or the corresponding deuterated derivative thereof.

9. The metal complex according to claim 1, wherein X₁ and X₄ are N, and R₃ and R₄ are different from each other.

10. The metal complex according to claim 1, wherein X₁ and X₃ are N, and R₃ and R₄ are different from each other. 10

11. The metal complex according to claim 1, wherein X₂ and X₄ are N, and R₃ and R₄ are different from each other.

12. The metal complex according to claim 9, wherein one of R₃ and R₄ is tert-butyl.

13. The metal complex according to claim 12, wherein the other one of R₃ and R₄ is hydrogen, trifluoromethyl, phenyl, or aryl.

14. The metal complex according to claim 1, wherein the metal complex is a homoleptic metal complex.

15. The metal complex according to claim 1, wherein the metal complex is a tris-bidentate metal complex with two pairs of two adjacent L², L³, L⁴, and L⁵ identical to L¹.

16. The metal complex according to claim 1, wherein the metal complex is a tris-bidentate metal complex with only one pair of two adjacent L², L³, L⁴, and L⁵ identical to L¹.

17. The metal complex according to claim 1, comprising a facial isomer or a meridional isomer.

18. The metal complex according to claim 1, wherein the metal complex is selected from one of the following:

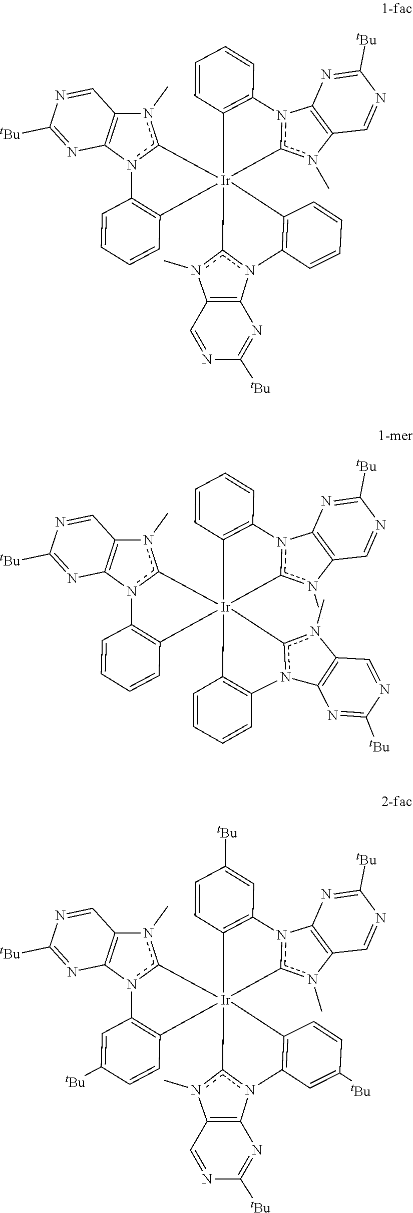

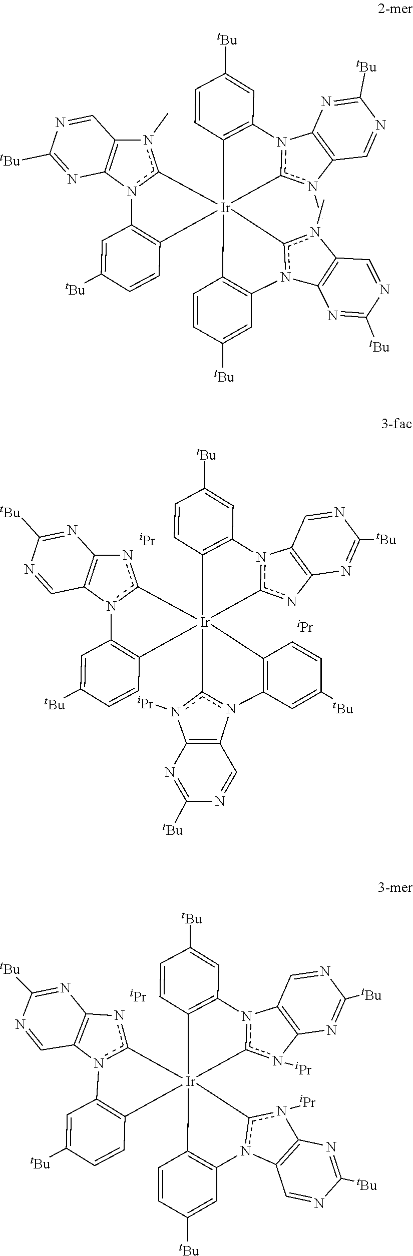

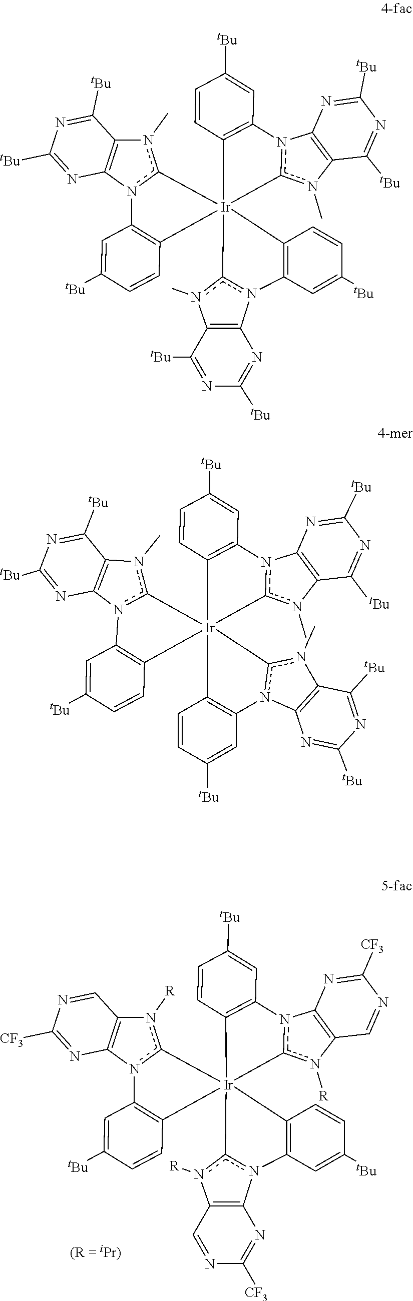

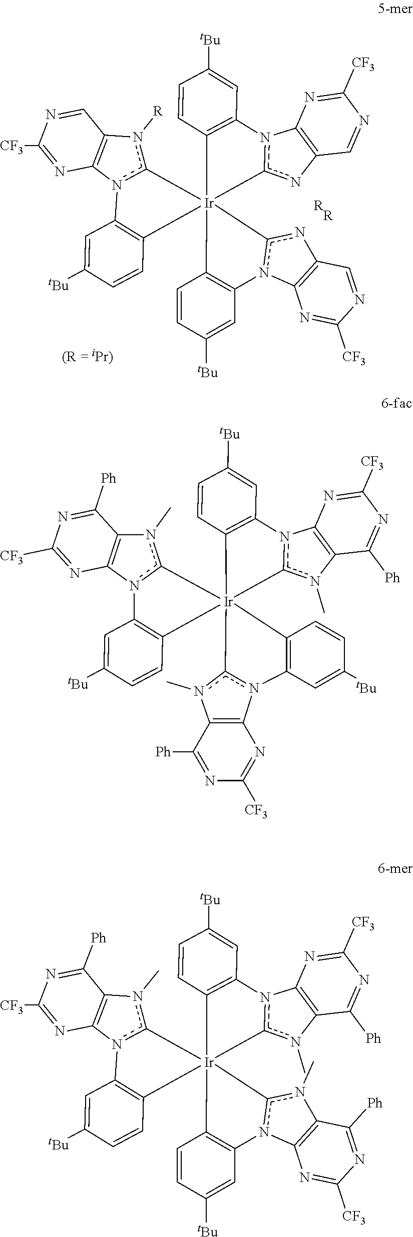

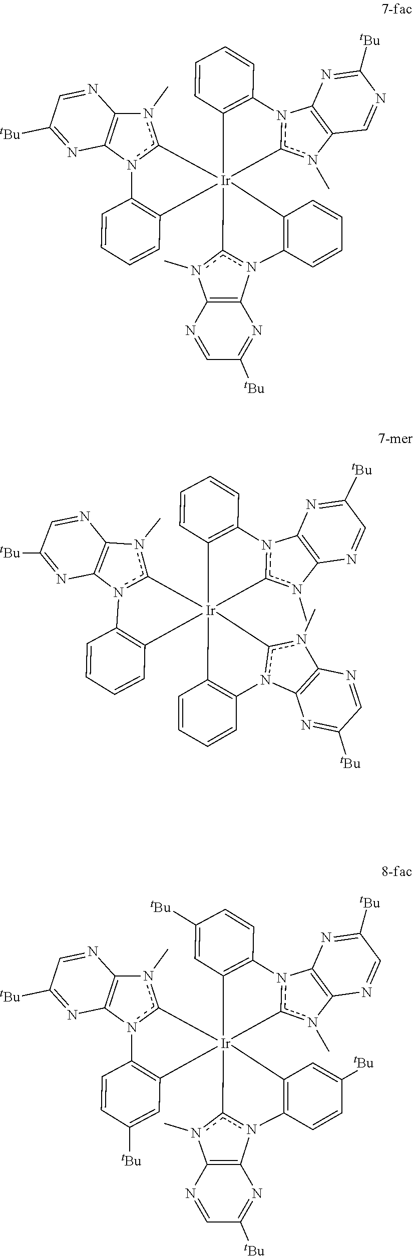

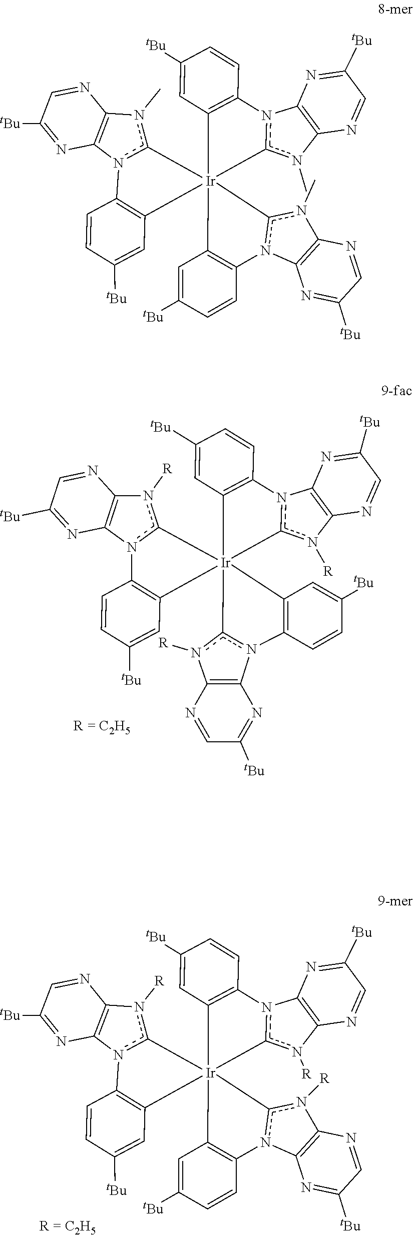

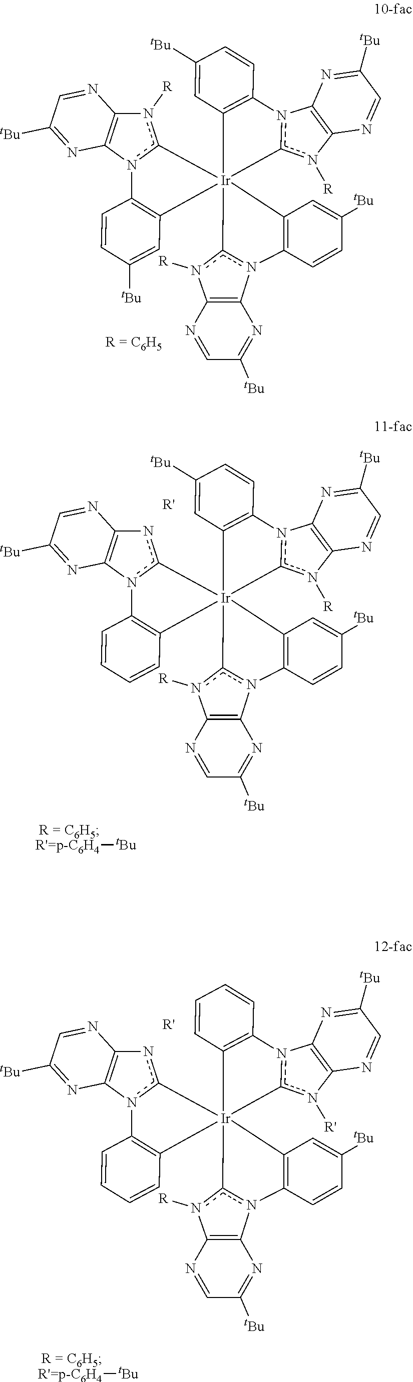

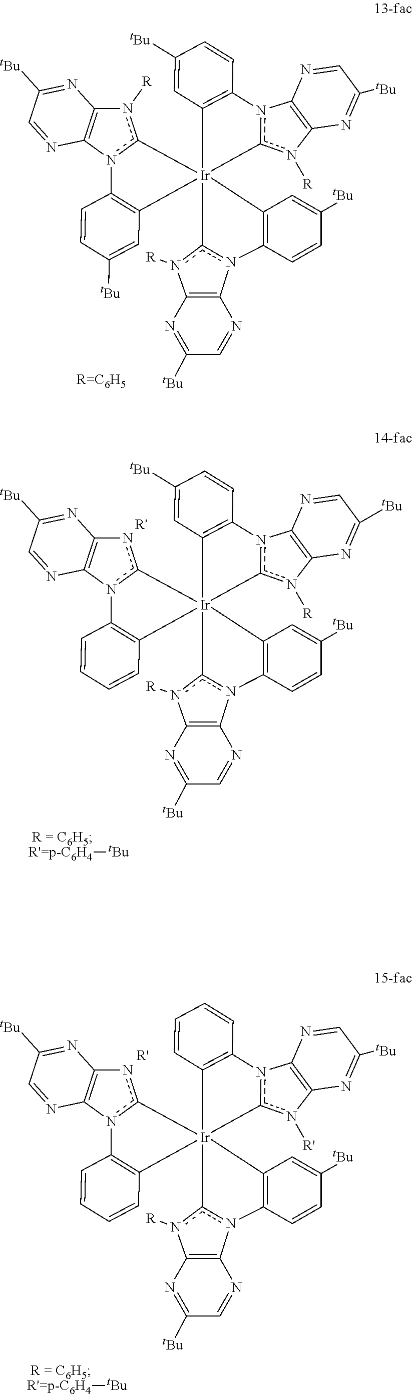

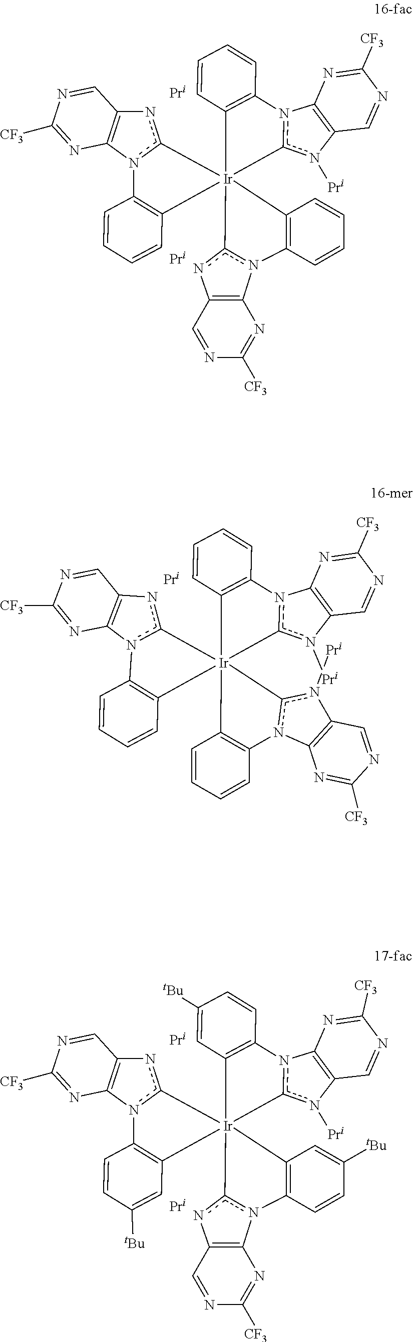

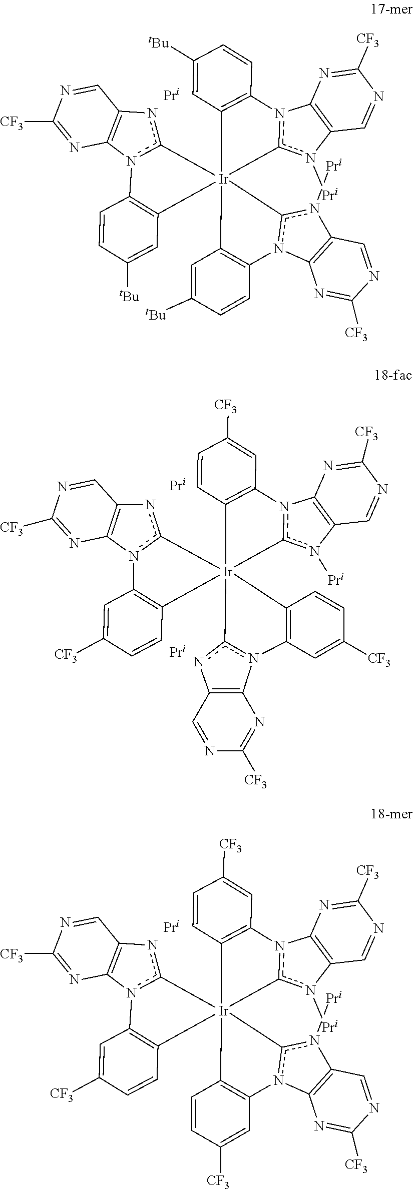

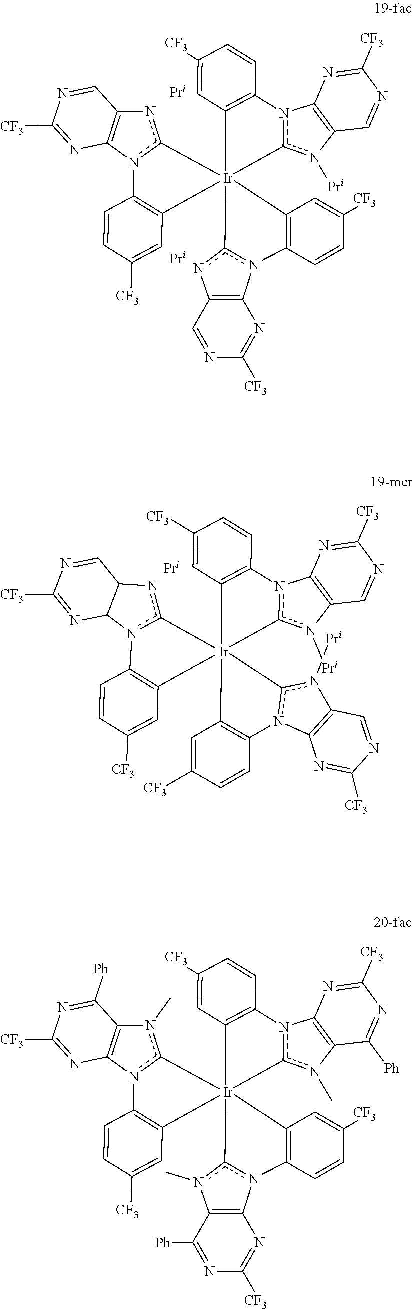

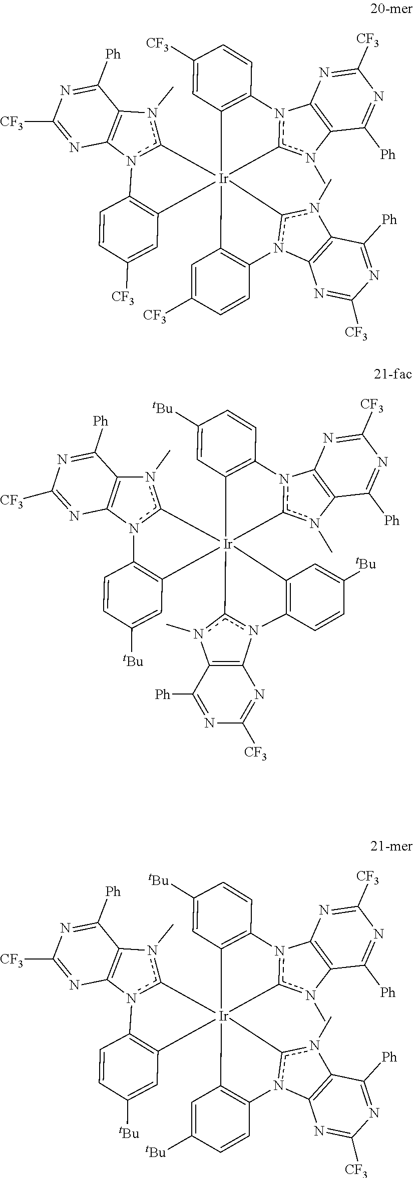

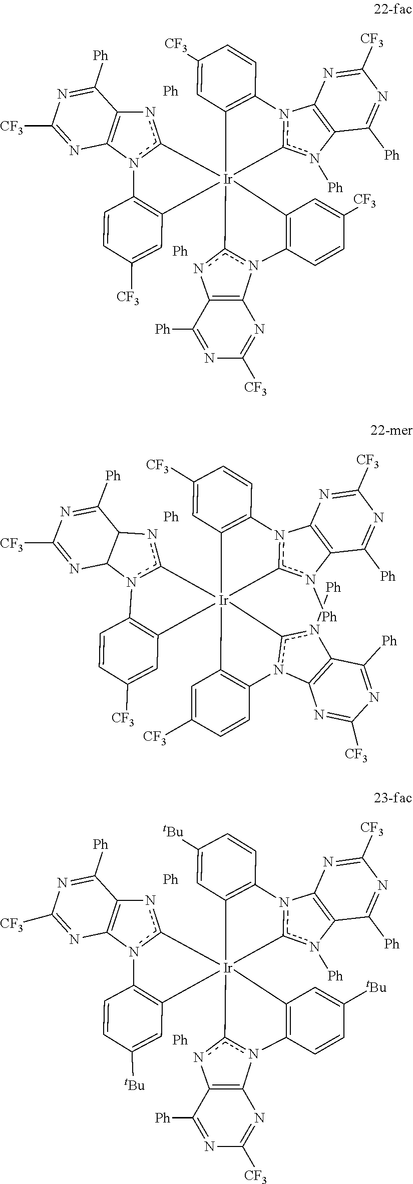

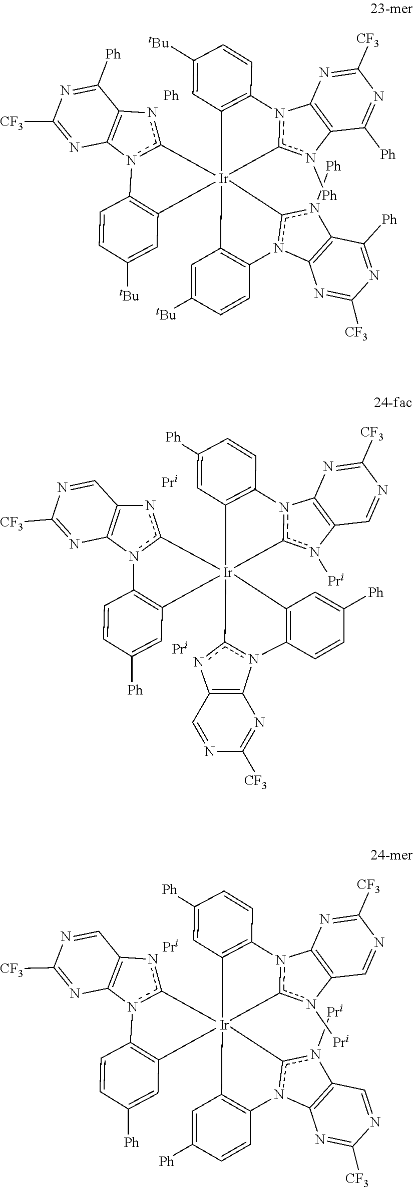

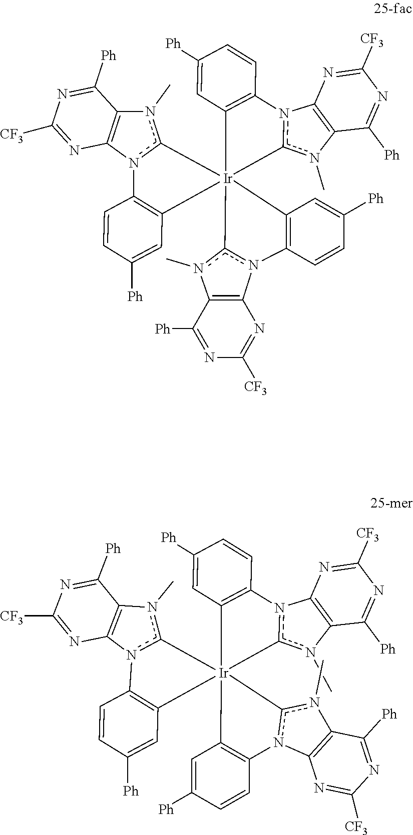

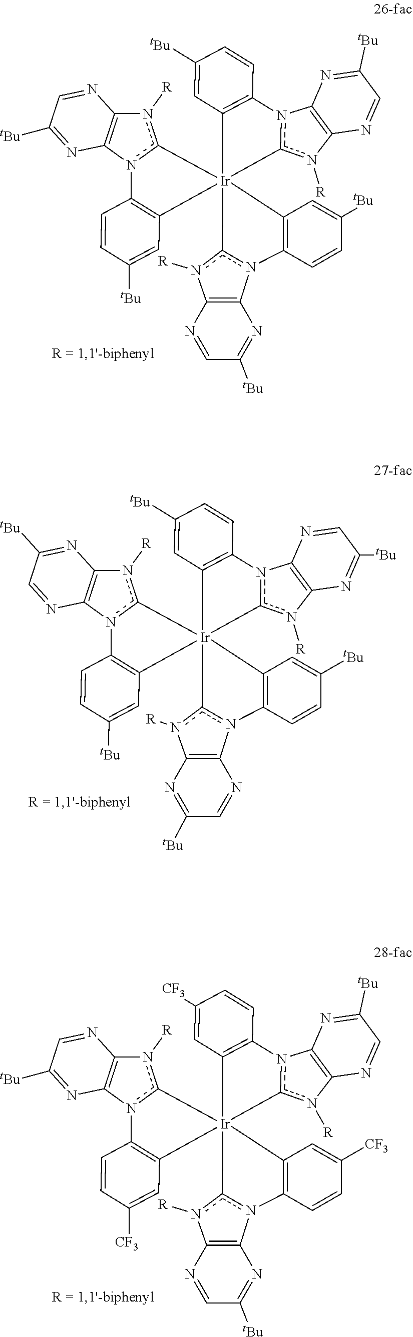

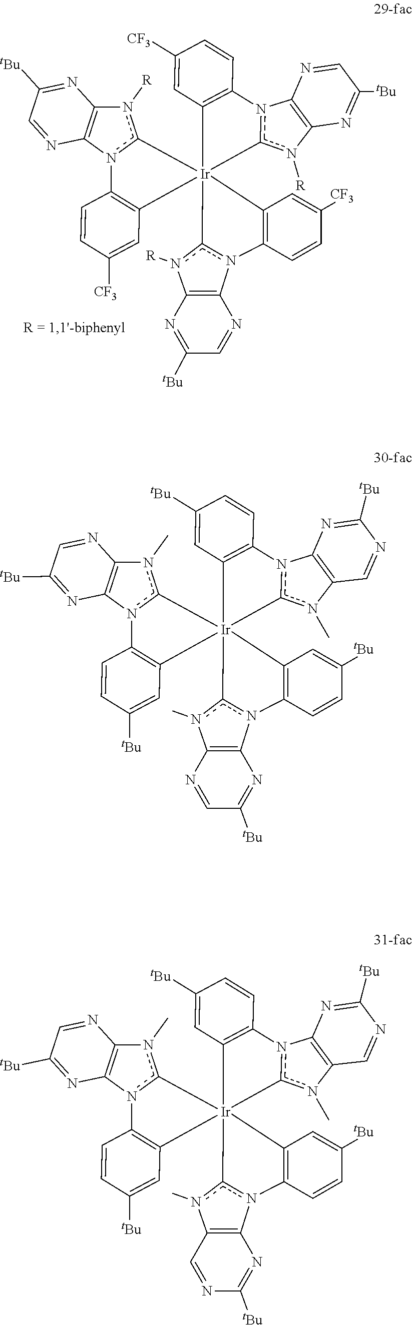

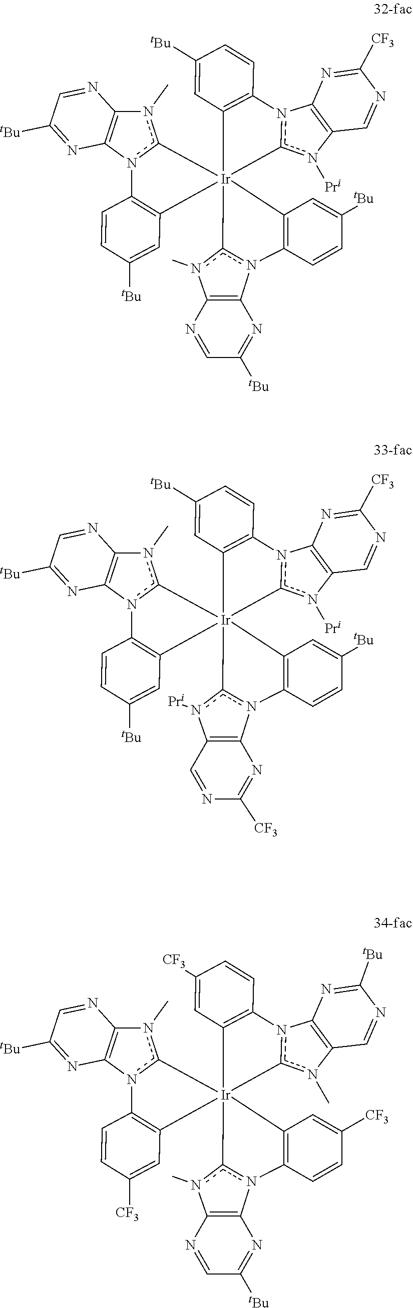

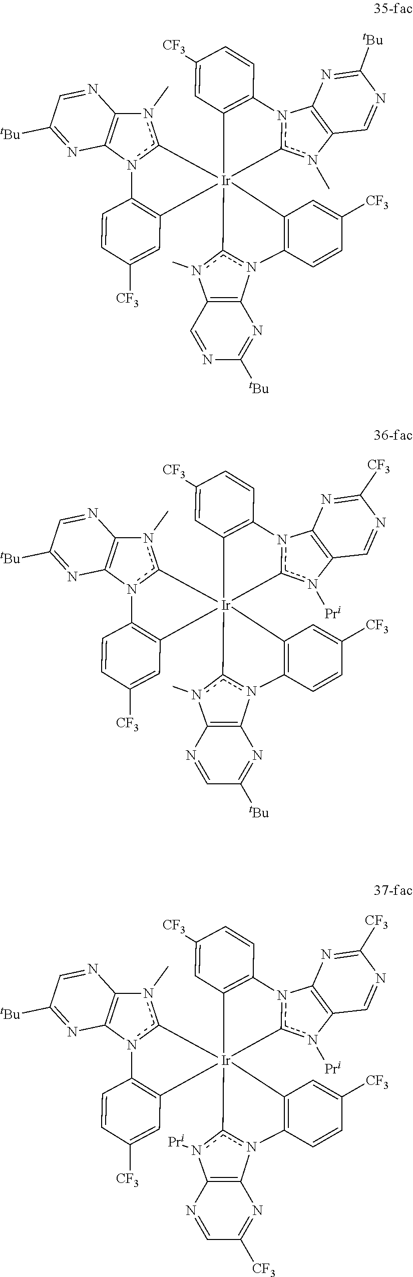

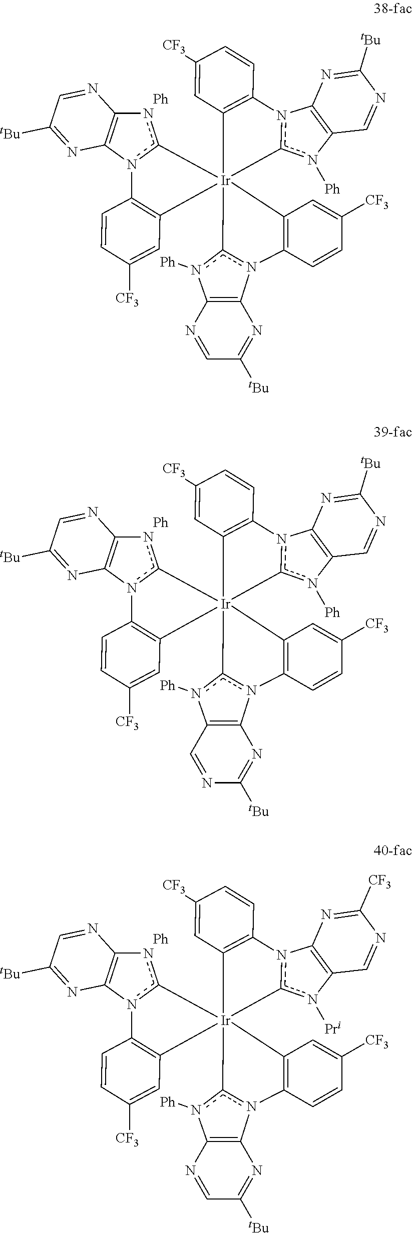

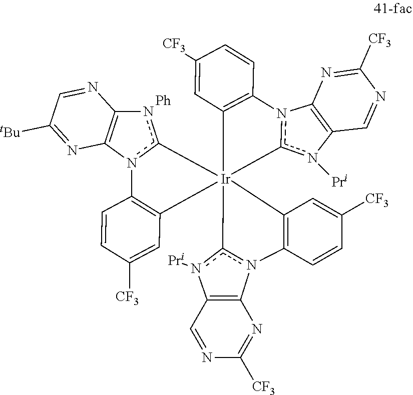

19. A light emitting device comprising an emissive layer having the metal complex according to claim 1.
